(19) United States
(12) Patent Application Publication
(10) Pub. No.: US 2024/0147850 A1
(43) Pub. Date: May 2, 2024

(54) MATERIALS FOR ORGANIC ELECTROLUMINESCENT DEVICES

(71) Applicant: Merck Patent GmbH, Darmstadt (DE)

(72) Inventors: Rouven LINGE, Darmstadt (DE); Miriam ENGEL, Darmstadt (DE); Sebastian STOLZ, Darmstadt (DE); Sebastian MEYER, Darmstadt (DE)

(21) Appl. No.: 18/038,455

(22) PCT Filed: Nov. 29, 2021
(86) PCT No.: PCT/EP2021/083276

§ 371 Date: May 24, 2023

(30) Foreign Application Priority Data
Nov. 30, 2020 (EP) 20210776.9

(51) Int. Cl. H10K 85/60; C09K 11/02; C09K 11/06; H10K 59/35; H10K 85/30

(52) U.S. Cl. CPC H10K 85/6572; C09K 11/02; C09K 11/06; H10K 59/35; H10K 85/342; H10K 85/615; H10K 85/622; H10K 85/633; H10K 85/636; H10K 85/654; H10K 50/11

(57) ABSTRACT

The present invention relates to an electroluminescent device comprising pixels in a side-by-side geometry. The present invention furthermore relates to a process for the fabrication of such an electroluminescent device.

The present invention relates to an electroluminescent device comprising pixels in a side-by-side geometry. The present invention furthermore relates to a process for the fabrication of such an electroluminescent device.

The development of organic light-emitting diodes (OLEDs) for use in small portable devices like mobile phones and television screens is currently the subject of intensive search. The self-emissive nature of OLEDs is a highly desirable feature for display applications in a general way.

There are different types of OLED construction. For example, full-color OLED pixels can be fabricated by vertical stacking of a red-, green-, and blue-emitting unit. Full-color OLED pixels can also be fabricated by placing multiple, single-OLED stacks in a side-by-side configuration within a single pixel. More particularly, it is frequent in flat-panel displays, that each pixel consists of laterally separated red, green, and blue subpixels in a side-by-side geometry as disclosed, for example, in US 2004/0108818 A1, US2006/0244696 A1.

However, in case of OLED displays, side-by-side layouts can lead to cross-contamination issues during the fabrication process. If, for example, the green-emitting layer of a subpixel contains a small amount of a material present in an adjacent subpixel, which can lead to the green emission quenching (for example the green emitting layer comprises a triplet green emitter and the adjacent layer comprises a material which can act as a triplet green quencher), then the green subpixel will not emit a pure green emission as expected (see also FrObel et al, Three-terminal RGB full-color OLED pixels for ultrahigh density display, SCIENTIFIC REPORTS, (2018) 8:9684).

Therefore, further improvements are still necessary with respect to the fabrication of OLEDs, in particular with respect to the fabrication of RGB displays based on a side-by-side pixel layout. Of particular importance in this connection are the lifetime, the efficiency and the operating voltage of the OLEDs and as well as the colour values achieved.

The present invention is thus based on the technical object of providing electroluminescent devices having pixels comprising subpixels placed in a side-by-side configuration. The present invention is also based on the technical object of providing compounds which are suitable for these electroluminescent devices. Furthermore, the present invention is based on the technical object of providing processes for the manufacturing of these electroluminescent devices

In investigations on novel electroluminescent devices having pixels or/and subpixels placed in a side-by-side geometry, it has now been found, that the electroluminescent devices as defined below are eminently suitable for use in display applications. In particular, they achieve one or more, preferably all, of the above-mentioned technical objects.

The invention thus relates to an electroluminescent device comprising at least one pixel comprising:
A first subpixel comprising an emitting layer EMLA comprising a compound A;
A second subpixel comprising an emitting layer EMLB comprising a compound B, wherein the compound B is the compound having the lowest T₁ state in the emitting layer EMLB;
   characterized in that:

T_{1-A}<T_{1-B}

TGA_{A}≥225° C.

where

T_{1-A}, T_{1-B} are the energetically lowest triplet state of the compounds A and B; and

TGA_{A} is the temperature at which 5% weight loss is measured via thermal gravimetric analysis.

The electroluminescent device according to the present invention is preferably an organic electroluminescent device, also called OLED.

The energetically lowest triplet state of a compound can be determined using quantum chemical calculations.

More particularly, the electronic properties of materials, including molecular orbitals, in particular the highest occupied molecular orbital (HOMO) and the lowest unoccupied molecular orbital (LUMO), their energy levels and the energy of the lowest triplet state T₁ or of the lowest excited singlet state S₁ of the materials, are determined via quantum-chemical calculations using the software package “Gaussian16” (Gaussian Inc.). The singlet ground state geometries are optimized at the B3PW91/6-31G(d) level of theory. Subsequently, TD-DFT singlet and triplet excitation energies (vertical transitions) are computed using the optimized ground state geometry and the same method (B3PW91/6-31G(d)). Default settings for SCF and geometry convergence are employed.

The energy calculation gives the HOMO energy level HEh or LUMO energy level LEh in hartree units. The HOMO and LUMO energy levels in electron volts are calculated as follows:

HOMO(eV)=(HEh*27.212)

LUMO(eV)=(LEh*27.212)

These values are to be regarded as HOMO and LUMO energy levels respectively of the materials.

The lowest triplet state T₁ is defined as the energy of the triplet state having the lowest energy which arises from the quantum-chemical calculation described.

The lowest excited singlet state S₁ is defined as the energy of the excited singlet state having the second lowest energy which arises from the quantum-chemical calculation described.

The lowest energy singlet state referred to SO, also often referred to as ground state.

The method described herein is independent of the software package used and always gives the same results. Examples of frequently used programs for this purpose are “Gaussian09W” (Gaussian Inc.) and Q-Chem 4.1 (Q-Chem, Inc.). In the present case, the software package “Gaussian16”, (Gaussian Inc.) is used.

The TGA (Thermogravimetric Analyses) measurements are performed here using a TG 209 F1 Libra from Netzsch, which is temperature-calibrated under vacuum in the means of Curie standards as described in ASTM E1582-10 “Standard Practice for Calibration of Temperature Scale for Thermogravimetry”. Further details on the method used for TGA measurements are given in the examples below.

Preferably, the compound A has a temperature TGA_{A} at which 5% weight loss is measured via thermal gravimetric analysis of ≥230° C., more preferably TGA_{A}≥235° C., particularly preferably ≥240° C., very particularly preferably ≥245° C.

In accordance with a preferred embodiment, the compound A is the compound having the highest T₁ state in the emitting layer EMLA of the first subpixel.

In accordance with a preferred embodiment, the emitting layer EMLA comprises a host compound HA and an emitting compound EA, wherein the compound A is either the host compound HA or the emitting compound EA.

In accordance with the present invention, when the emitting layer comprises both the host compound and the emitting compound, then the emitting compounds are generally the compounds having the smaller proportion in the system (=dopants) and the host compounds are those compounds having the greater proportion in the system. In individual cases, however, the proportion of a single matrix material in the system may be less than the proportion of a single emitting compound.

Preferably, the compound A has a molecular weight MwA ≥520 g/mol, more preferably ≥530 g/mol, particularly preferably ≥540 g/mol, more particularly preferably ≥550 g/mol.

Preferably, the host compound A has a molecular weight MwA of ≤5000 g/mol, more preferably ≤3000 g/mol, and particularly preferably ≤2000 g/mol.

In accordance with a preferred embodiment, the compound B is a polymer, which preferably has a molecular weight MwB in the range of 10.000 to 2.000.000 g/mol, more preferably in the range of 20.000 to 1.500.000 g/mol, particularly preferably in the range of 30.000 to 1.000.000 g/mol, and very particularly preferably 40.000 to 500.000 g/mol.

In accordance with another preferred embodiment, the compound B is a small molecule, which has a molecular weight MwB of ≤5000 g/mol, more preferably ≤3000 g/mol, and particularly preferably ≤2000 g/mol.

In accordance with a preferred embodiment, the emitting layer EMLB comprises a host compound HB and an emitting compound EB, wherein the compound B is either the host compound HB or the emitting compound EB.

In accordance with another preferred embodiment, the emitting layer EMLB comprises a compound B, which is an emitting polymer PB.

In accordance with a preferred embodiment, the electroluminescent device comprises a third sub pixel comprising an emitting layer EMLC.

EMLA, EMLB and EMLC respectively have an emission maximum wavelength λ_{A}, λ_{B} and λ_{c} and it is preferred that:

λ_{A}<λ_{B}=λ_{C}; or 1)

λ_{A}<λ_{C}<λ_{B}; or 2)

λ_{C}<λ_{B}<λ_{A}. 3)

Preferably, λ_{A}<λ_{B}<λ_{C}.

The present invention also relates to an electroluminescent device comprising at least one pixel comprising:
A first subpixel comprising an emitting layer EML1 comprising a host compound H1 and an emitting compound E1;
A second subpixel comprising an emitting layer EML2 comprising a host compound H2 and an emitting compound E2;
   characterized in that:

T_{1-H1}<T_{1-E2}

TGA_{H1}≥225° C.

where

T_{1-H1}, T_{1-E2} are the energetically lowest triplet state of the host compound H1 and of the emitting compound E2; and

TGA_{H1} is the temperature at which 5% weight loss is measured via thermal gravimetric analysis.

Preferably, the host compound H1 has a temperature TGAH1 at which 5% weight loss is measured via thermal gravimetric analysis of ≥230° C., more preferably TGA_{H1}≥235° C., particularly preferably ≥240° C., very particularly preferably ≥245° C.

Preferably, the host compound H1 has a molecular weight Mw1≥520 g/mol, more preferably ≥530 g/mol, particularly preferably ≥540 g/mol, more particularly preferably ≥550 g/mol.

Preferably, the host compound H1 has a molecular weight Mw1 of ≥5000 g/mol, more preferably ≥3000 g/mol, and particularly preferably ≥2000 g/mol.

In accordance with one preferred embodiment, the host compound H2 has a molecular weight Mw2 of ≥5000 g/mol, more preferably ≥3000 g/mol, and particularly preferably ≥2000 g/mol.

In accordance with another preferred embodiment, the host H2 is a polymer, which preferably has a molecular weight Mw2 in the range of 10.000 to 2.000.000 g/mol, more preferably in the range of 20.000 to 1.500.000 g/mol, particularly preferably in the range of 30.000 to 1.000.000 g/mol, and very particularly preferably 40.000 to 500.000 g/mol.

In accordance with a preferred embodiment, the compound HA or the host compound H1 comprises a condensed aryl group having 14 to 22 aromatic atoms, more preferably an anthracene group.

More preferably, the compound HA or the host compound H1 comprises a first condensed aryl group, which is an anthracene group and a second condensed aryl group having 10 to 22, preferably 14 to 22 aromatic atoms. The second condensed aryl group may be an anthracene group.

More particularly preferably, the compound HA or the host compound H1 comprises a first condensed aryl group, which is an anthracene group, a second condensed aryl group having 10 to 22, preferably 14 to 22 aromatic atoms and a third condensed aryl group having 6 to 22 aromatic atoms.

More particularly preferably, the host compound HA or the host compound H1 comprises a first condensed aryl group, which is an anthracene group, a second condensed aryl group having 10 to 22, preferably 14 to 22 aromatic atoms, a third condensed aryl group having 6 to 22 aromatic atoms and a fourth condensed aryl group having 6 to 22 aromatic atoms.

Preferably, the compound HA or the host compound H1 is a compound of formula (1),

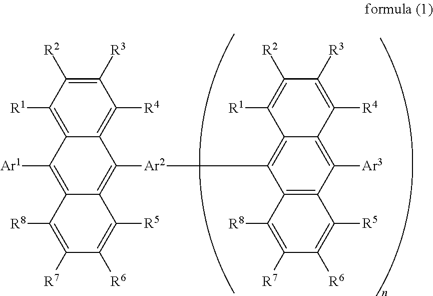

where

Ar¹, Ar², Ar³ are, on each occurrence, identically or differently, an aromatic or heteroaromatic ring system having 5 to 60 aromatic ring atoms, which may in each case also be substituted by one or more radicals R⁹;

R¹to R⁹ stand on each occurrence, identically or differently, for H, D, F, Cl, Br, I, CHO, CN, C(═O)Ar, P(═O)(Ar)₂, S(═O)Ar, S(═O)2Ar, N(R)₂, N(Ar)₂, NO₂, Si(R)₃, B(OR)₂, OSO₂R, a straight-chain alkyl, alkoxy or thioalkyl group having 1 to 40 C atoms or branched or a cyclic alkyl, alkoxy or thioalkyl group having 3 to 40 C atoms, each of which may be substituted by one or more radicals R, where in each case one or more non-adjacent CH₂ groups may be replaced by RC═CR, CEC, Si(R)₂, Ge(R)₂, Sn(R)₂, C═O, C═S, C═Se, P(═O)(R), SO, SO₂, O, S or CONR and where one or more H atoms may be replaced by D, F, Cl, Br, I, CN or NO₂, an aromatic or heteroaromatic ring system having 5 to 60 aromatic ring atoms, which may in each case be substituted by one or more radicals R, or an aryloxy group having 5 to 60 aromatic ring atoms, which may be substituted by one or more radicals R;

R stands on each occurrence, identically or differently, for H, D, F, Cl, Br, I, CHO, CN, C(═O)Ar, P(═O)(Ar)₂, S(═O)Ar, S(═O)₂Ar, N(R′)₂, N(Ar)₂, NO₂, Si(R′)₃, B(OR′)₂, OSO₂R′, a straight-chain alkyl, alkoxy or thioalkyl group having 1 to 40 C atoms or branched or a cyclic alkyl, alkoxy or thioalkyl group having 3 to 40 C atoms, each of which may be substituted by one or more radicals R′, where in each case one or more non-adjacent CH₂ groups may be replaced by R′C═CR′, C≡C, Si(R′)₂, Ge(R′)₂, Sn(R′)₂, C═O, C═S, C═Se, P(═O)(R′), SO, SO₂, O, S or CONR′ and where one or more H atoms may be replaced by D, F, Cl, Br, I, CN or NO₂, an aromatic or heteroaromatic ring system having 5 to 60 aromatic ring atoms, which may in each case be substituted by one or more radicals R′, or an aryloxy group having 5 to 60 aromatic ring atoms, which may be substituted by one or more radicals R′; where two adjacent substituents R may form an aliphatic or aromatic ring system together, which may be substituted by one or more radicals R′;

Ar is, on each occurrence, identically or differently, an aromatic or heteroaromatic ring system having 5 to 60 aromatic ring atoms, which may in each case also be substituted by one or more radicals R′;

R′ stands on each occurrence, identically or differently, for H, D, F, Cl, Br, I, CN, a straight-chain alkyl, alkoxy or thioalkyl group having 1 to 20 C atoms or branched or cyclic alkyl, alkoxy or thioalkyl group having 3 to 20 C atoms, where in each case one or more non-adjacent CH2 groups may be replaced by SO, SO₂, O, S and where one or more H atoms may be replaced by D, F, Cl, Br or I, or an aromatic or heteroaromatic ring system having 5 to 24 aromatic ring atoms; and

n is 0 or 1.

If n is 0, at least one of the group Ar¹ or Ar² is a condensed aryl or heteroaryl group having 10 to 40, preferably 14 to 40 aromatic atoms.

More preferably, the compound HA or the host compound H1 is a compound of formula (1A) or (1B)

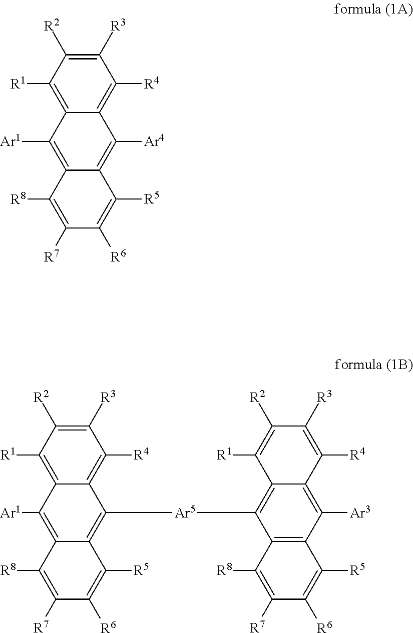

where R¹ to R⁸, Ar¹ and Ar³ have the same meaning as above; and Ar⁴ and Ar⁵ are, on each occurrence, identically or differently, an aromatic or heteroaromatic ring system having 5 to 60 aromatic ring atoms, which may in each case also be substituted by one or more radicals R⁹, which is as defined above.

The compound of formula (1A) is preferably selected from the compounds of formula (1A-1) or (1A-2),

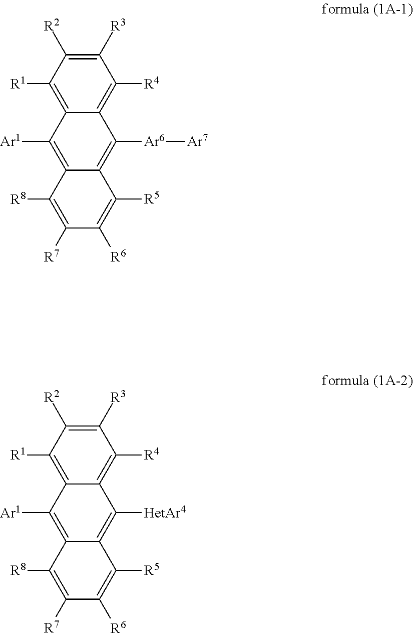

where

Ar⁶ and Ar⁷ are, on each occurrence, identically or differently, an aryl group having 6 to 60, preferably 6 to 30, more preferably 10 to 22 aromatic ring atoms, which may in each case also be substituted by one or more radicals R⁹, which is as defined above.

HetAr⁴ is an heteroaryl group having 5 to 60, preferably 13 to 40, more preferably 20 to 35 aromatic ring atoms, which may in each case also be substituted by one or more radicals R⁹, which is as defined above.

Example of suitable groups Ar⁶ and Ar⁷ are benzene, naphthalene, anthra-cene, phenanthrene, pyrene, chrysene, perylene, fluoranthene, benz-anthracene, benzophenanthrene, tetracene, pentacene and benzopyrene, each of which may be substituted by one or more radicals R⁹.

HetAr⁴ is an heteroaryl group having 5 to 60, preferably 13 to 40, more preferably 20 to 35 aromatic ring atoms, which may in each case also be substituted by one or more radicals R⁹, which is as defined above.

Example of suitable groups HetAr⁴ are condensed heteroaryl groups comprising at least one heteroatom selected from O, S or N, preferably O, like dibenzofuran derivatives.

Preferably, the group Ar¹ is an aryl group having 6 to 30, preferably 6 to 20, more preferably 6 to 10 aromatic ring atoms, which may in each case also be substituted by one or more radicals R⁹.

Example of suitable groups Ar¹ are benzene, naphthalene, anthracene, phenanthrene, pyrene, chrysene, perylene, fluoranthene, benzanthracene, benzophenanthrene, tetracene, pentacene and benzopyrene, more preferably benzene, each of which may be substituted by one or more radicals R⁹.

Preferably, the group Ar⁵ in the compound of formula (1B) is selected from the groups of formulae (Ar5-1) to (A5-8),

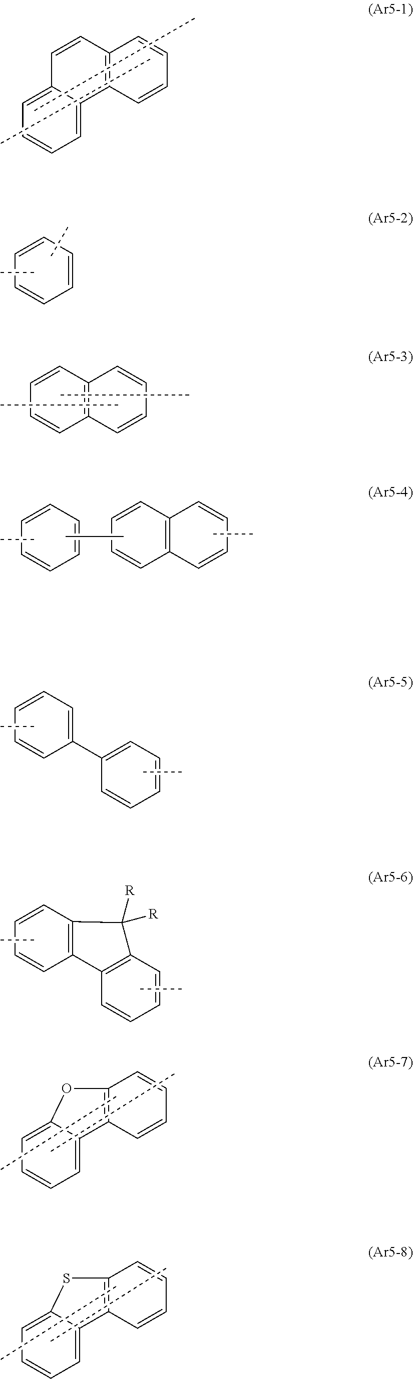

where

the dashed bonds indicate the bonding to the adjacent groups; and where the groups of formulae (Ar5-1) to (Ar5-8) may be substituted at each free position by a group R, which has the same meaning as above.

It is further preferred that the compound HA or the host compound H1 is a compound of formula (1) having at least one D. More preferably, the compound A or the host compound H1 is a compound of formula (1), wherein at least one of the radicals R¹ to R⁸ is D.

In accordance with a preferred embodiment, the emitting layers EMLA, EML1 of the first subpixel comprise a second host compound.

More particularly, considering the electroluminescent device comprising a first subpixel comprising an emitting layer EML1 and a second subpixel comprising an emitting layer EML2, then it is preferred that the first subpixel comprises an emitting layer EML1 comprising an emitting compound E1, a host compound H1 and a second host compound H1B. Preferably, the first host compound H1 and the second host compound H1B are both selected from the compounds of formula (1) as defined above. It is understood here that it is preferred that H1 and H1B are both compounds of formula (1), however they are different from each other.

In accordance with another preferred embodiment, the first host compound H1 is selected from the compounds of formula (1) and the second host compound H1B is selected from compounds selected from the classes of the oligoarylenes (e.g. 2,2′,7,7′-tetraphenylspirobifluorene or dinaphthylanthracene), especially of oligoarylenes containing fused aromatic groups, oligoarylenevinylenes (e.g. DPVBi or spiro-DPVBi), polypodal metal complexes, hole-conducting compounds, electron-conducting compounds, especially ketones, phosphine oxides, and sulphoxides, and atropisomers, boronic acid derivatives or benzanthracenes. Particularly preferred matrix materials are selected from the classes of the oligoarylenes comprising naphthalene, anthracene, benzanthracene and/or pyrene or atropisomers of these compounds, the oligoarylenevinylenes, the ketones, the phosphine oxides and the sulphoxides. Very particularly preferred matrix materials are selected from the classes of the oligoarylenes comprising anthracene, benzanthracene, benzophenanthrene and/or pyrene or atropisomers of these compounds. An oligoarylene in the context of this invention shall be understood to mean a compound in which at least three aryl or arylene groups are bonded to one another.

In accordance with a preferred embodiment, the compound EA or the emitting compound E1 is a fluorescent emitting compound. More preferably, the compound EA or the the emitting compound E1 is a fluorescent emitting compound and does not comprise any metal. More particularly preferably, the compound EA or the the emitting compound E1 is a fluorescent emitting compound selected from the group consisting of:
an arylamine containing three substituted or unsubstituted aromatic or heteroaromatic ring systems bonded directly to the nitrogen;
a bridged triarylamine;
a condensed aromatic or heteroaromatic ring system having at least 14 aromatic ring atoms;
an indenofluorene, indenofluorenamine or indenofluorenediamine;
a benzoindonofluorene, benzoindenofluorenamine or benzoindenofluorenediamine;
a dibenzoindenofluorene, dibenzoindenofluorenamine or dibenzo-indenofluorenediamine;
an indenofluorene containing a condensed aryl group having at least 10 aromatic ring atoms;
a bisindenoindenofluorene;
an indenodibenzofuran; indenofluorenamine or indenofluorenediamine;
a fluorene dimer;
a phenoxazine; and
a boron derivative.

Even more particularly preferably, the compound EA or the the emitting compound E1 is a fluorescent emitting compound selected from the compounds of formula (E-1), (E-2), (E-3) or (E-4),

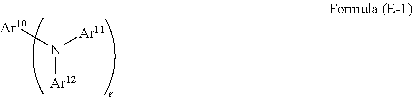

where

Ar¹⁰, Ar¹¹, Ar¹² are on each occurrence, identically or differently, an aromatic or heteroaromatic ring system having 6 to 60 aromatic ring atoms, which may in each case also be substituted by one or more radicals R; with the proviso that at least one group Ar¹⁰, Ar¹¹, Ar¹² is an aromatic or heteroaromatic ring system having 10 to 40 aromatic ring atoms, containing at least one condensed aryl or heteroaryl group consisting of 2 to 4 aromatic rings condensed with one another, where the aromatic or heteroaromatic ring system may be substituted by one or more radicals R;

R stands on each occurrence, identically or differently, for H, D, F, Cl, Br, I, CHO, CN, C(═O)Ar, P(═O)(Ar)₂, S(═O)Ar, S(═O)₂Ar, N(R′)₂, N(Ar)₂, NO₂, Si(R′)₃, B(OR′)₂, OSO₂R′, a straight-chain alkyl, alkoxy or thioalkyl group having 1 to 40 C atoms or branched or a cyclic alkyl, alkoxy or thioalkyl group having 3 to 40 C atoms, each of which may be substituted by one or more radicals R′, where in each case one or more non-adjacent CH₂ groups may be replaced by R′C═CR′, C≡C, Si(R′)₂, Ge(R′)₂, Sn(R′)₂, C═O, C═S, C═Se, P(═O)(R′), SO, SO₂, O, S or CONR′ and where one or more H atoms may be replaced by D, F, Cl, Br, I, CN or NO₂, an aromatic or heteroaromatic ring system having 5 to 60 aromatic ring atoms, which may in each case be substituted by one or more radicals R′, or an aryloxy group having 5 to 60 aromatic ring atoms, which may be substituted by one or more radicals R′; where two adjacent substituents R may form an aliphatic or aromatic ring system together, which may be substituted by one or more radicals R′;

Ar is, on each occurrence, identically or differently, an aromatic or heteroaromatic ring system having 5 to 60 aromatic ring atoms, which may in each case also be substituted by one or more radicals R′;

R′ stands on each occurrence, identically or differently, for H, D, F, Cl, Br, I, CN, a straight-chain alkyl, alkoxy or thioalkyl group having 1 to 20 C atoms or branched or cyclic alkyl, alkoxy or thioalkyl group having 3 to 20 C atoms, where in each case one or more non-adjacent CH₂ groups may be replaced by SO, SO₂, O, S and where one or more H atoms may be replaced by D, F, Cl, Br or I, or an aromatic or heteroaromatic ring system having 5 to 24 aromatic ring atoms; and

e is 1, 2, 3 or 4; more preferably, e is 1;

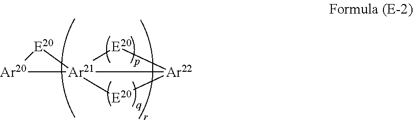

where

Ar²⁰, Ar²¹, Ar²² are on each occurrence, identically or differently, an aryl or heteroaryl group having 6 to 30 aromatic ring atoms, which may in each case also be substituted by one or more radicals R;

E²⁰ is on each occurrence, identically or differently a group selected from BR, C(R⁰)₂, Si(R⁰)₂, C═O, C═NR⁰, C═C(R⁰)₂, O, S, S═O, SO₂, NR⁰, PR⁰, P(═O)R⁰ or P(═S)R⁰; wherein Ar²⁰, Ar²¹ and E²⁰ together form a five-membered ring or a six-membered ring, and Ar²¹, Ar²³ and E²⁰ together form a five-membered ring or a six-membered ring;

R⁰ stands on each occurrence, identically or differently, for H, D, F, a straight-chain alkyl group having 1 to 20, preferably 1 to 10 C atoms or branched or a cyclic alkyl group having 3 to 20, preferably 3 to 10 C atoms, each of which may be substituted by one or more radicals R, where in each case one or more non-adjacent CH₂ groups may be replaced by O or S and where one or more H atoms may be replaced by D or F, or an aromatic or heteroaromatic ring systems having 5 to 40, preferably 5 to 30, more preferably 6 to 18 aromatic ring atoms, which may in each case be substituted by one or more radicals R, where two adjacent radicals R⁰, may form an aliphatic or aromatic ring system together, which may be substituted by one or more radicals R,

R has the same definition as above in formula (E−1);

p, q are on each occurrence, identically or differently, 0 or 1, with the proviso that p +q =1;

r is 1, 2 oder 3;

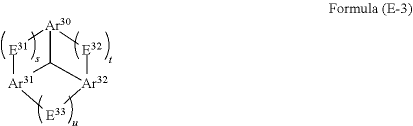

where

Ar³⁰, Ar³¹, Ar³² stand on each occurrence, identically or differently, for a substituted or unsubstituted aryl or heteroaryl group having 5 to 22, preferably 5 to 18, more preferably 6 to 14 aromatic ring atoms; E³⁰ stands for B or N;

E³¹, E³², E³³ stand on each occurrence, identically or differently, for O, S, C(R⁰)₂, C═O, C═S, C═NR⁰, C═C(R⁰)₂, Si(R⁰)₂, BR⁰, NR⁰, PR⁰, SO₂, SeO₂ or a chemical bond, with the proviso that if E³⁰ is B, then at least one of the groups E³¹, E³², E³³ stands for NR⁰ and if E³⁰ is N, then at least one of the groups E³¹, E³², E³³ stands for BR⁰;

R⁰ has the same definition as above;

s, t, u are on each occurrence, identically or differently, 0 or 1, with the proviso that s+t+u≥1;

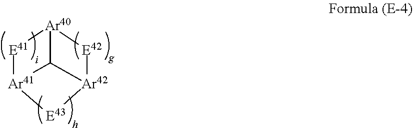

where

Ar⁴⁰, Ar⁴¹, Ar⁴² stand on each occurrence, identically or differently, for a substituted or unsubstituted aryl or heteroaryl group having 5 to 22, preferably 5 to 18, more preferably 6 to 14 aromatic ring atoms;

E⁴¹, E⁴², E⁴³ stand on each occurrence, identically or differently, for O, S, C(R⁰)₂, C═O, C═S, C═NR⁰, C═C(R⁰)₂, Si(R⁰)₂, BR⁰, NR⁰, PR⁰, SO₂, SeO₂ or a chemical bond, with the proviso that at least one of the groups E⁴¹, E⁴², E⁴³ is present and stands for a chemical bond;

R⁰ has the same definition as above;

i, g, h are on each occurrence, identically or differently, 0 or 1, with the proviso that i+g+h≥1.

Preferably, the fluorescent emitting compound of formula (E-1) comprises at least one group Ar¹⁰, Ar¹¹ or Ar¹², preferably Ar¹⁰, which is selected from the groups of formulae (Ar¹⁰-1) to (Ar¹⁰-24):

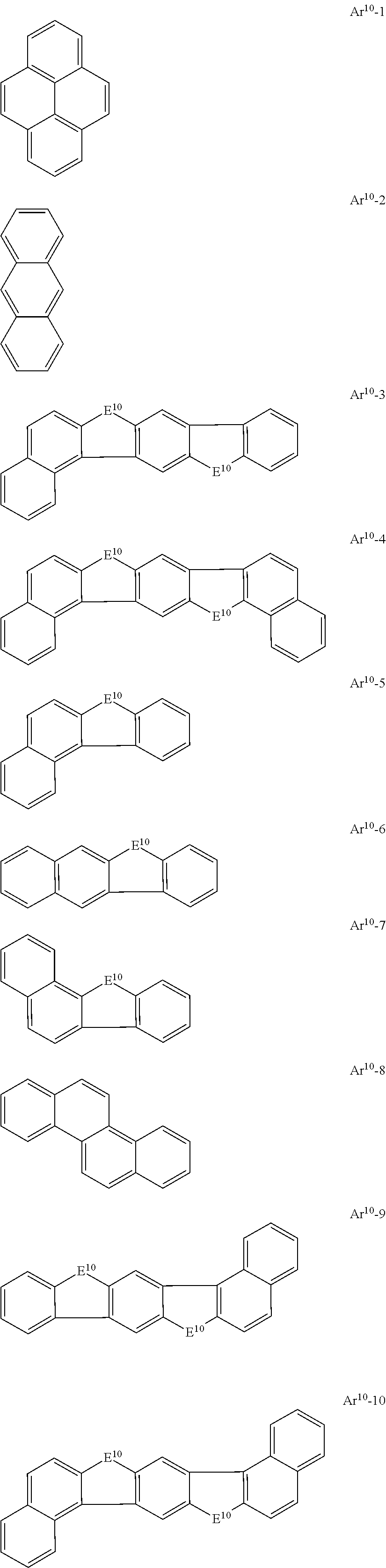

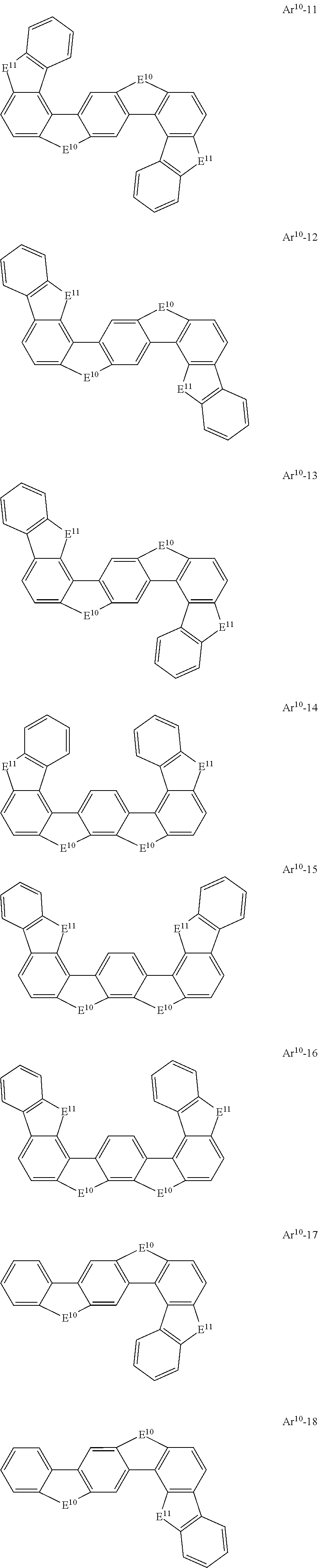

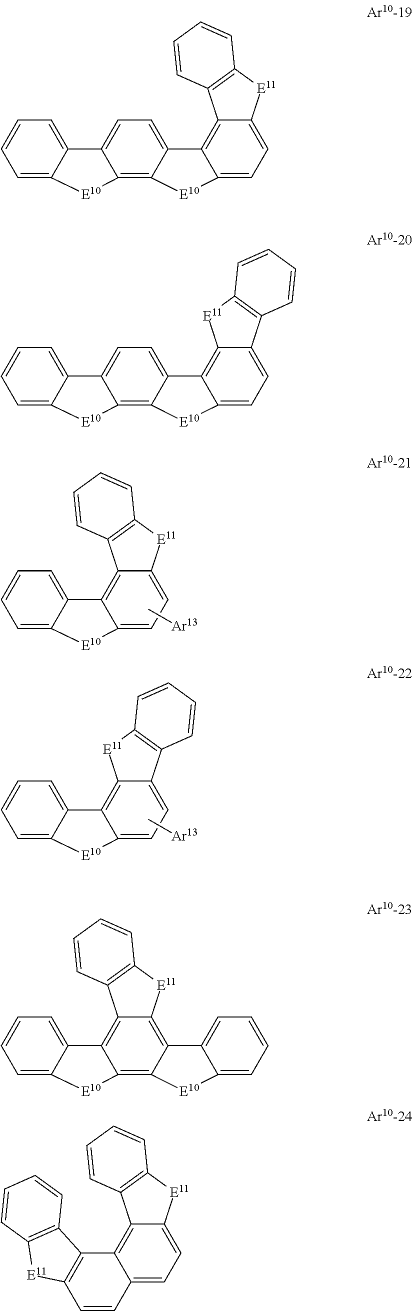

where the groups Ar¹⁰-1 to Ar¹⁰-24 may be substituted at all free positions by one or more radicals R; and where

E¹⁰ is on each occurrence, identically or differently a group selected from BR⁰, C(R⁰)₂, Si(R⁰)₂, C═O, C═NR⁰, C═C(R⁰)₂, O, S, S═O, SO₂, NR⁰, PR⁰, P(═O)R⁰ or P(═S)R⁰, preferably E¹⁰ is C(R⁰)₂;

where R⁰ has the same definition as above;

E¹¹ is on each occurrence, identically or differently a group selected from C═O, O, S, S═O or SO₂, preferably O or S, more preferably O; and

Ar¹³ is on each occurrence, identically or differently, an aromatic or heteroaromatic ring system having 5 to 60 aromatic ring atoms, which may in each case also be substituted by one or more radicals R.

In accordance with a preferred embodiment, the emitting compounds of formula (E-1) comprise a group Ar¹⁰ selected from the groups of formulae (Ar¹⁰-15) to (Ar¹⁰-22), wherein d is preferably equal to 1 and wherein preferably at least one group Ar¹¹, Ar¹² is selected from the groups of formulae (Ar¹⁰-15) to (Ar¹⁰-22).

In accordance with a very preferred embodiment, the emitting compound of formula (E-1) is selected from the emitting compounds of formulae (E-1-1) to (E-1-6),

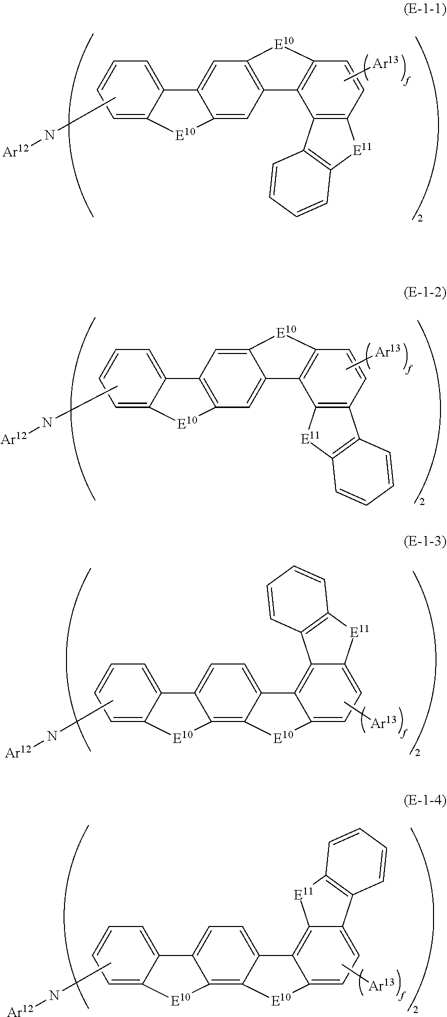

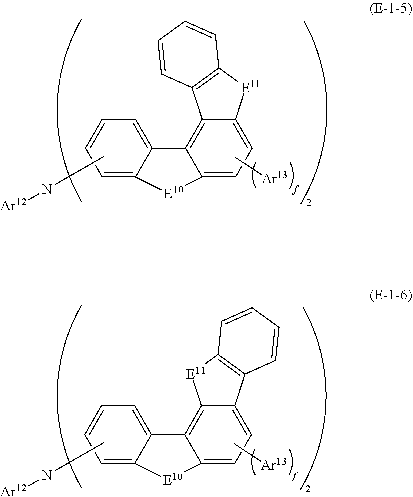

where the symbols have the same meaning as above and where:

f is 0, 1 or 2; and

the benzene rings represented above in the compounds of formulae (E-1-1) to (E-1-6) may be substituted at all free positions by one or more radicals R.

Particularly preferably, the compounds of formula (E-1) are selected from the compounds of formulae (E-1-1-A) to (E-1-6-A),

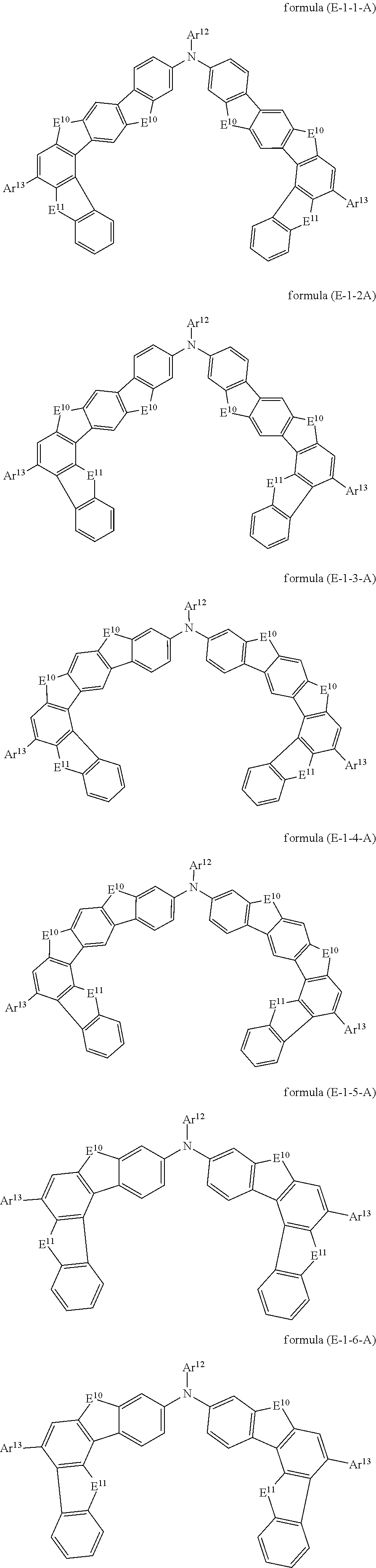

where the symbols and indices have the same meaning as above and where the benzene rings represented above in the compounds of formulae (E-1-1-A) to (E-1-6-A) may be substituted at all free positions by one or more radicals R.

Preferably, the fluorescent emitting compound of formula (E-2) is selected from fluorescent emitting compounds of formula (E-2-1) to (E-2-43),

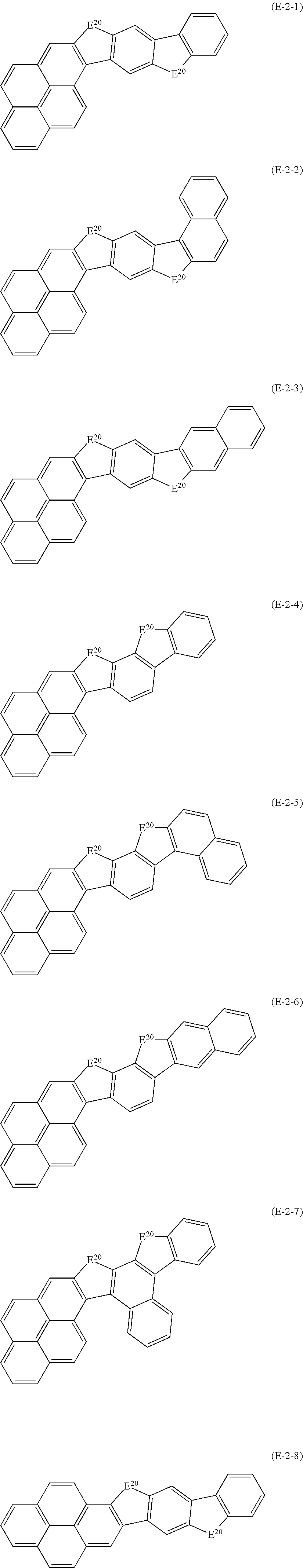

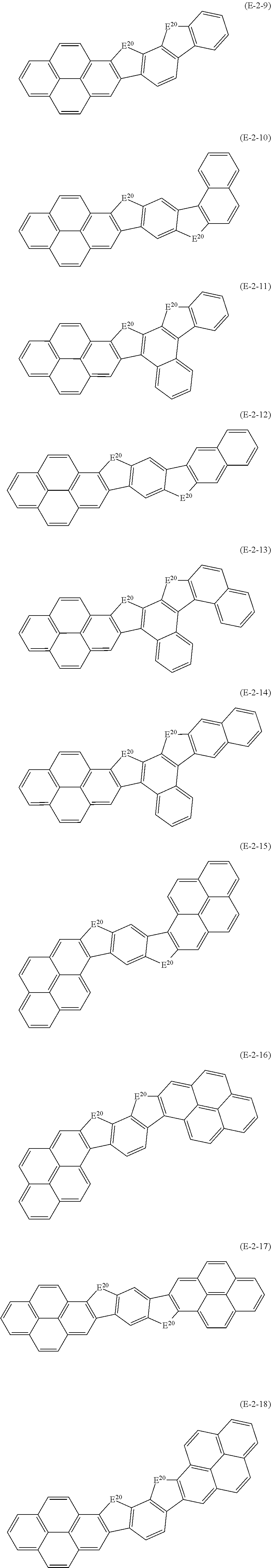

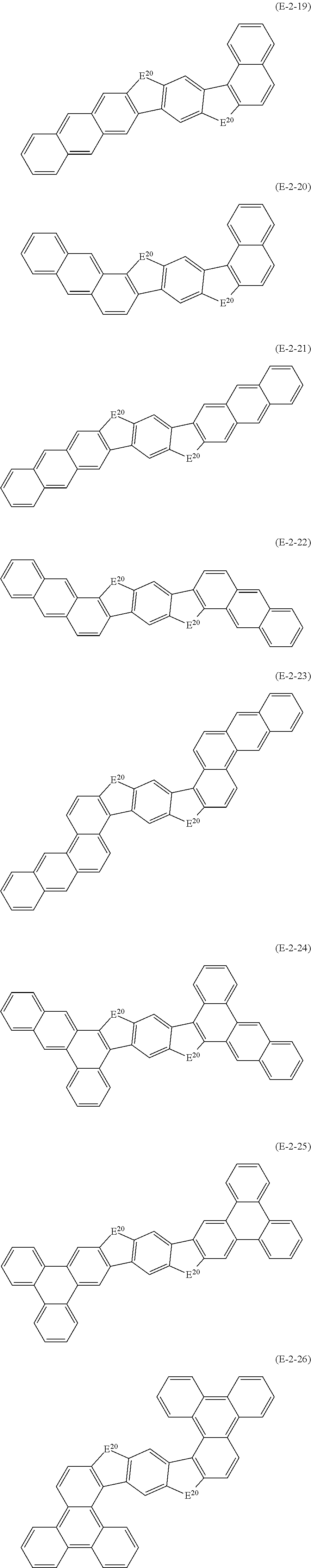

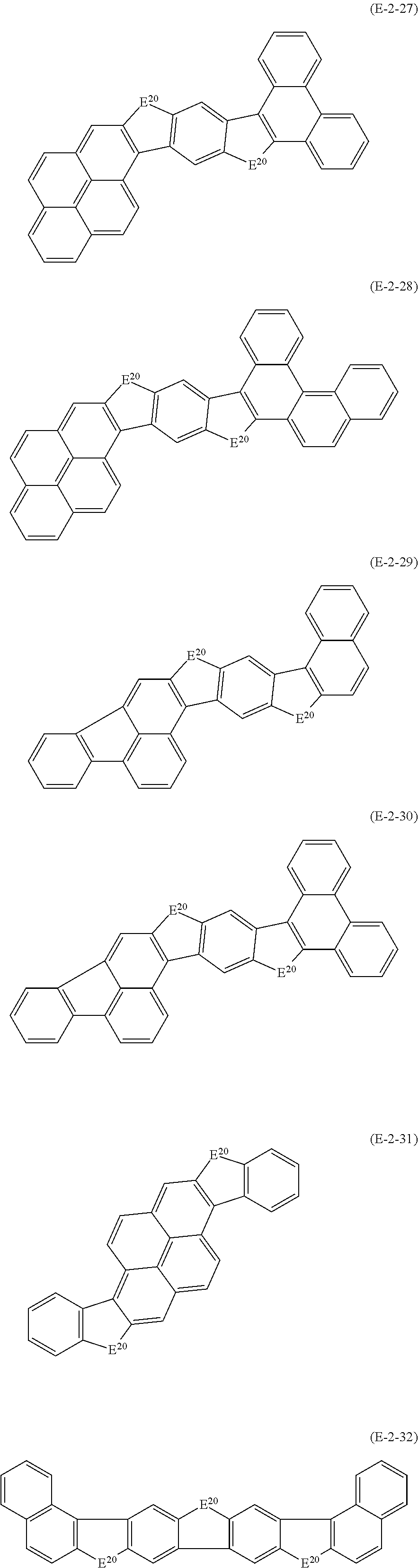

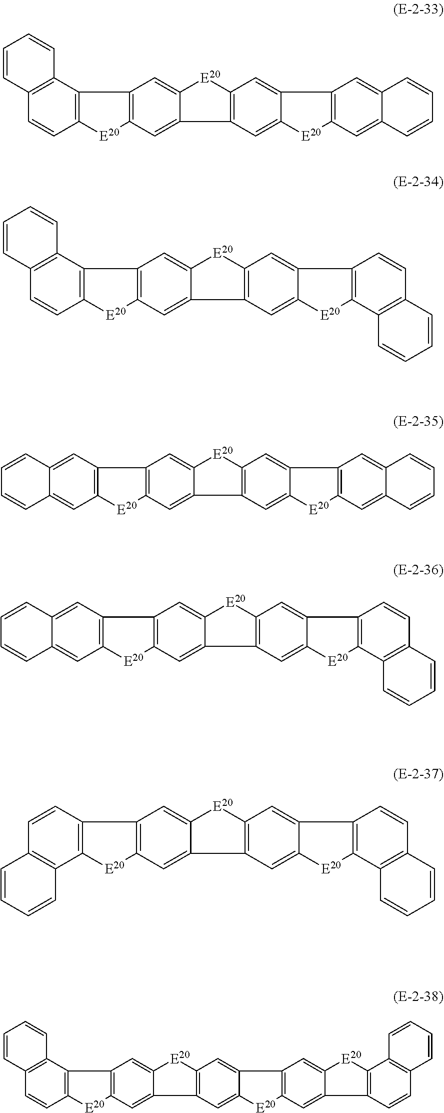

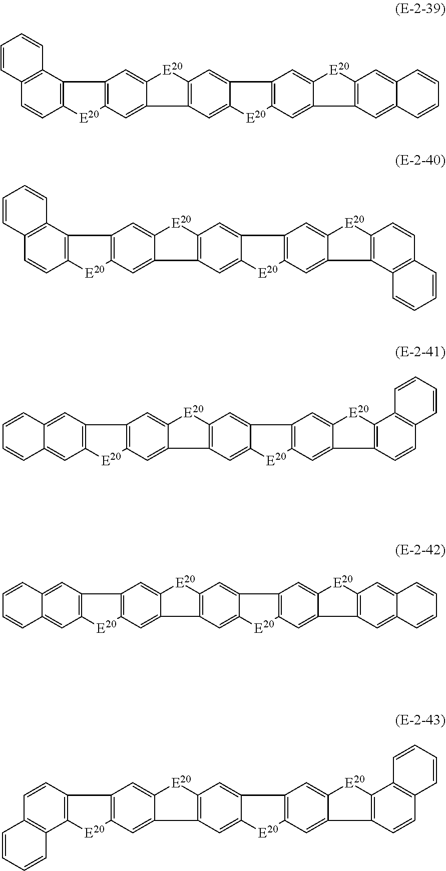

where the groups of formulae (E-2-1) to (E-2-43) may be substituted at all free positions by one or more radicals R; and where E²⁰ has the same definition as above. Preferably, E²⁰ is C(R⁰)₂.

The compounds of formula (E-2) are preferably selected from the compounds of formulae (E-2-32) to (E-2-43). More preferably, the compounds of formula (E-2) are selected from the compounds (E-2-32-A) to (E-2-43-A):

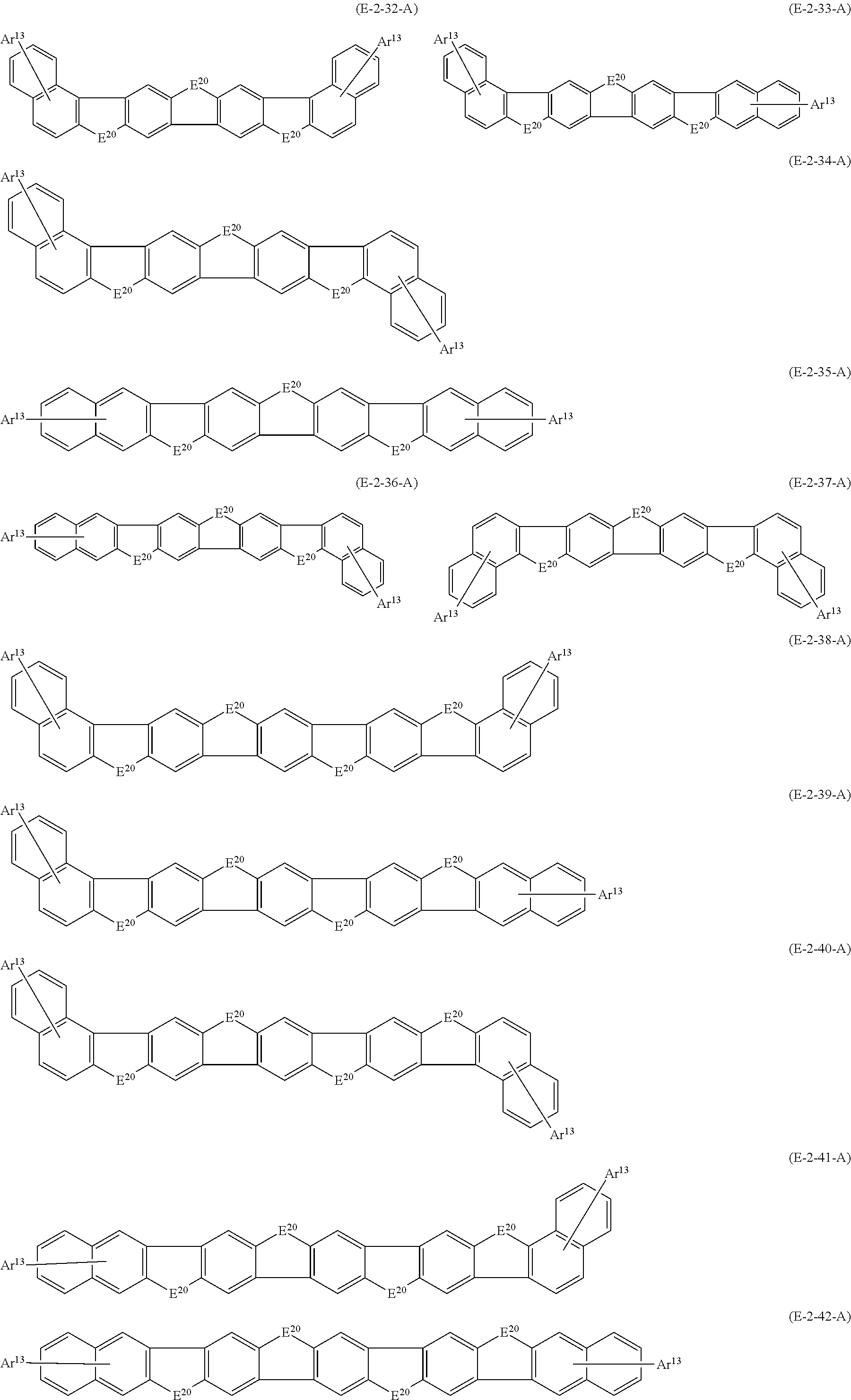

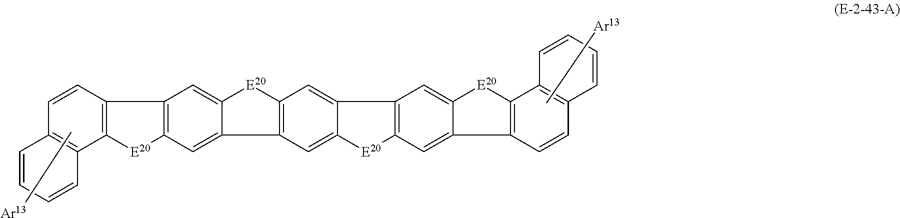

where the symbols have the same meaning as above and where the benzene and naphthalene rings represented above in the compounds of formulae (E-2-32-A) to (E-2-43-A) may be substituted at all free positions by one or more radicals R.

Preferably, the fluorescent emitting compound of formula (E-3) is selected from fluorescent emitting compounds of formula (E-3-1),

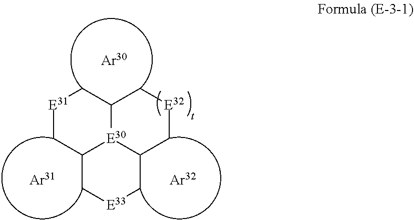

where the symbols and indices have the same meaning as above.

More preferably, the fluorescent emitting compound of formula (E-3) is selected from fluorescent emitting compounds of formula (E-3-2),

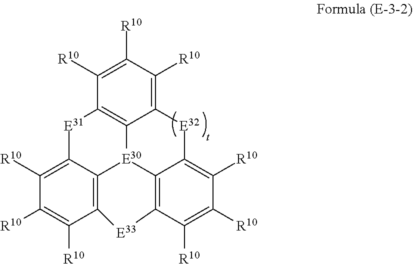

where the symbols E³⁰ to E³³ have the same meaning as above; where t is 0 or 1, wherein when t is 0, the group E³² is absent and radicals R¹⁰ are present, which replace the bonds to E³²; and where

R¹⁰ stands on each occurrence, identically or differently, for H, D, F, Cl, Br, I, CHO, CN, C(═O)Ar, P(═O)(Ar)₂, S(═O)Ar, S(═O)₂Ar, N(R′)₂, N(Ar)₂, NO₂, Si(R′)₃, B(OR′)₂, OSO₂R′, a straight-chain alkyl, alkoxy or thioalkyl group having 1 to 40 C atoms or branched or a cyclic alkyl, alkoxy or thioalkyl group having 3 to 40 C atoms, each of which may be substituted by one or more radicals R′, where in each case one or more non-adjacent CH₂ groups may be replaced by R′C═CR′, C≡C, Si(R′)₂, Ge(R′)₂, Sn(R′)₂, C═O, C═S, C═Se, P(═O)(R′), SO, SO₂, O, S or CONR′ and where one or more H atoms may be replaced by D, F, Cl, Br, I, CN or NO₂, an aromatic or heteroaromatic ring system having 5 to 60 aromatic ring atoms, which may in each case be substituted by one or more radicals R′, or an aryloxy group having 5 to 60 aromatic ring atoms, which may be substituted by one or more radicals R′; where two adjacent substituents R¹⁰ may form an aliphatic or aromatic ring system together, which may be substituted by one or more radicals R′; where R′ has the same definition as above.

Even more preferably, the fluorescent emitting compound of formula (E-3) is selected from fluorescent emitting compounds of formula (E-3-3) and (E-3-4),

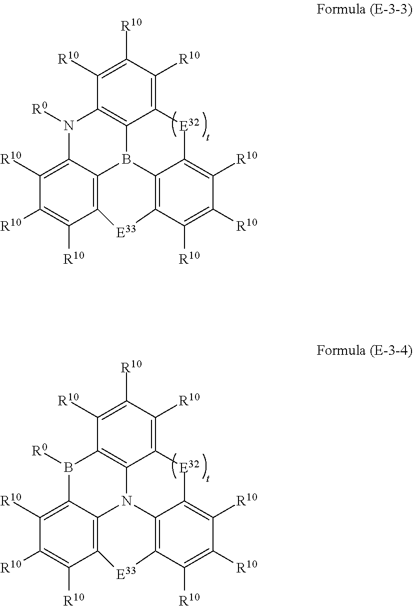

where the symbols and indices have the same meaning as above.

Preferably, the fluorescent emitting compound of formula (E-4) is selected from fluorescent emitting compounds of formula (E-4-1) or (E-4-2),

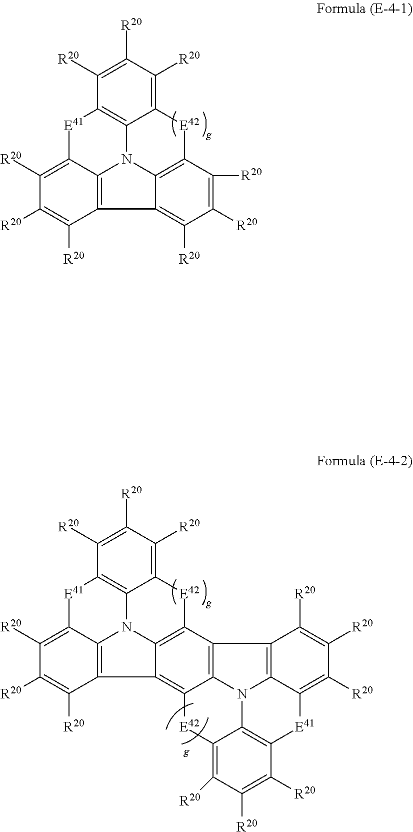

where

E⁴¹ and E⁴² stand on each occurrence, identically or differently, for O, S,) C(R⁰)₂, C═O, C═S, C═NR⁰, C≡C(R⁰)₂, Si(R⁰)₂, BR⁰, NR⁰, PR⁰, SO2, SeO₂ or a chemical bond, where E⁴¹ is preferably bond;

R²⁰ stands on each occurrence, identically or differently, for H, D, F, Cl, Br, I, CHO, CN, C(═O)Ar, P(═O)(Ar)₂, S(═O)Ar, S(═O)₂Ar, N(R′)₂, N(Ar)₂, NO₂, Si(R′)₃, B(OR′)₂, OSO₂R′, a straight-chain alkyl, alkoxy or thioalkyl group having 1 to 40 C atoms or branched or a cyclic alkyl, alkoxy or thioalkyl group having 3 to 40 C atoms, each of which may be substituted by one or more radicals R′, where in each case one or more non-adjacent CH₂ groups may be replaced by R′C═CR′, C≡C, Si(R′)₂, Ge(R′)₂, Sn(R′)₂, C═O, C═S, C═Se, P(═O)(R′), SO, SO₂, O, S or CONR′ and where one or more H atoms may be replaced by D, F, Cl, Br, I, CN or NO₂, an aromatic or heteroaromatic ring system having 5 to 60 aromatic ring atoms, which may in each case be substituted by one or more radicals R′, or an aryloxy group having 5 to 60 aromatic ring atoms, which may be substituted by one or more radicals R′; where two adjacent substituents R₂₀ may form an aliphatic or aromatic ring system together, which may be substituted by one or more radicals R′; where R′ has the same definition as above; g is 0 or 1.

More preferably, the fluorescent emitting compound of formula (E-4) is selected from fluorescent emitting compounds of formula (E-4-1-A) or (E-4-2-A),

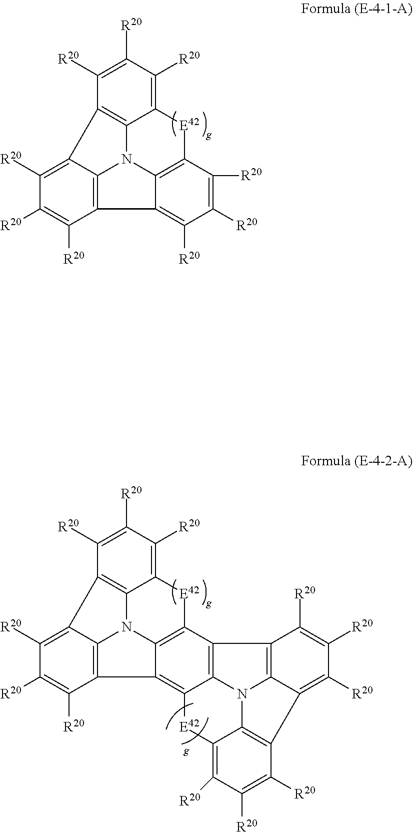

where the symbols have the same meaning as above.

In accordance with a preferred embodiment, the fluorescent emitting compound of formula (E-1), (E-2), (E-3) or (E-4) comprises a group RS, wherein the group RS is selected:
from branched or cyclic alkyl groups represented by the general following formula a group of formula (RS-a),

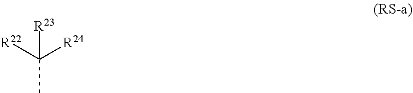

wherein

R²², R²³, R²⁴ are at each occurrence, identically or differently, selected from H, a straight-chain alkyl group having 1 to 10 carbon atoms, or a branched or cyclic alkyl group having 3 to 10 carbon atoms, where the above-mentioned groups may each be substituted by one or more radicals R²⁵, and where two of radicals R²², R²³, R²⁴ or all radicals R²², R²³, R²⁴ may be joined to form a (poly)cyclic alkyl group, which may be substituted by one or more radicals R²⁵;

R²⁵ is at each occurrence, identically or differently, selected from a straight-chain alkyl group having 1 to 10 carbon atoms, or a branched or cyclic alkyl group having 3 to 10 carbon atoms;

with the proviso that at each occurrence at least one of radicals R²², R²³ and R²⁴ is other than H, with the proviso that at each occurrence all of radicals R²², R²³ and R²⁴ together have at least 4 carbon atoms and with the proviso that at each occurrence, if two of radicals R²², R²³, R²⁴ are H, the remaining radical is not a straight-chain; or
from branched or cyclic alkoxy groups represented by the general following formula (RS-b)

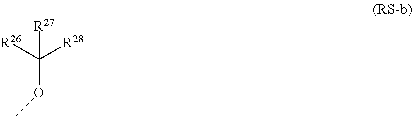

wherein

R²⁶, R²⁷, R²⁸ are at each occurrence, identically or differently, selected from H, a straight-chain alkyl group having 1 to 10 carbon atoms, or a branched or cyclic alkyl group having 3 to 10 carbon atoms, where the above-mentioned groups may each be substituted by one or more radicals R²⁵ as defined above, and where two of radicals R²⁶, R²⁷, R²⁸ or all radicals R²⁶, R²⁷, R²⁸ may be joined to form a (poly)cyclic alkyl group, which may be substituted by one or more radicals R²⁵ as defined above;

with the proviso that at each occurrence only one of radicals R²⁶, R²⁷ and R²⁸ may be H;
from aralkyl groups represented by the general following formula (RS-c)

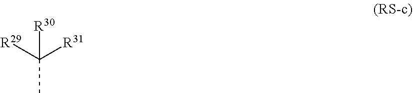

wherein

R²⁹, R³⁰, R³¹ are at each occurrence, identically or differently, selected from H, a straight-chain alkyl group having 1 to 10 carbon atoms, or a branched or cyclic alkyl group having 3 to 10 carbon atoms, where the above-mentioned groups may each be substituted by one or more radicals R³², or an aromatic ring system having 6 to 30 aromatic ring atoms, which may in each case be substituted by one or more radicals R³², and where two or all of radicals R²⁹, R³⁰, R³¹ may be joined to form a (poly)cyclic alkyl group or an aromatic ring system, each of which may be substituted by one or more radicals R³²;

R³² is at each occurrence, identically or differently, selected from a straight-chain alkyl group having 1 to 10 carbon atoms, or a branched or cyclic alkyl group having 3 to 10 carbon atoms, or an aromatic ring system having 6 to 24 aromatic ring atoms;

with the proviso that at each occurrence at least one of radicals R²⁹, R³⁰ and R³¹ is other than H and that at each occurrence at least one of radicals R²⁹, R³⁰ and R³¹ is or contains an aromatic ring system having at least 6 aromatic ring atoms;
from aromatic ring systems represented by the general following formula (RS-d)

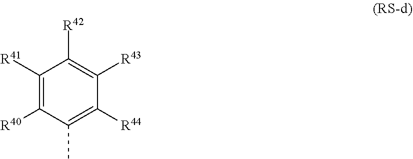

wherein

R⁴⁰ to R⁴⁴ is at each occurrence, identically or differently, selected from H, a straight-chain alkyl group having 1 to 10 carbon atoms, or a branched or cyclic alkyl group having 3 to 10 carbon atoms, where the above-mentioned groups may each be substituted by one or more radicals R³², or an aromatic ring system having 6 to 30 aromatic ring atoms, which may in each case be substituted by one or more radicals R³², and where two or more of radicals R⁴⁰ to R⁴⁴ may be joined to form a (poly)cyclic alkyl group or an aromatic ring system, each of which may be substituted by one or more radicals R³² as defined above; or
from groups of formula (RS-e),

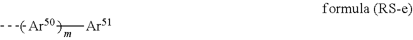

where the dashed bond in formula (RS-e) indicates the bonding to the fluorescent emitting compound, where Ar⁵⁰, Ar⁵¹ stand on each occurrence, identically or differently, for an aromatic or heteroaromatic ring systems having 5 to 60 aromatic ring atoms, which may in each case be substituted by one or more radicals R; and where m is an integer selected from 1 to 10.

Preferably, the index m in the group of formula (RS-e) is an integer selected from 1 to 6, very preferably from 1 to 4.

Preferably, Ar⁵⁰, Ar⁵¹ stand on each occurrence, identically or differently, for an aromatic or heteroaromatic ring systems having 5 to 40, preferably 5 to 30, more preferably 6 to 18 aromatic ring atoms, which may in each case be substituted by one or more radicals R. More preferably, Ar⁵⁰, Ar⁵¹ are selected from phenyl, biphenyl, terphenyl, quaterphenyl, fluorene, spirobifluorene, naphthalene, anthracene, phenanthrene, triphenylene, fluoranthene, dibenzofuran, carbazole and dibenzothiophene, which may in each case be substituted by one or more radicals R. Very preferably, at least one group Ar⁵⁰ or Ar⁵¹ is a fluorene, which may be substituted by one or more radicals R.

More particularly, it is preferred that at least one group Ar⁵⁰ stands for a group of formula (Ar50-2) and/or at least one group Ar⁵¹ stands for a group of formula (Ar51-2),

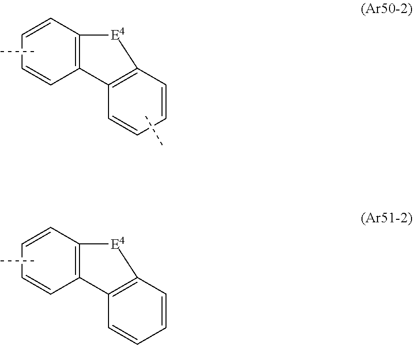

where
the dashed bonds in formula (Ar50-2) indicate the bonding to the fluorescent emitting compound and to a group Ar⁵⁰ or Ar⁵¹; and the dashed bond in formula (Ar51-2) indicates the bonding to Ar⁵⁰;

E⁴ is selected from —C(R^{0a})_{2—}, —Si(R^{0a})_{2—}, —O—, —S— or —N(R^{0a})—, preferably —C(R^{0a})₂; R^{0a} stands on each occurrence, identically or differently, for H, D, F, CN, a straight-chain alkyl group having 1 to 40, preferably 1 to 20, more preferably 1 to 10 C atoms or branched or cyclic alkyl group having 3 to 40, preferably 3 to 20, more preferably 3 to 10 C atoms, each of which may be substituted by one or more radicals R, an aromatic or heteroaromatic ring system having 5 to 60, preferably 5 to 40, more preferably 5 to 30, very preferably 5 to 18 aromatic ring atoms, which may in each case be substituted by one or more radicals R; where two adjacent substituents R^{0a} may form a mono- or polycyclic, aliphatic ring system or aromatic ring system, which may be substituted by one or more radicals R, which has the same meaning as above; and
the groups of formulae (Ar50-2) and (Ar51-2) may be substituted at each free position by a group R, which has the same meaning as above.

The group RS is preferably located at a position, where it replaces R, R⁰ or R′.

Examples of suitable fluorescent emitting compounds, when the compound EA or the emitting compound E1 is a fluorescent emitting compound, are aromatic anthracenamines, aromatic anthracenediamines, aromatic pyrenamines, aromatic pyrenediamines, aromatic chrysenamines or aromatic chrysenediamines. An aromatic anthracenamine is taken to mean a compound in which one diarylamino group is bonded directly to an anthracene group, preferably in the 9-position. An aromatic anthracene-diamine is taken to mean a compound in which two diarylamino groups are bonded directly to an anthracene group, preferably in the 9,10-position. Aromatic pyrenamines, pyrenediamines, chrysenamines and chrysene-diamines are defined analogously thereto, where the diarylamino groups are preferably bonded to the pyrene in the 1-position or in the 1,6-position. Further preferred emitting compounds are bridged triarylamines, for example in accordance with WO 2019/111971, WO2019/240251 and WO 2020/067290. Further preferred emitting compounds are indenofluorenamines or indenofluorenediamines, for example in accordance with WO 2006/108497 or WO 2006/122630, benzoindenofluorenamines or benzoindenofluorenediamines, for example in accordance with WO 2008/006449, and dibenzoindenofluorenamines or dibenzoindenofluorenediamines, for example in accordance with WO 2007/140847, and the indenofluorene derivatives containing condensed aryl groups which are disclosed in WO 2010/012328. Still further preferred emitting compounds are benzanthracene derivatives as disclosed in WO 2015/158409, anthracene derivatives as disclosed in WO 2017/036573, fluorene dimers connected via heteroaryl groups like in WO 2016/150544 or phenoxazine derivatives as disclosed in WO 2017/028940 and WO 2017/028941. Preference is likewise given to the pyrenarylamines disclosed in WO 2012/048780 and WO 2013/185871. Preference is likewise given to the benzoindenofluorenamines disclosed in WO 2014/037077, the benzo-fluorenamines disclosed in WO 2014/106522 and the indenofluorenes disclosed in WO 2014/111269 or WO 2017/036574, WO 2018/007421. Also preferred are the emitting compounds comprising dibenzofuran or indenodibenzofuran moieties as disclosed in WO 2018/095888, WO 2018/095940, WO 2019/076789, WO 2019/170572 as well as in the unpublished applications PCT/EP2019/072697, PCT/EP2019/072670 and PCT/EP2019/072662. Preference is likewise given to boron derivatives as disclosed, for example, in WO 2015/102118, CN108409769, CN107266484, WO2017195669, US2018069182 as well as in the unpublished applications EP 19168728.4, EP 19199326.0 and EP 19208643.7. Very suitable fluorescent emitting compounds are the indenofluorene derivatives disclosed in WO 2018/007421 and the dibenzofuran derivatives disclosed in WO 2019/076789.

Examples of particularly suitable fluorescent emitting compounds, when the compound EA or the emitting compound E1 is a fluorescent emitting compound, are depicted in the following table:

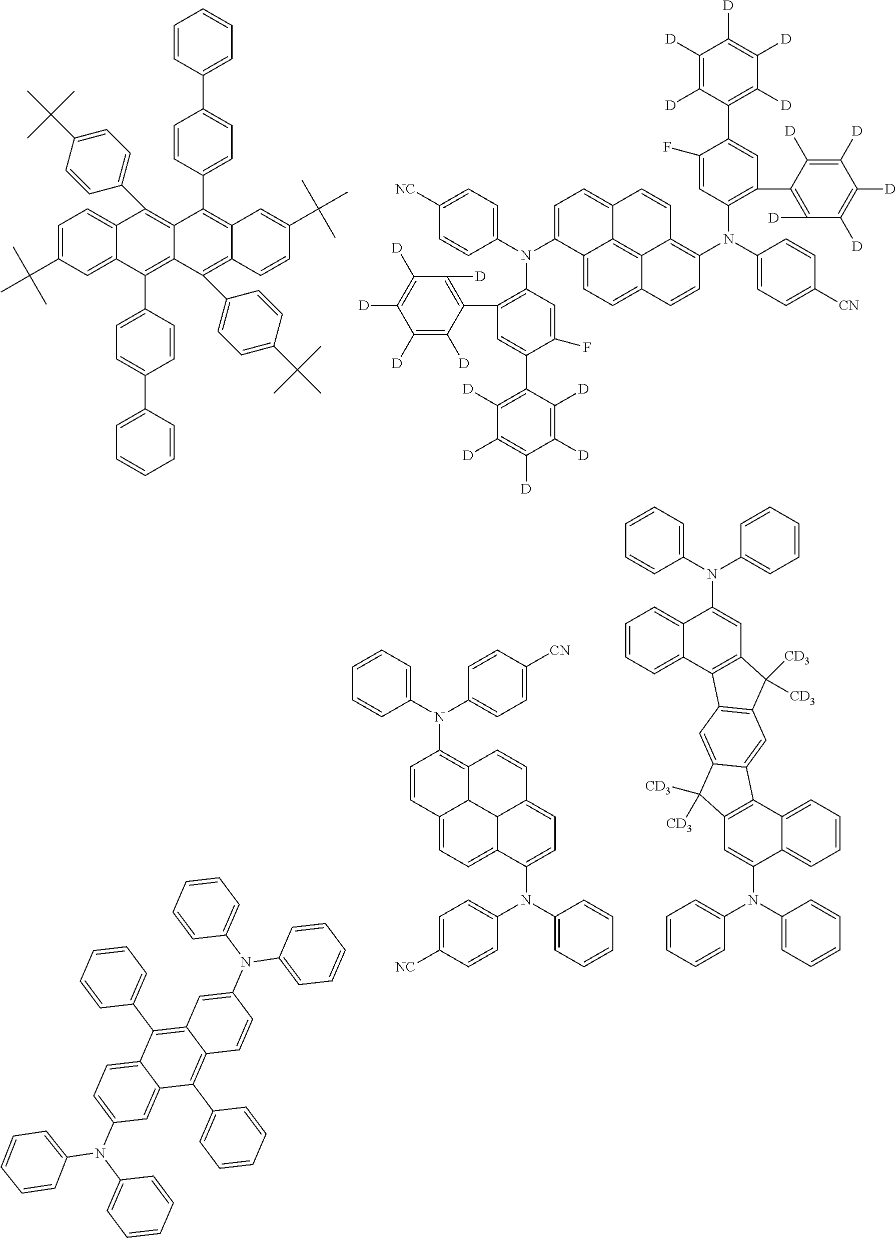

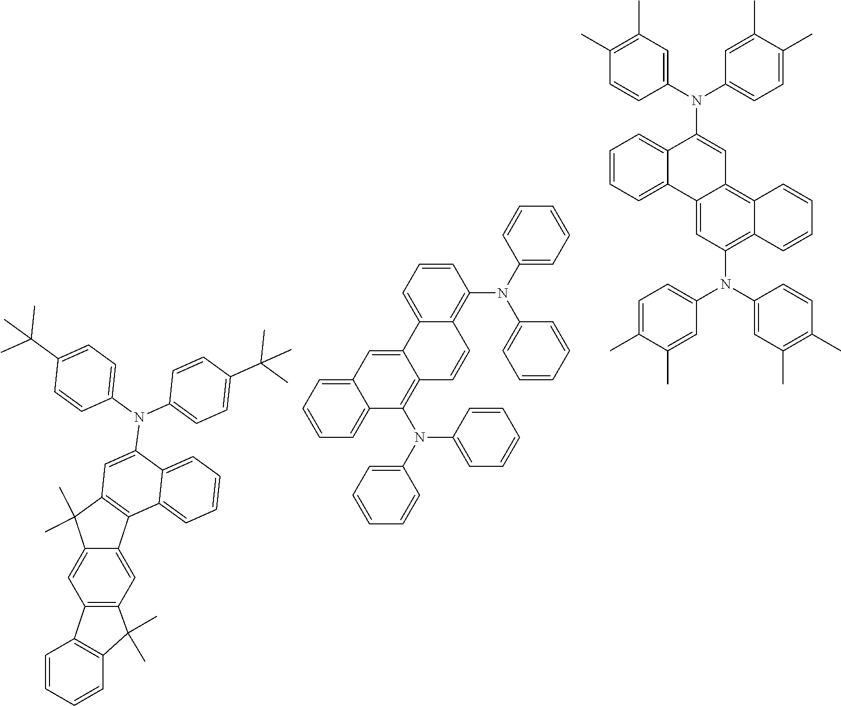

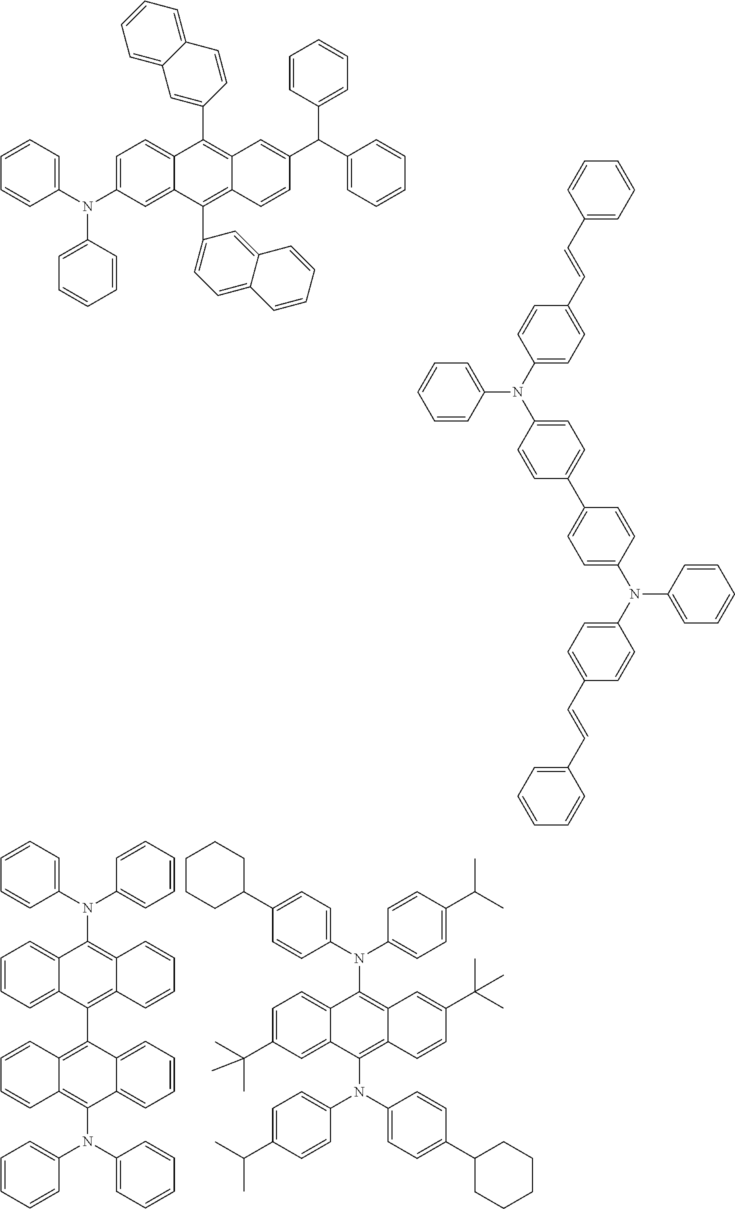

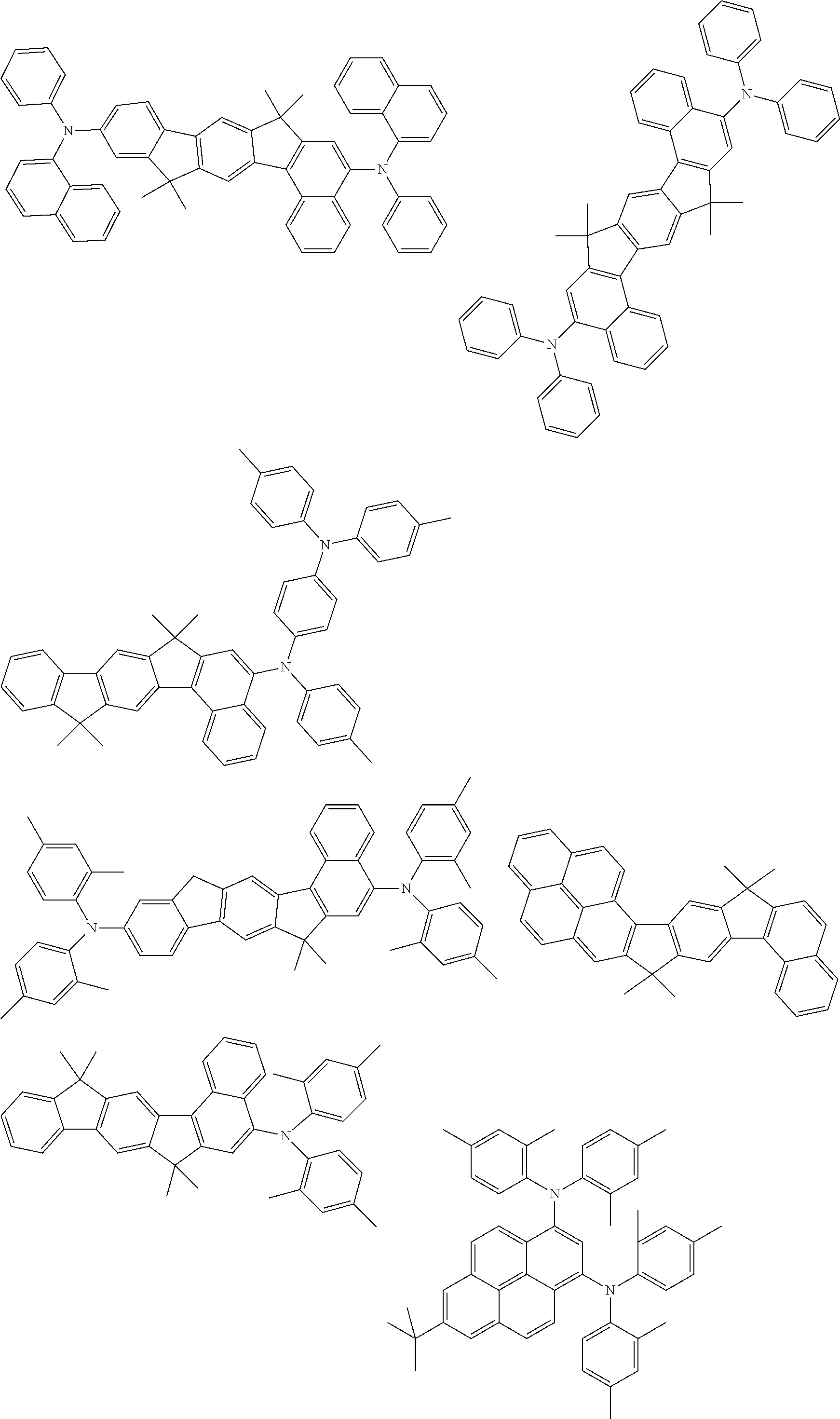

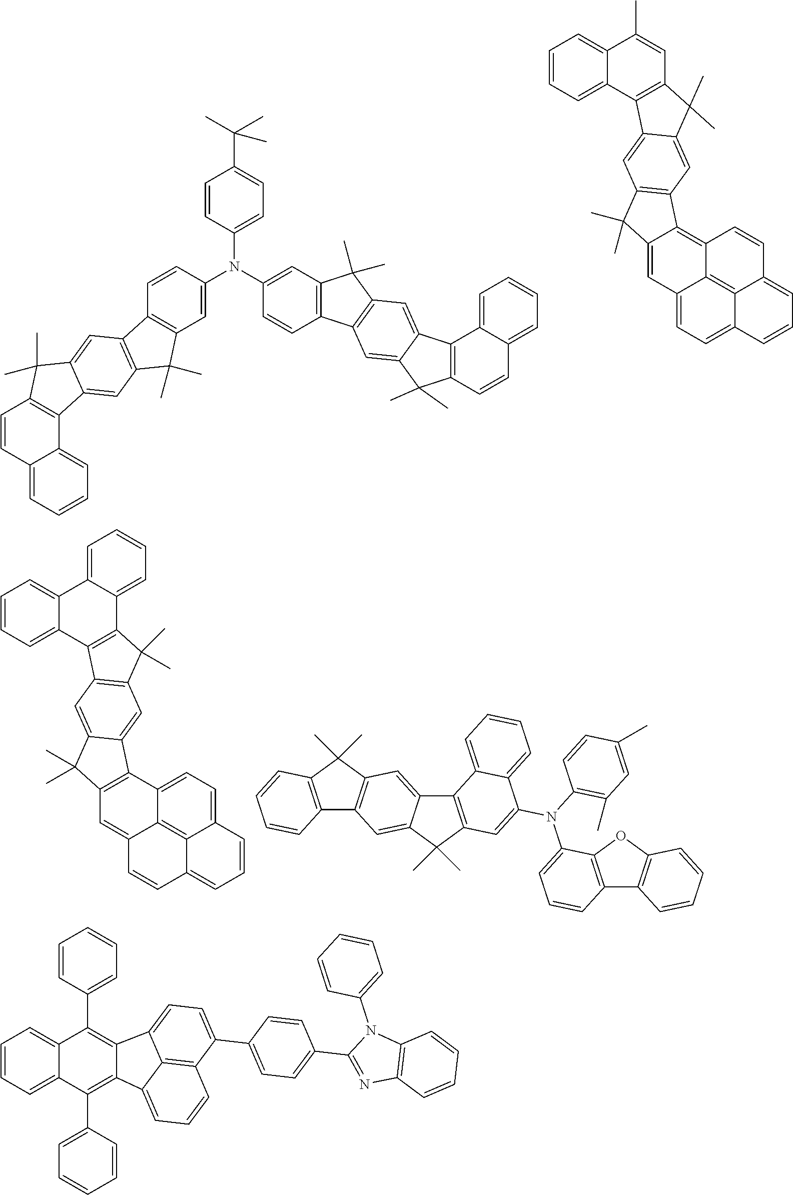

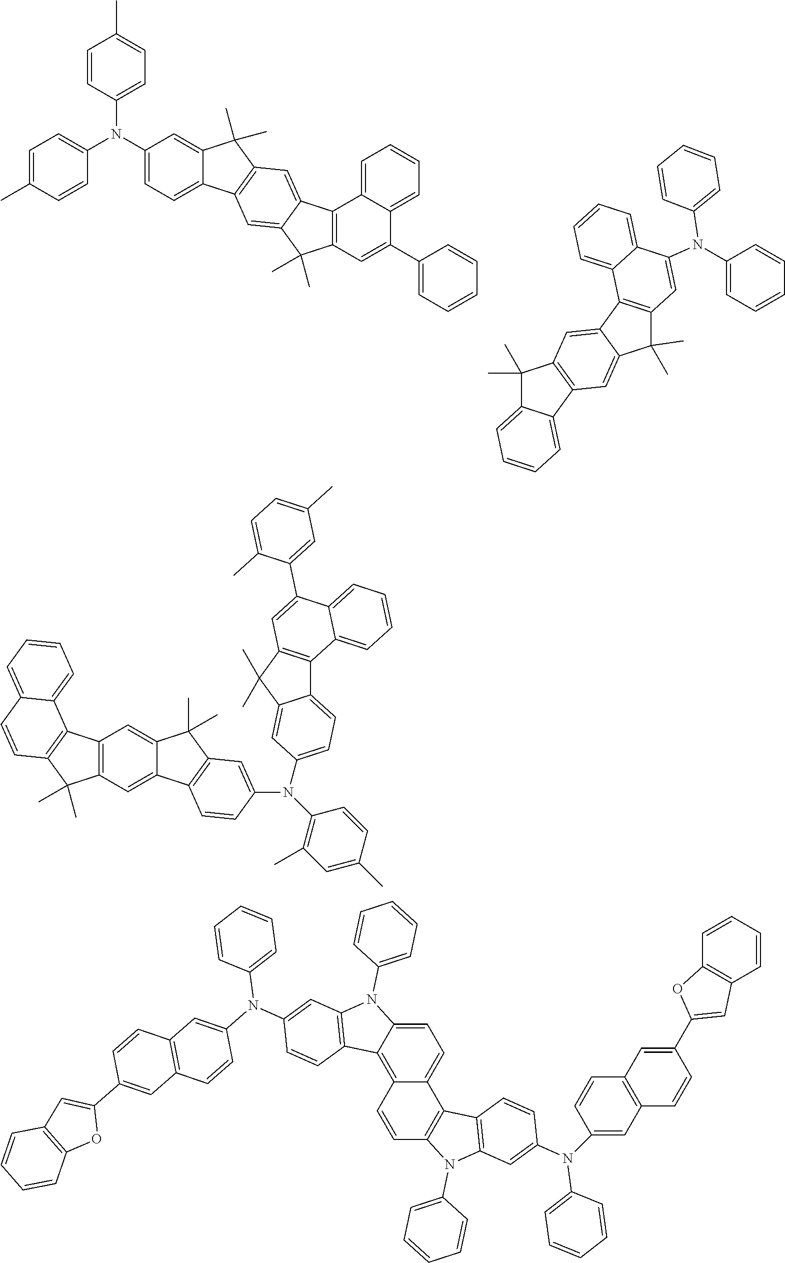

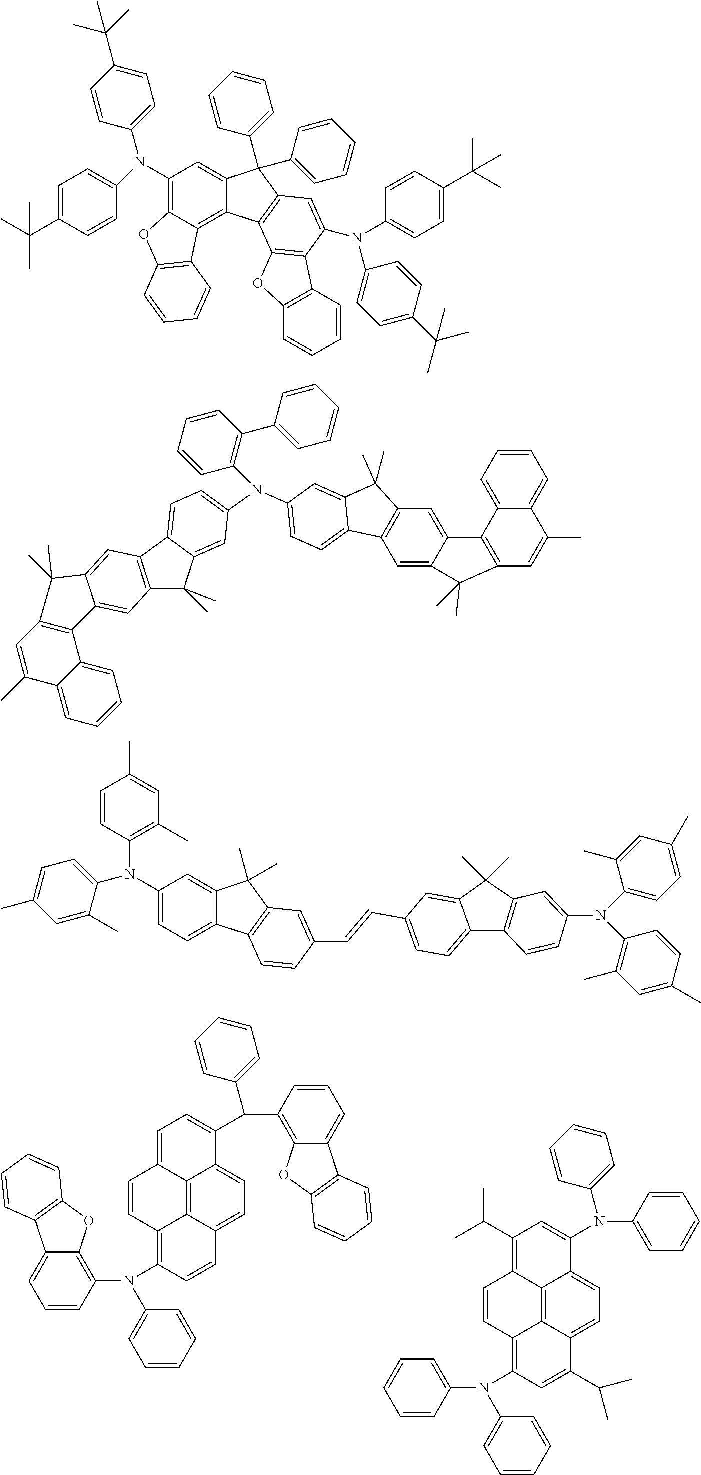

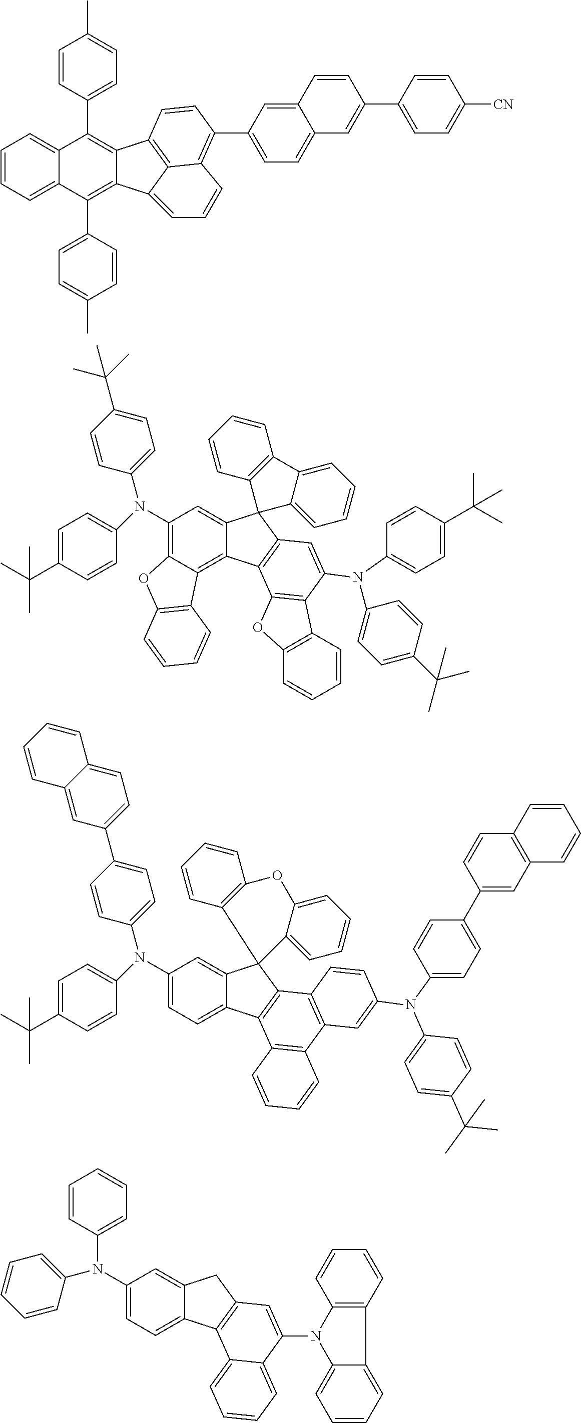

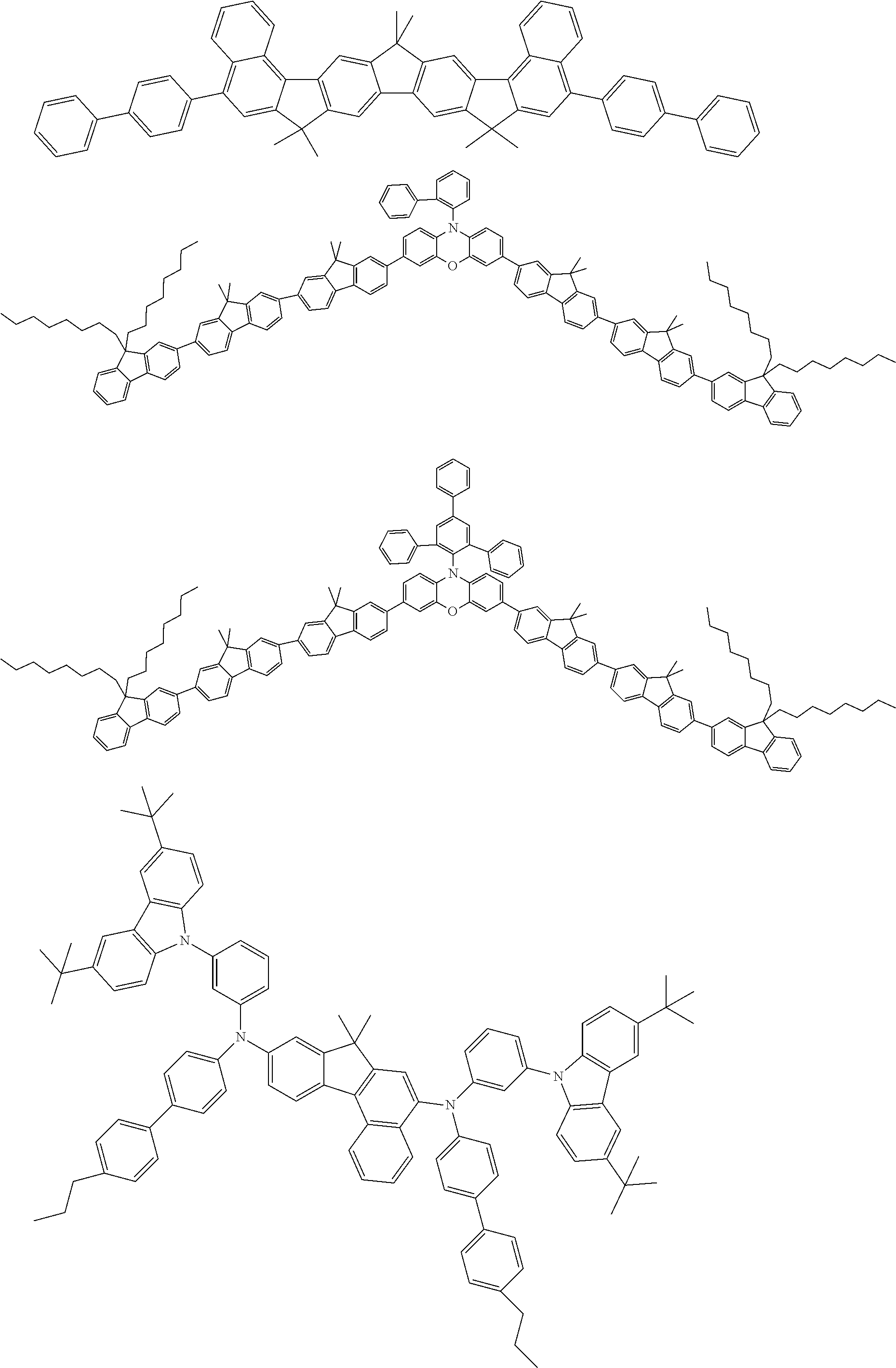

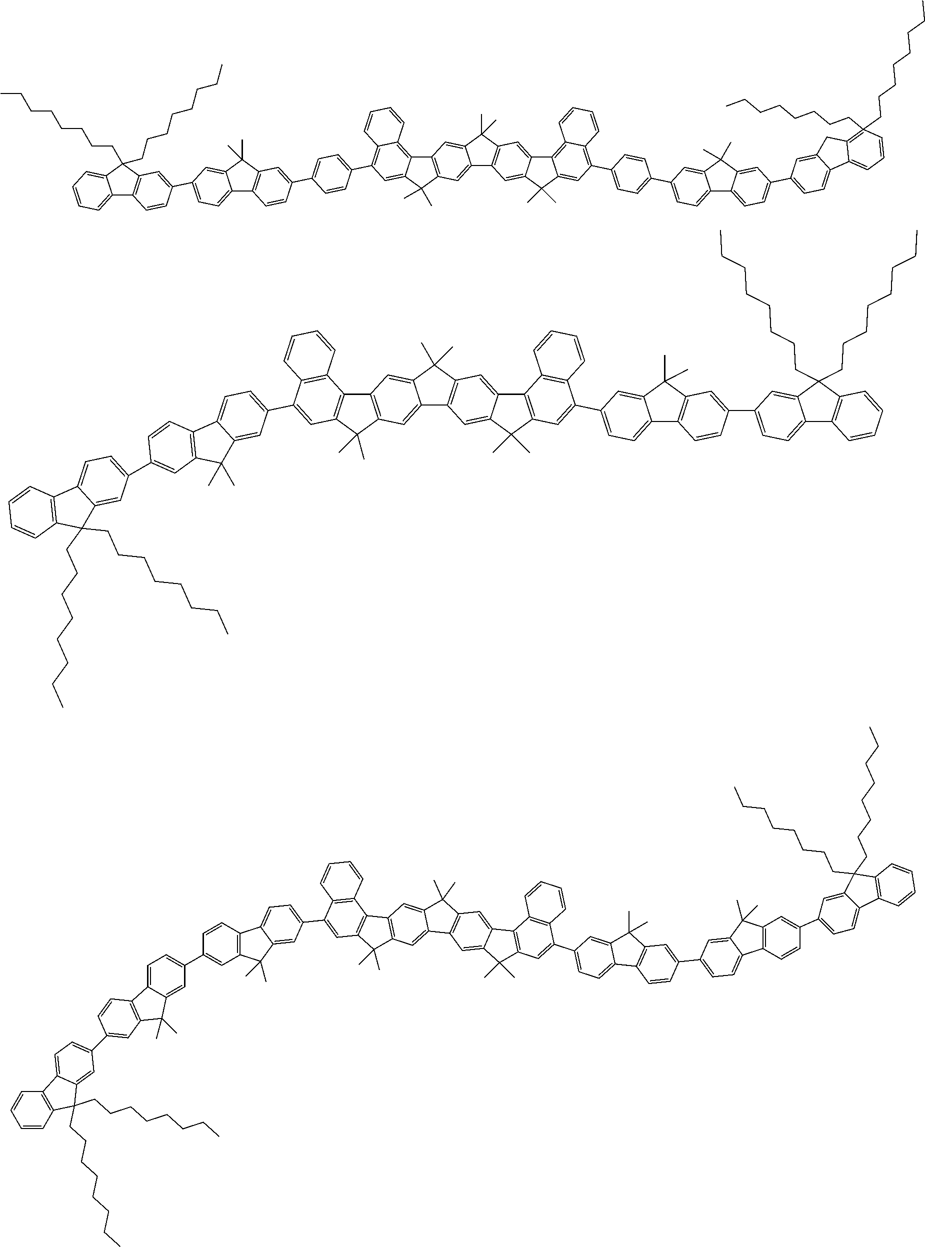

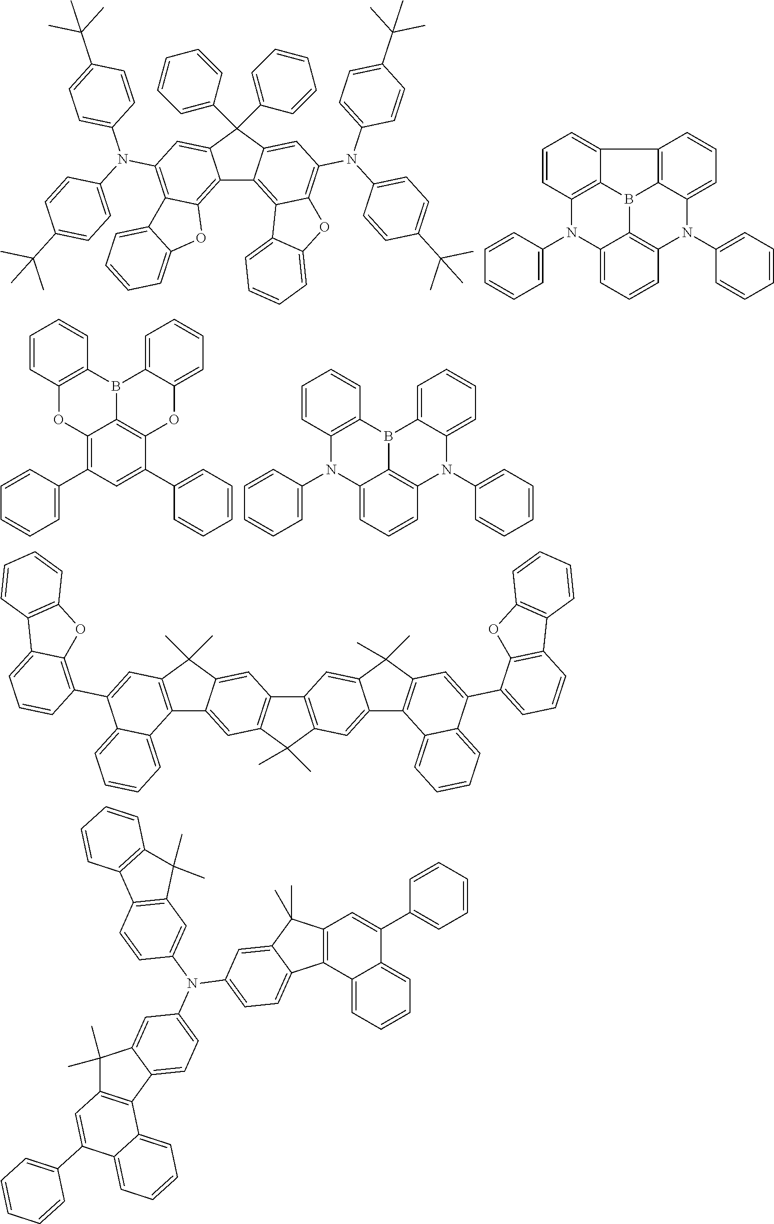

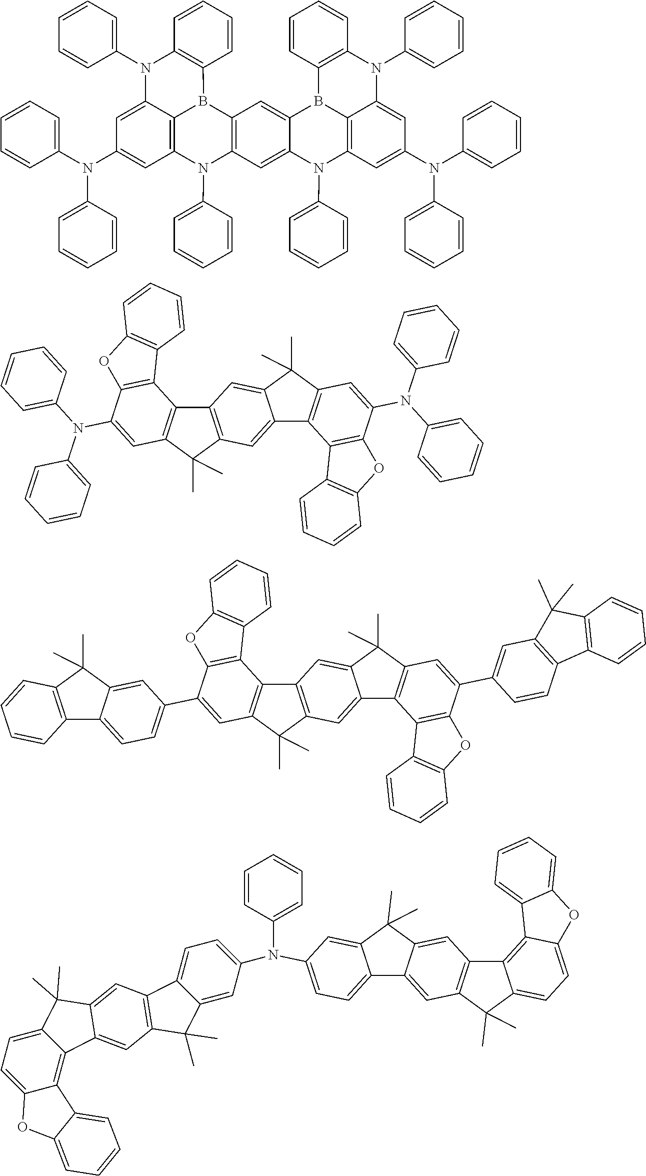

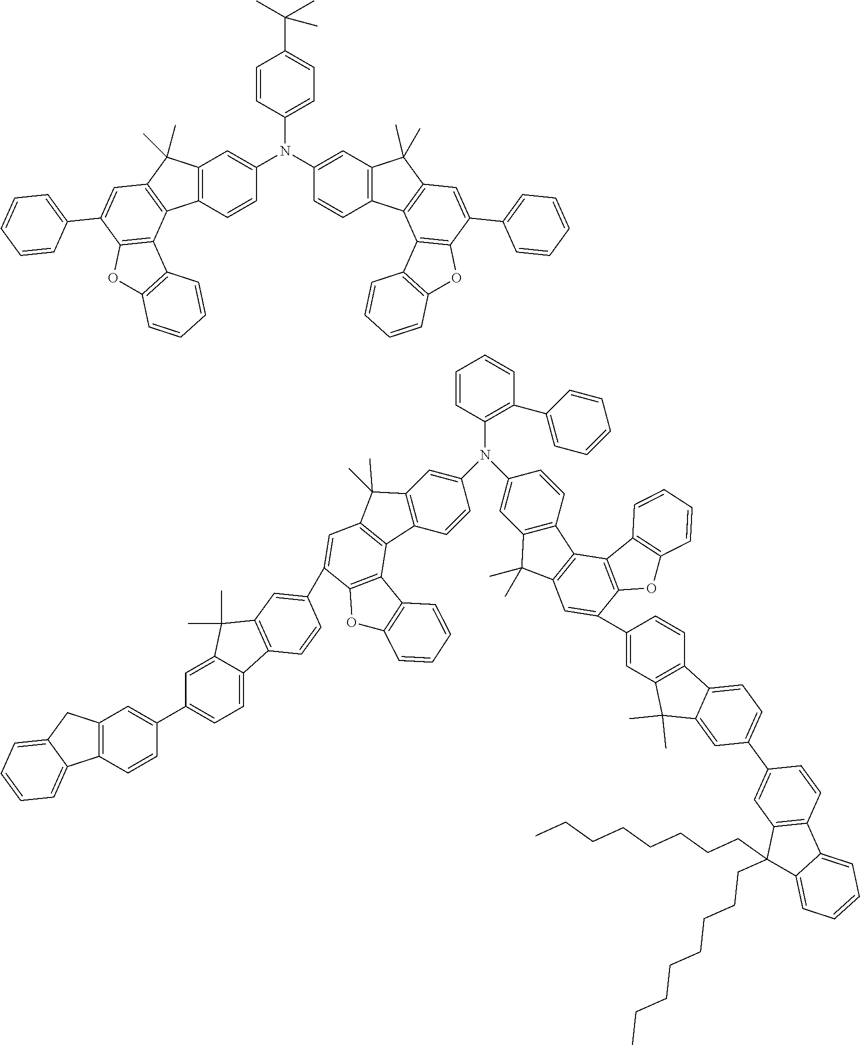 [SMILES: CC(C)(C)c1ccc(N(c2ccc3c(c2)C(C)(C)c2cc(-c4ccccc4)c4oc5ccccc5c4c2-3)c2ccc3c(c2)C(C)(C)c2cc(-c4ccccc4)c4oc5ccccc5c4c2-3)cc1 ; CCCCCCCCC1(CCCCCCCC)c2ccccc2-c2ccc(-c3ccc4c(c3)C(C)(C)c3cc(-c5cc6c(c7c5oc5ccccc57)-c5ccc(N(c7ccc8c(c7)C(C)(C)c7cc(-c9ccc%10c(c9)C(C)(C)c9cc(-c%11ccc%12c(c%11)Cc%11ccccc%11-%12)ccc9-%10)c9oc%10ccccc%10c9c7-8)c7ccccc7-c7ccccc7)cc5C6(C)C)ccc3-4)cc21]

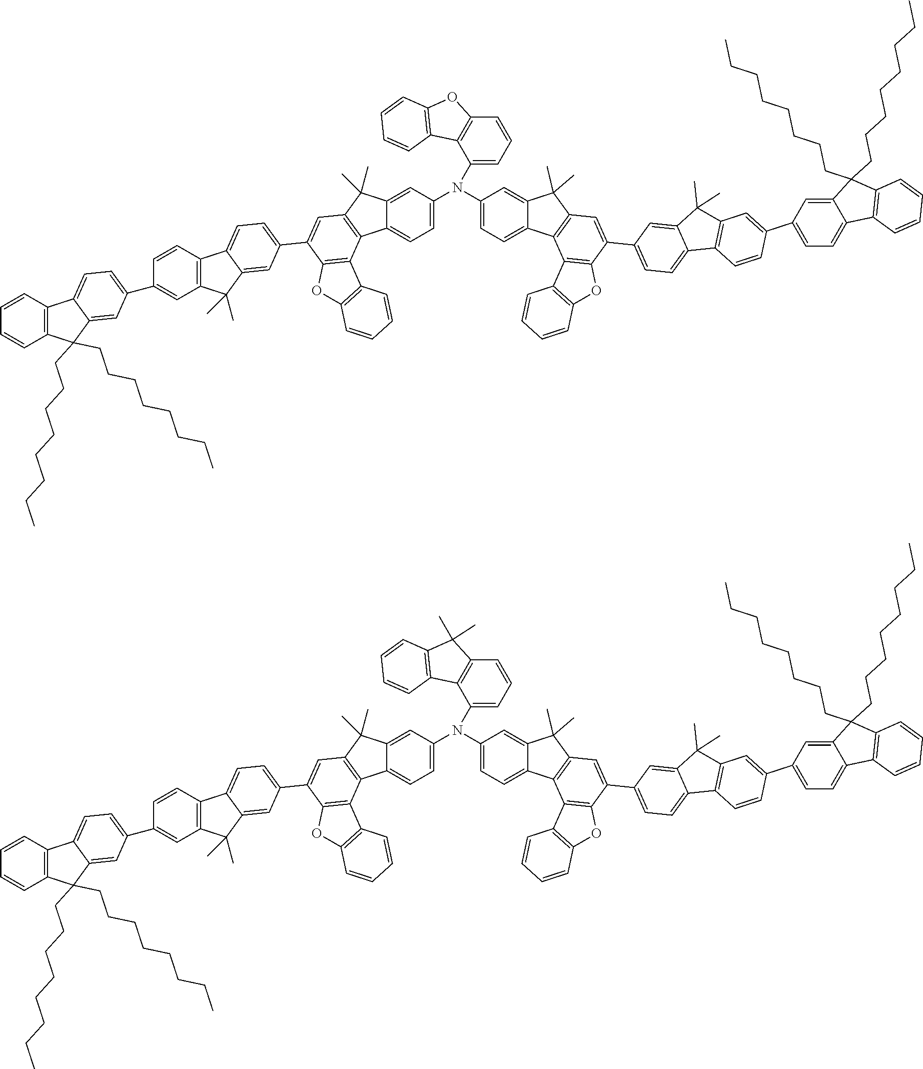

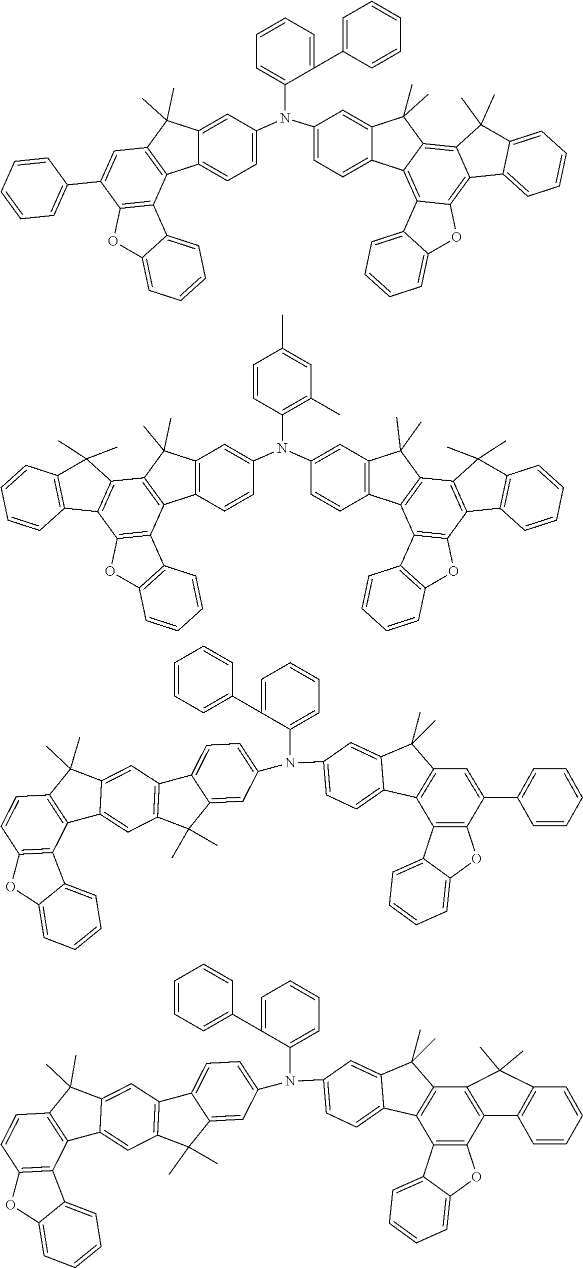

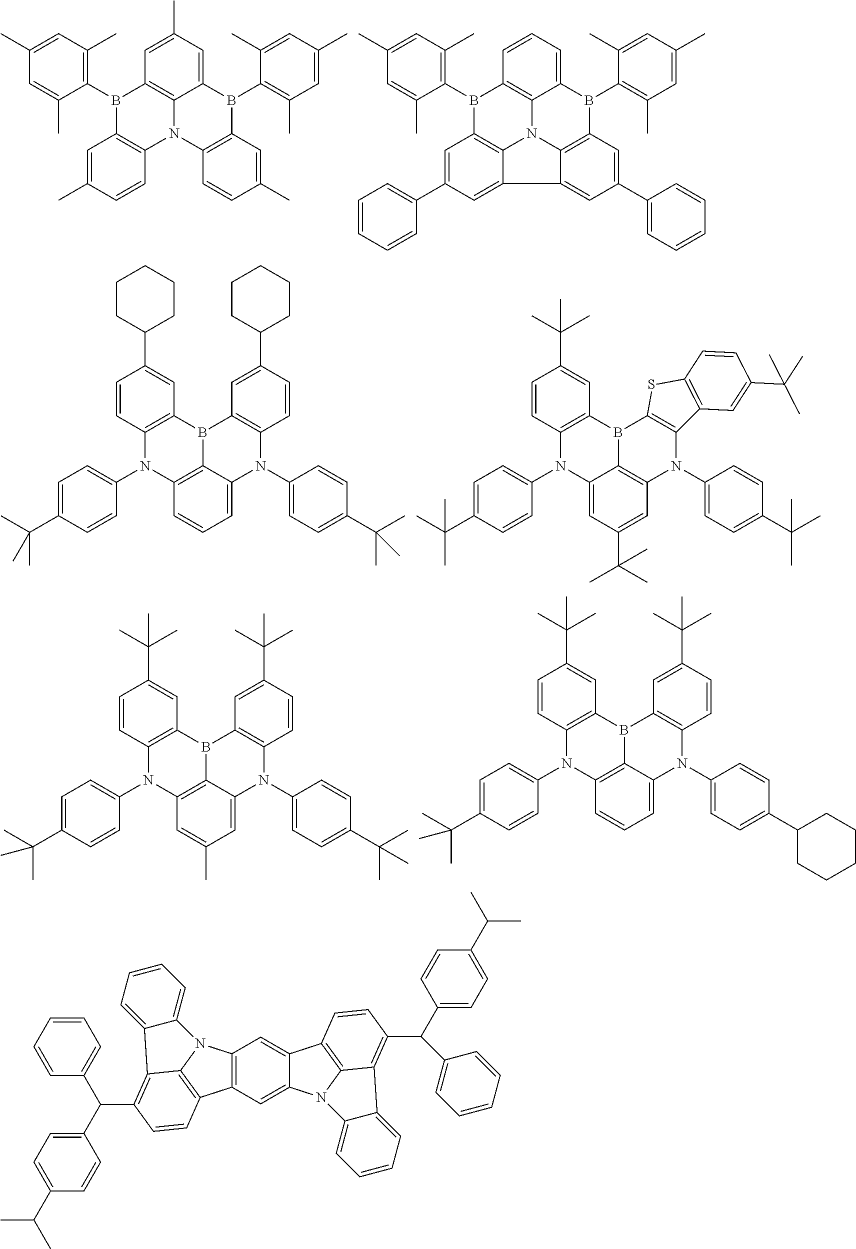

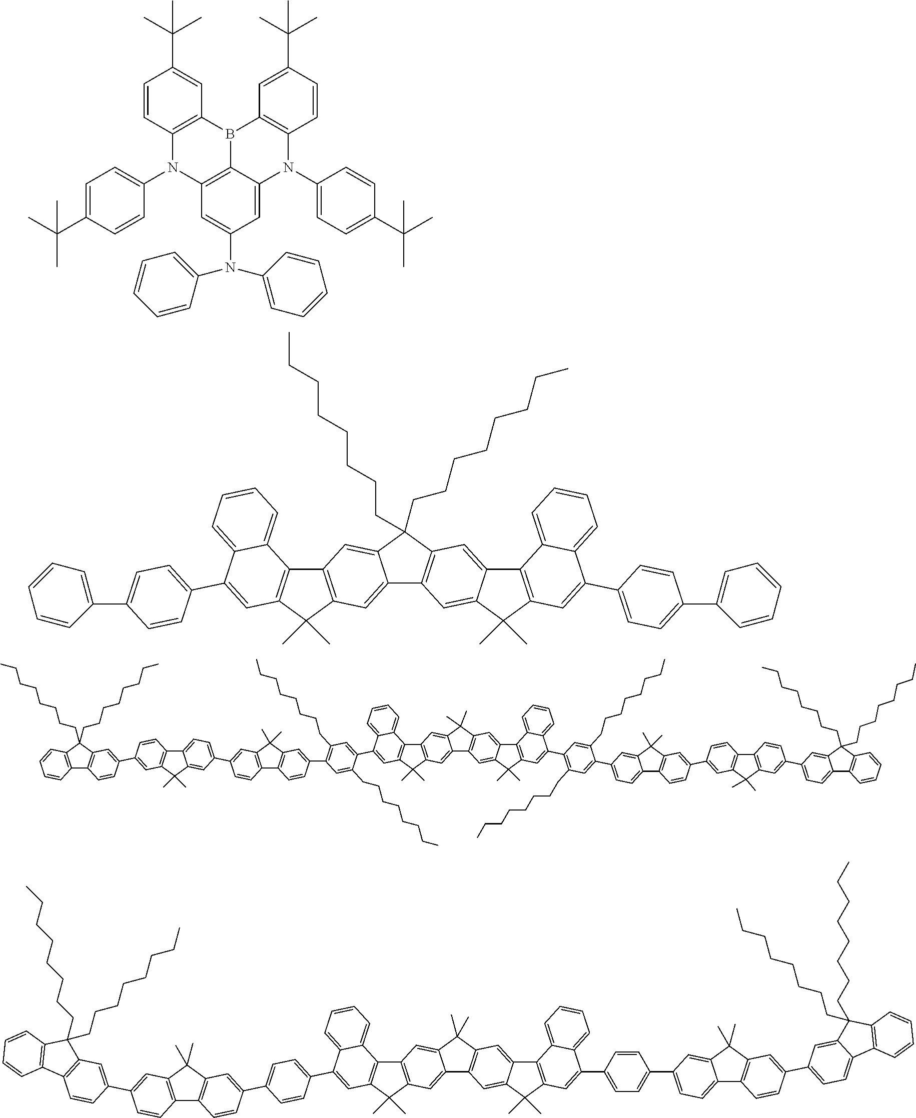

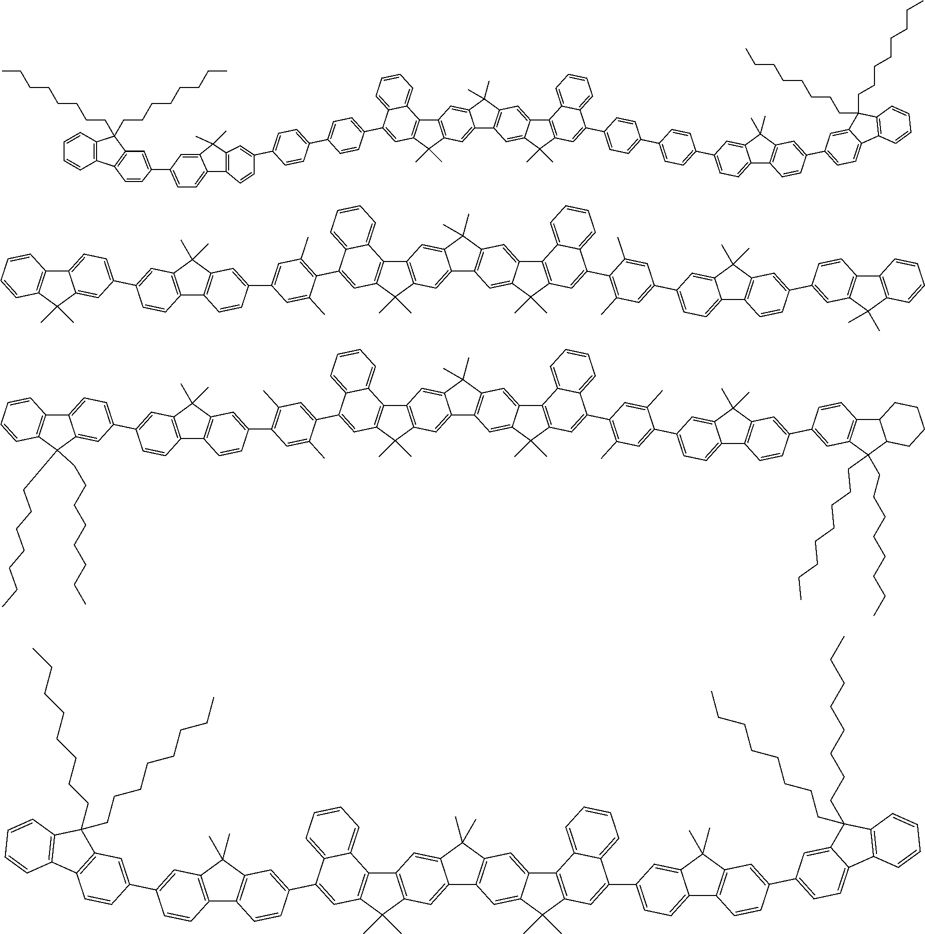

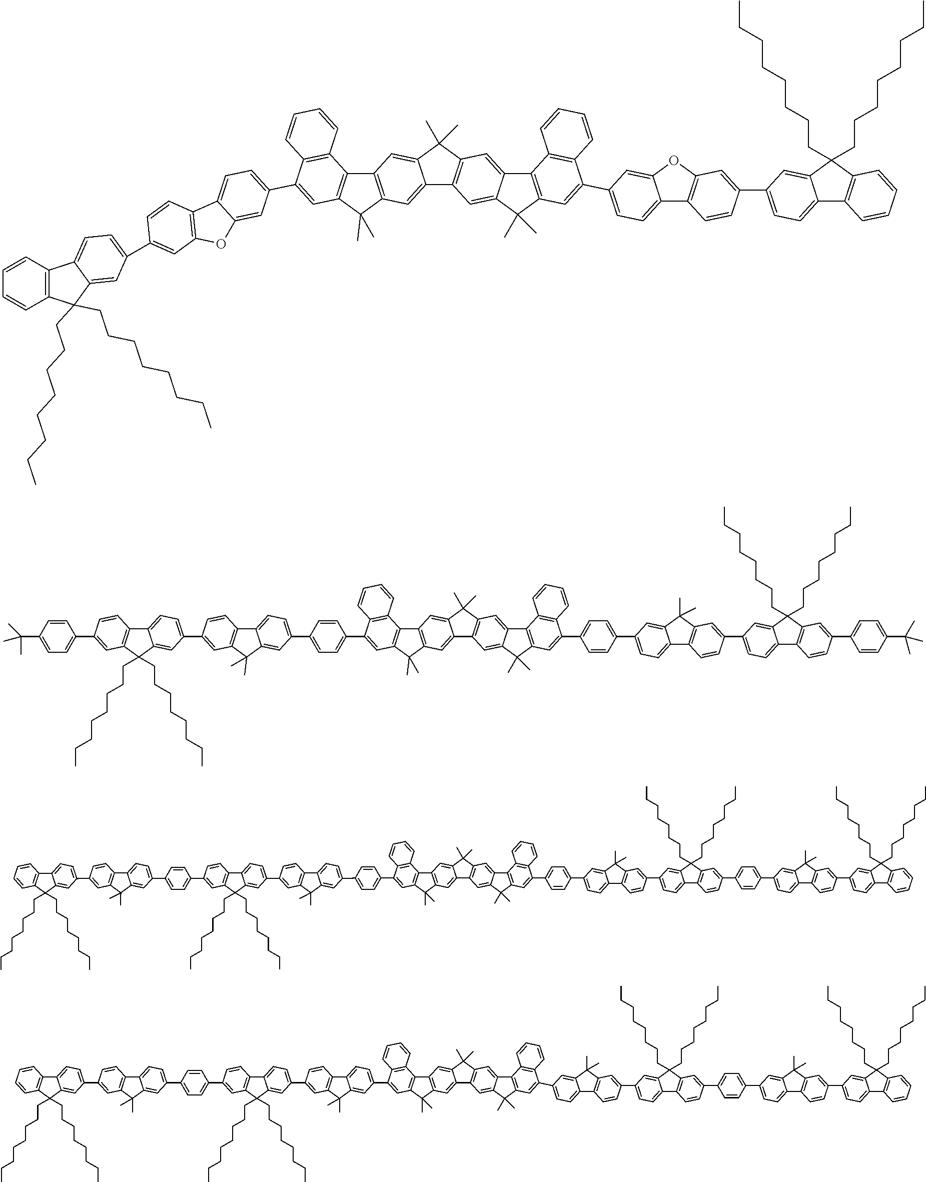

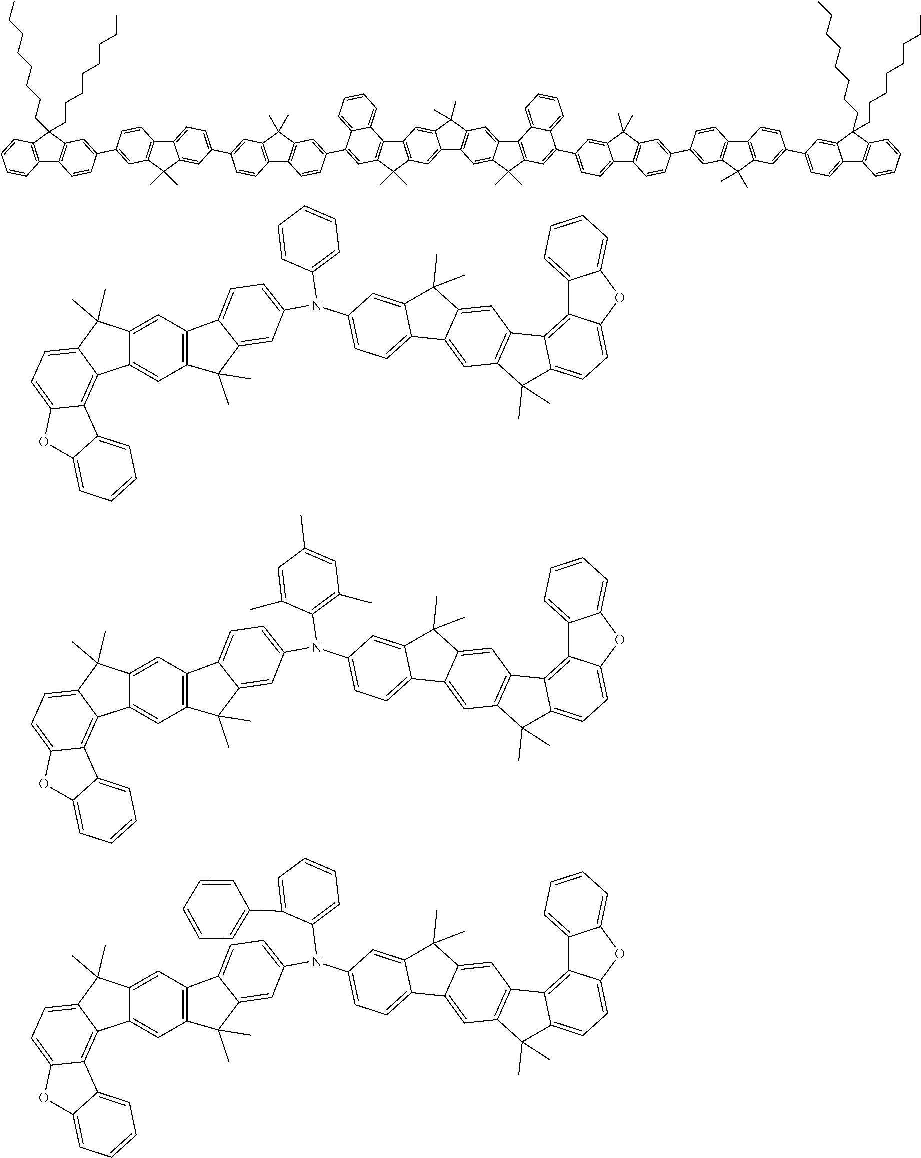

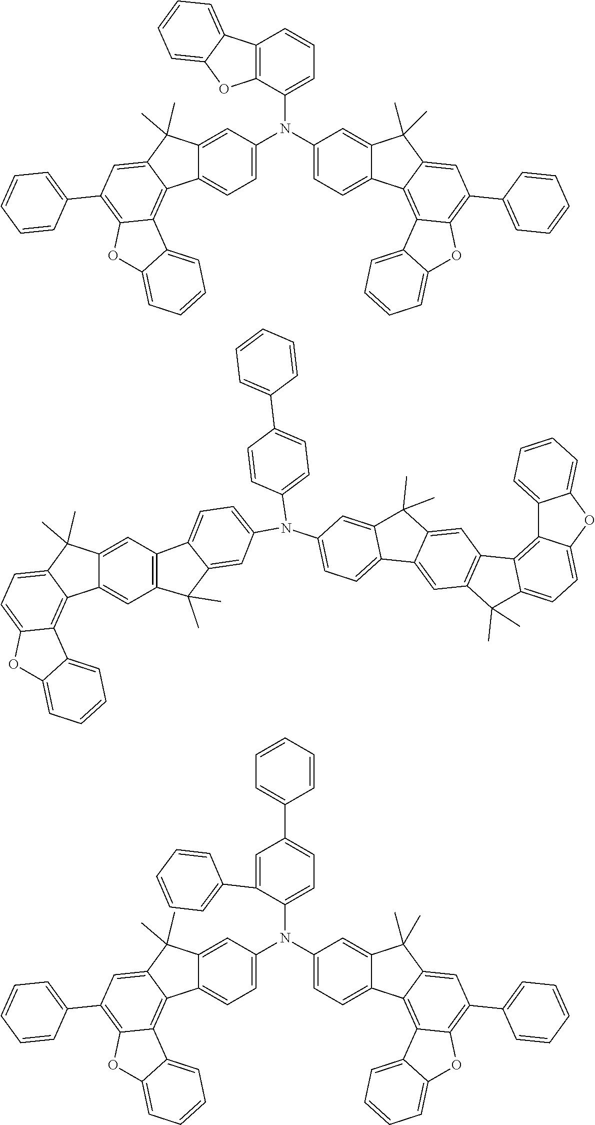 [SMILES: CC1(C)c2cc(N(c3ccc4c(c3)C(C)(C)c3cc(-c5ccccc5)c5oc6ccccc6c5c3-4)c3cccc4c3oc3ccccc34)ccc2-c2c1cc(-c1ccccc1)c1oc3ccccc3c21 ; CC1(C)c2cc(N(c3ccc(-c4ccccc4)cc3)c3ccc4c(c3)C(C)(C)c3cc5c(cc3-4)C(C)(C)c3ccc4oc6ccccc6c4c3-5)ccc2-c2cc3c(cc21)-c1c(ccc2oc4ccccc4c12)C3(C)C ; CC1(C)c2cc(N(c3ccc4c(c3)C(C)(C)c3cc(-c5ccccc5)c5oc6ccccc6c5c3-4)c3ccc(-c4ccccc4)cc3-c3ccccc3)ccc2-c2c1cc(-c1ccccc1)c1oc3ccccc3c21]

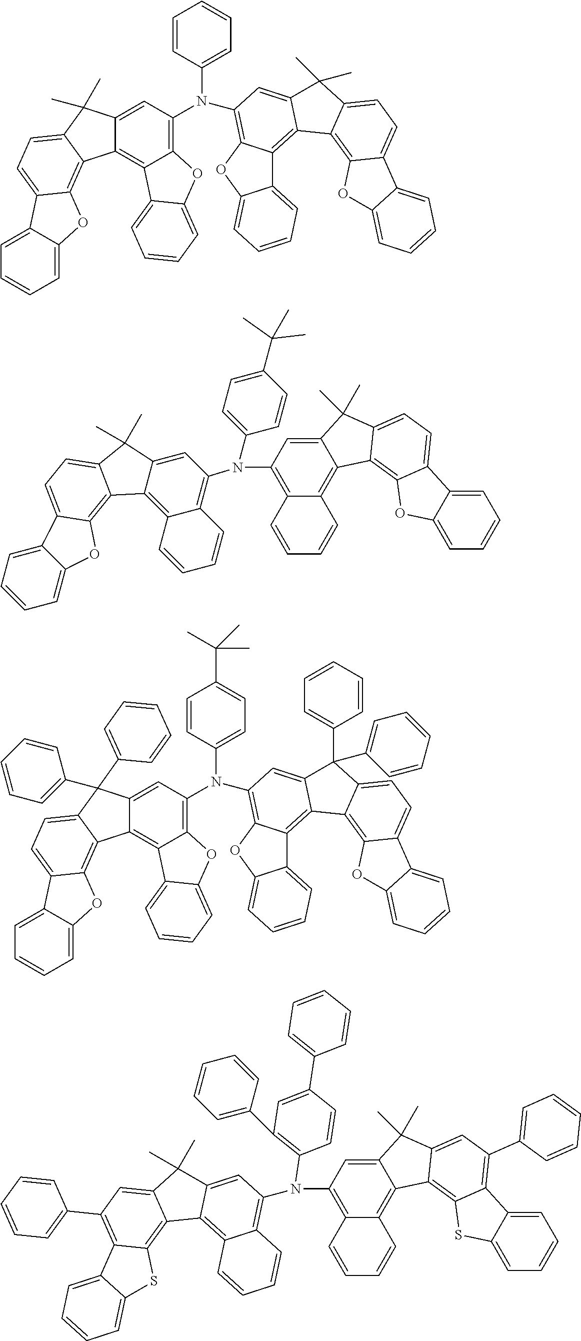

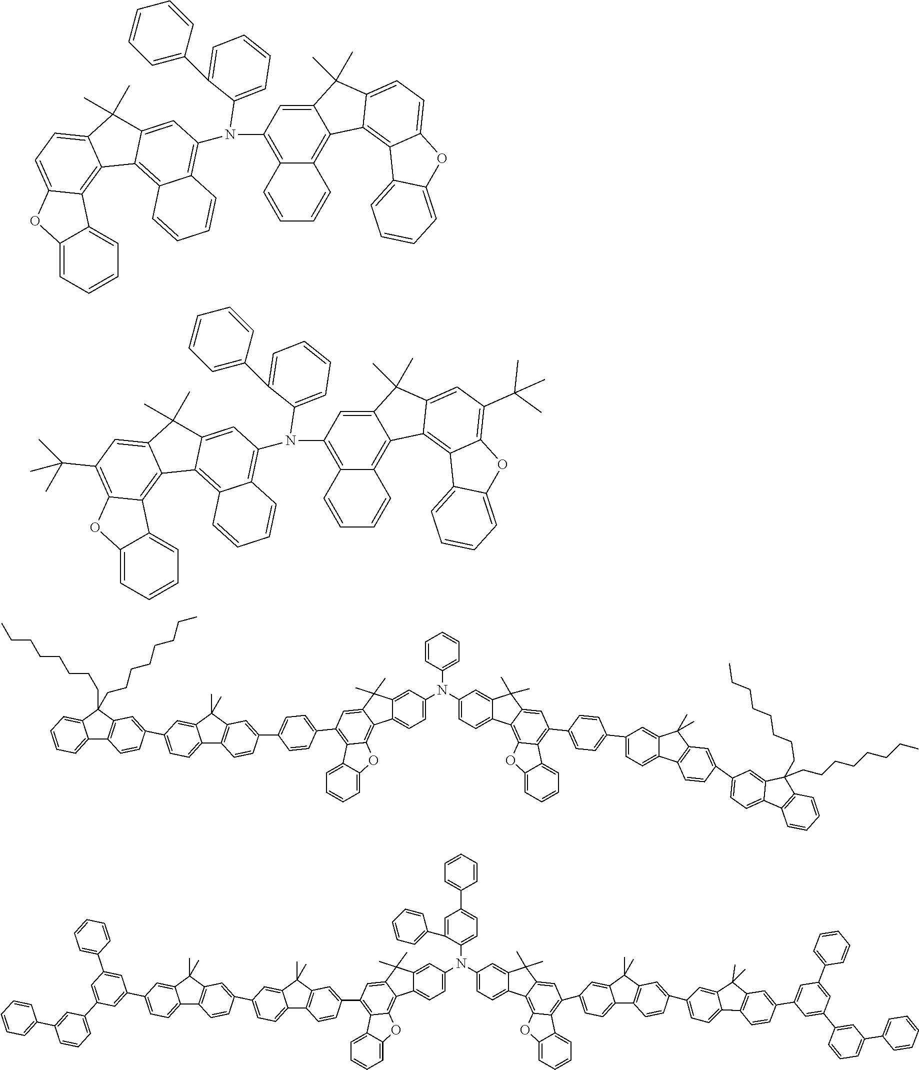

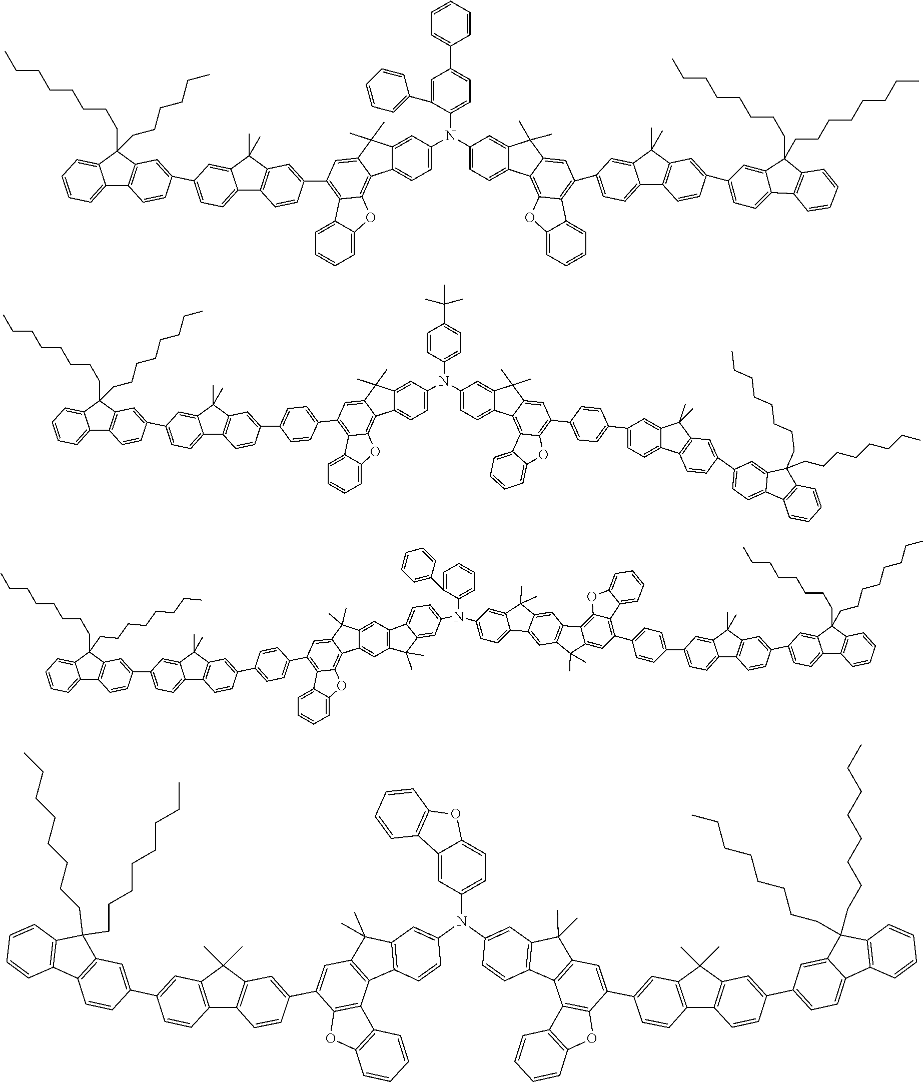

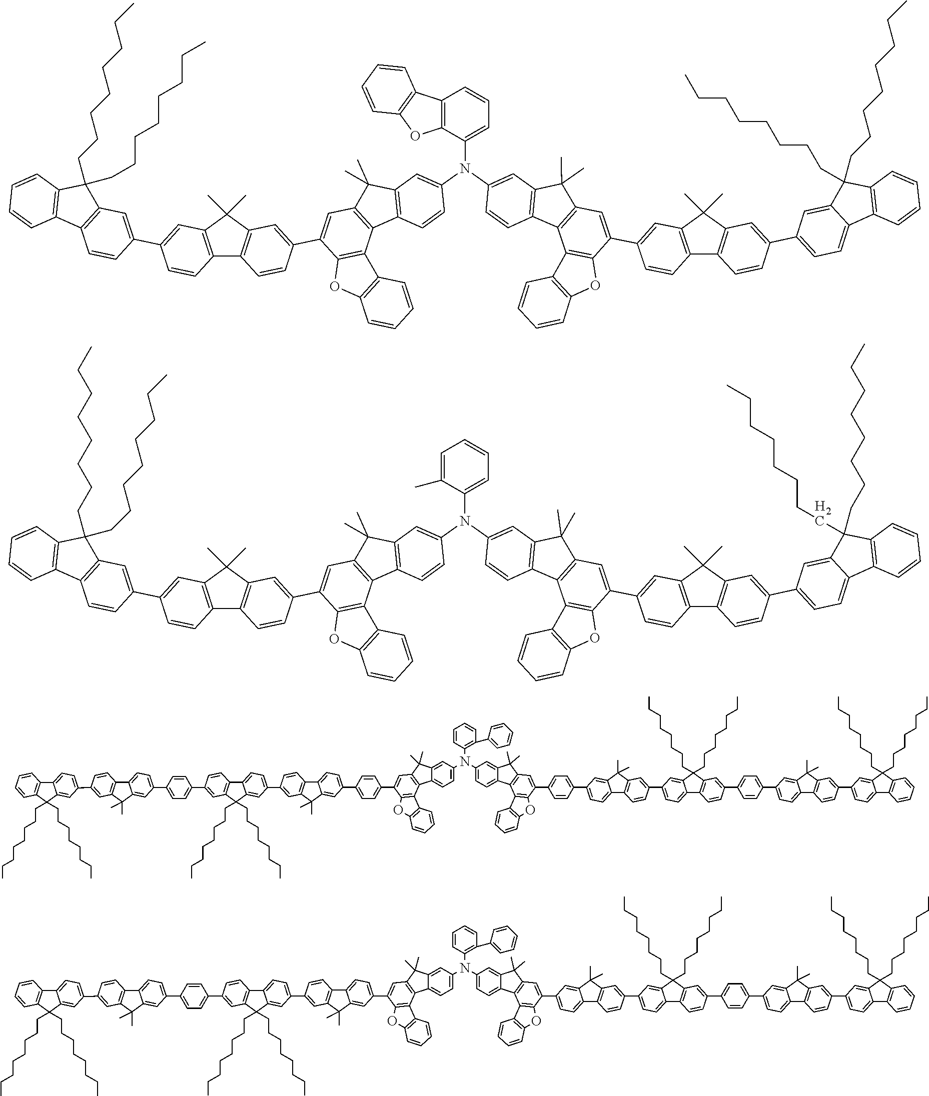

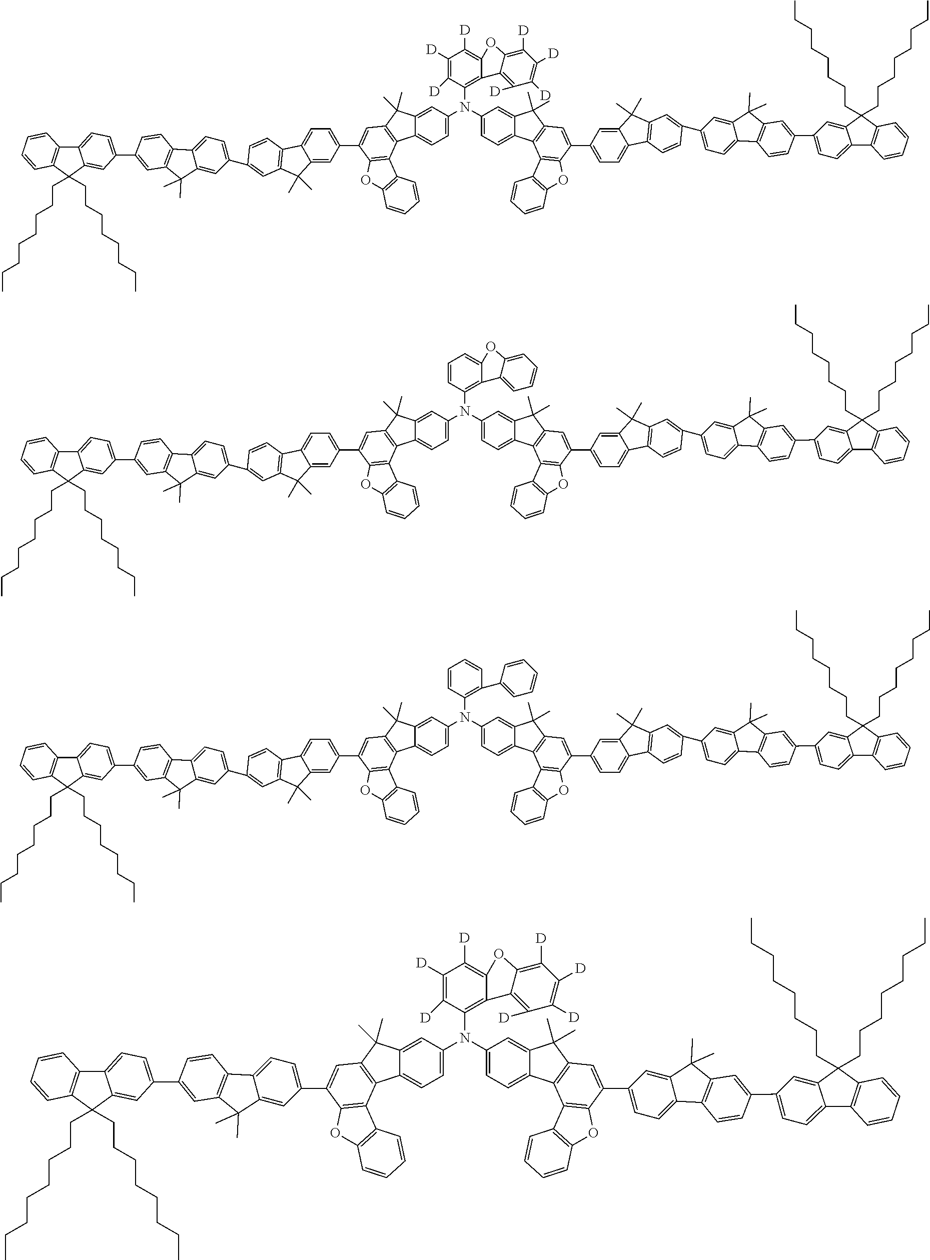

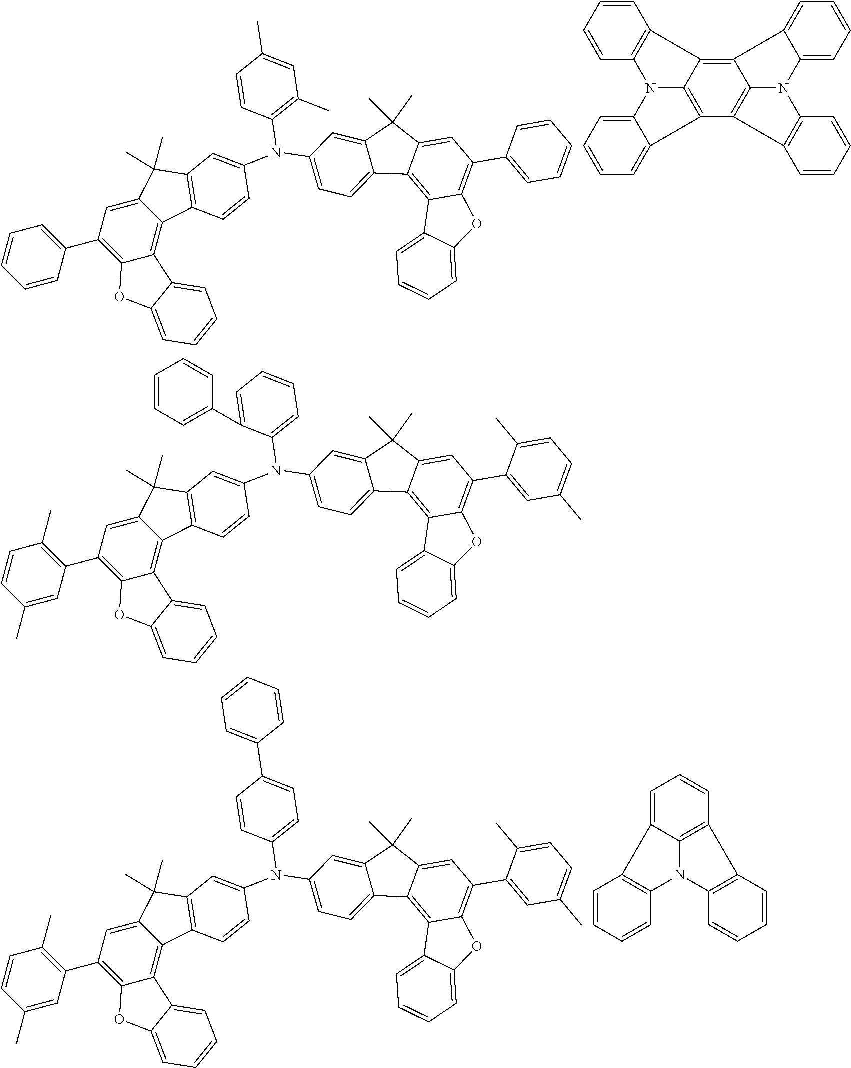

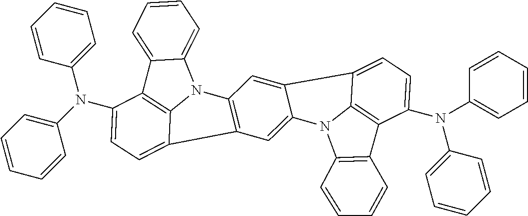 [SMILES: c1ccc(N(c2ccccc2)c2ccc3c4cc5c(cc4n4c6ccccc6c2c34)c2ccc(N(c3ccccc3)c3ccccc3)c3c4ccccc4n5c23)cc1]

Preferably, the emitting layers EMLA, EMLB and EMLC or EML1, EML2 and EML3 are obtained from a solution process.

The solution-based methods or formulation-based methods for depositing a layer in the fabrications of OLEDs have the potential of being very cost-efficient. In addition, the failure rate of the OLEDs obtained, in relative terms, is often lower.

For the processing of the compounds from the liquid phase, for example by coating processes like spin coating or by printing processes, formulations of the compositions are necessary. Soluble compounds are necessary for this purpose. High solubility can be achieved through suitable substitution of the compounds. The formulations comprise the compounds of the compositions and at least one solvent. These formulations can be, for example, solutions, dispersions or emulsions. More preferably, these formulations are solutions.

It may be preferred to use mixtures of two or more solvents for this purpose. The solvents are preferably selected from organic and inorganic solvents, more preferably organic solvents. The solvents are very preferably selected from hydrocarbons, alcohols, esters, ethers, ketones and amines. Suitable and preferred solvents are, for example, toluene, anisole, o-, m- or p-xylene, methyl benzoate, mesitylene, tetralin, veratrole, THF, methyl-THF, THP, chlorobenzene, dioxane, phenoxytoluene, in particular 3-phenoxytoluene, (−)-fenchone, 1,2,3,5-tetram ethylbenzene, 1,2,4,5-tetramethylbenzene, 1-methylnaphthalene, 1-ethylnaphthalene, decylbenzene, phenyl naphthalene, menthyl isovalerate, para tolyl isobutyrate, cyclohexal hexanoate, ethyl para toluate, ethyl ortho toluate, ethyl meta toluate, decahydronaphthalene, ethyl 2-methoxybenzoate, dibutylaniline, dicyclohexylketone, isosorbide dimethyl ether, decahydronaphthalene, 2-methylbiphenyl, ethyl octanoate, octyl octanoate, diethyl sebacate, 3,3-dimethylbiphenyl, 1,4-dimethylnaphthalene, 2,2′-dimethylbiphenyl, 2-methylbenzothiazole, 2-phenoxyethanol, 2-pyrrolidinone, 3-methylanisole, 4-methylanisole, 3,4-dimethylanisole, 3,5-dimethylanisole, acetophenone, α-terpineol, benzothiazole, butyl benzoate, cumene, cyclohexanol, cyclo-hexanone, cyclohexylbenzene, decalin, dodecylbenzene, ethyl benzoate, indane, NMP, p-cymene, phenetole, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene-glycol monobutyl ether, tripropylene glycol dimethyl ether, tetraethylene glycol dimethyl ether, 2-isopropylnaphthalene, pentylbenzene, hexyl-benzene, heptylbenzene, octylbenzene, 1,1-bis(3,4-dimethylphenyl)ethane or mixtures of these solvents.

The proportion of the organic solvent in the formulation is preferably at least 60% by weight, more preferably at least 70% by weight and particularly preferably at least 80% by weight, based on the total weight of the formulation.

The formulations, more preferably solutions, can be employed for the formation of a functional layer comprising at least one compound on a substrate or on one of the layers applied to the substrate for the production of electroluminescent devices.

Therefore, a further object of the invention is a process for the production of an electroluminescent device according to the invention, wherein at least one layer is obtained from a solution process. Preferably, the solution is applied to a substrate or to another layer and then dried.

In accordance with a preferred embodiment, the process for the production of an electroluminescent device according to the invention is characterized in that the process comprises the following steps:
a) Application of a solution comprising a compound A on a substrate, or on another layer, in order to form the emitting layer EMLA of the first subpixel;
b) Application of a solution comprising a compound B on a substrate, or on another layer, in order to form the emitting layer EMLB of the second subpixel;
c) Drying of the layer deposited in step a) in order to remove the solvent;
d) Drying of the layer deposited in step b) in order to remove the solvent;
whereas steps a) and b) can be performed one after each other or simultaneously; and
steps c) and d) can be performed one after each other or simultaneously.

In accordance with another preferred embodiment, the process for the production of an electroluminescent device according to the invention is characterized in that the process comprises the following steps:
a) Application of a solution comprising an emitting compound E1 and a host compound H1 on a substrate, or on another layer, in order to form the emitting layer EML1 of the first subpixel;
b) Application of a solution comprising an emitting compound E2 and a host compound H2 on a substrate, or on another layer, in order to form the emitting layer EML2 of the second subpixel;
c) Drying of the layer deposited in step a) in order to remove the solvent;
d) Drying of the layer deposited in step b) in order to remove the solvent;
whereas steps a) and b) can be performed one after each other or simultaneously; and
steps c) and d) can be performed one after each other or simultaneously.

Preferably, the drying of a layer as mentioned in steps c) and d) of the processes described above is a vacuum drying, preferably followed by an annealing of the layer. The vacuum drying here can preferably be carried out at a pressure in the range from 10 -7 mbar to 1 bar, particularly preferably in the range from 10 -6 mbar to 1 bar. More preferably, the vacuum drying step is followed by a thermal annealing of the layer. The thermal annealing of the layer preferably takes places at a temperature of from 120° C. to 180° C., preferably from 130° C. to 170° C., more preferably 140° C. to 160° C.

The application of a solution on a substrate, or on another layer, as mentioned in steps a) and b) is preferably performed via a coating method or a printing method. More preferably, the application of a solution on a substrate, or on another layer, as mentioned in steps a) and b) is performed by a coating method selected from spin coating, flood coating, dip coating, spray coating or by a printing method selected from inkjet printing, LITI (light-induced thermal imaging, thermal transfer printing), screen printing, relief printing, gravure printing, rotary printing, roller coating, flexographic printing, offset printing, nozzle printing, or electrohydrodynamic printing on a substrate or one of the layers applied to the substrate. The layers are preferably produced by inkjet printing.

In accordance with a preferred embodiment, the subpixels in the electroluminescent device according to the invention are laterally separated in a side-by-side geometry. More preferably, the subpixels are laterally separated in a side-by-side geometry by a hydrophobic bank structure.

Preferably, the first subpixel comprises the emitting layer EML1, which comprises an emitting compound E1 having an emission maximum wavelength λ₁, and the second subpixel comprises the emitting layer EML2, which comprises an emitting compound E2 having an emission maximum wavelength λ₂, where λ₁<λ₂.

It is preferred that the emitting compound E1 is a blue fluorescent emitting compound, which preferably has an emission wavelength λ₁ of from 430 to 480 nm.

In accordance with a preferred embodiment, the electroluminescent device comprises a third sub pixel comprising an emitting layer EML3 comprising an emitting compound E3 having an emission maximum wavelength λ₃, where:

λ₁<λ₂<λ₃; or 1)

λ₁<λ₃<λ₂. 2)

Preferably, the emitting compound E2 in EML2 is a phosphorescent emitting compound. More preferably, the emitting compound E2 in EML2 is a green phosphorescent emitting compound, which preferably has an emission wavelength λ₂ of from 500 to 560 nm.

Preferably, the emitting compound E3 in EML3 is a phosphorescent emitting compound. More preferably, the emitting compound E3 in EML3 is an orange/red phosphorescent emitting compound, which preferably has an emission wavelength λ₃ of from 560 to 650 nm.

The term “phosphorescent emitting compound” typically encompasses compounds where the emission of light is effected through a spin-forbidden transition, for example a transition from an excited triplet state or a state having a higher spin quantum number, for example a quintet state.

Suitable phosphorescent emitting compounds (=triplet emitting compounds) are especially compounds which, when suitably excited, emit light, preferably in the visible region, and also contain at least one atom of atomic number greater than 20, preferably greater than 38, and less than 84, more preferably greater than 56 and less than 80. Preference is given to using, as phosphorescent emitting compounds, compounds containing copper, molybdenum, tungsten, rhenium, ruthenium, osmium, rhodium, iridium, palladium, platinum, silver, gold or europium, especially compounds containing iridium, platinum or copper. In the context of the present invention, all luminescent iridium, platinum or copper complexes are considered to be phosphorescent emitting compounds. In general, all phosphorescent complexes as used for phosphorescent OLEDs according to the prior art and as known to those skilled in the art in the field of organic electroluminescent devices are suitable. It is also possible for the person skilled in the art, without exercising inventive skill, to use further phosphorescent complexes in combination with the compounds according to the present application in organic electroluminescent devices.

Examples of suitable phosphorescent emitting compounds are the following ones:

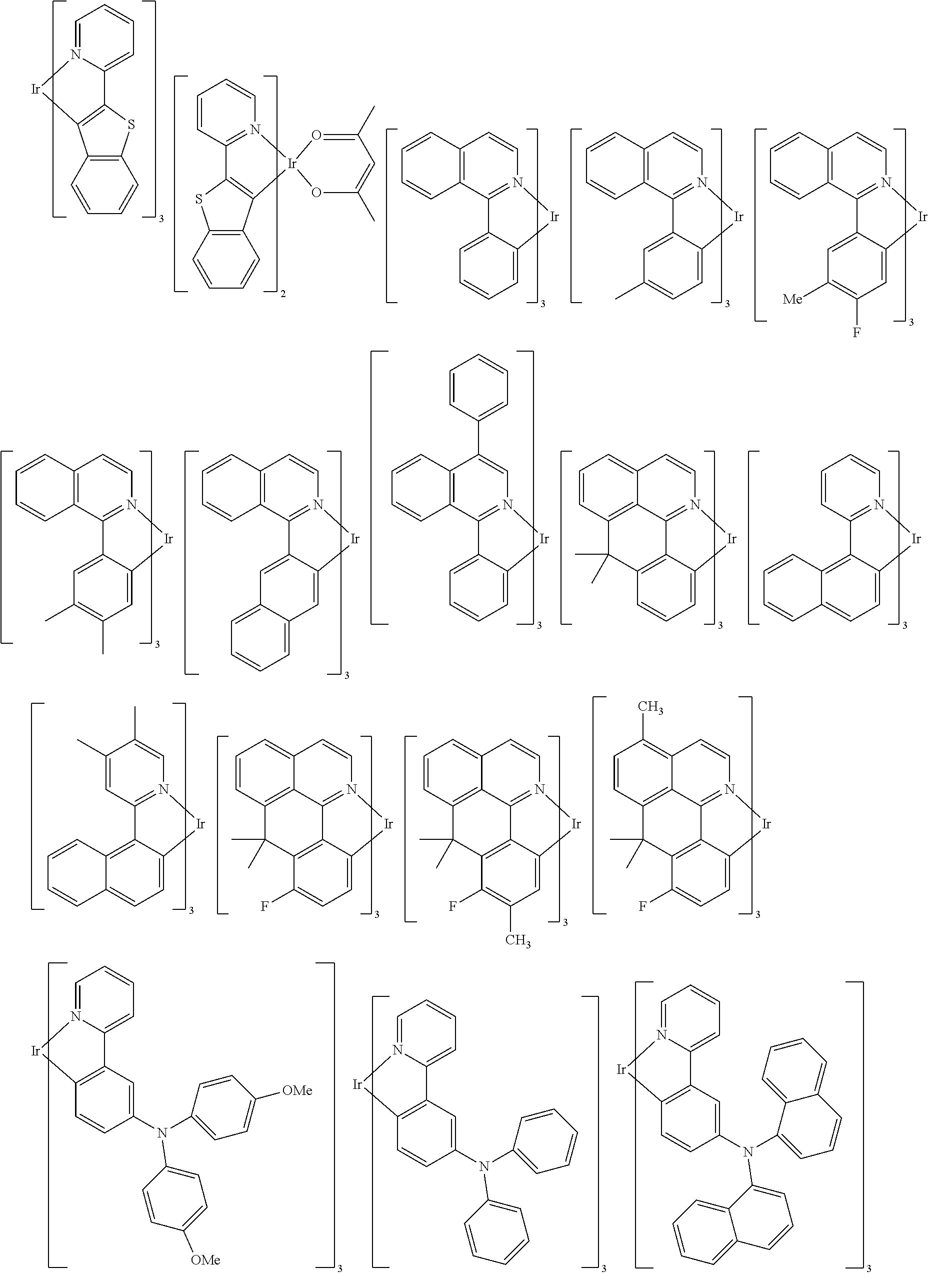

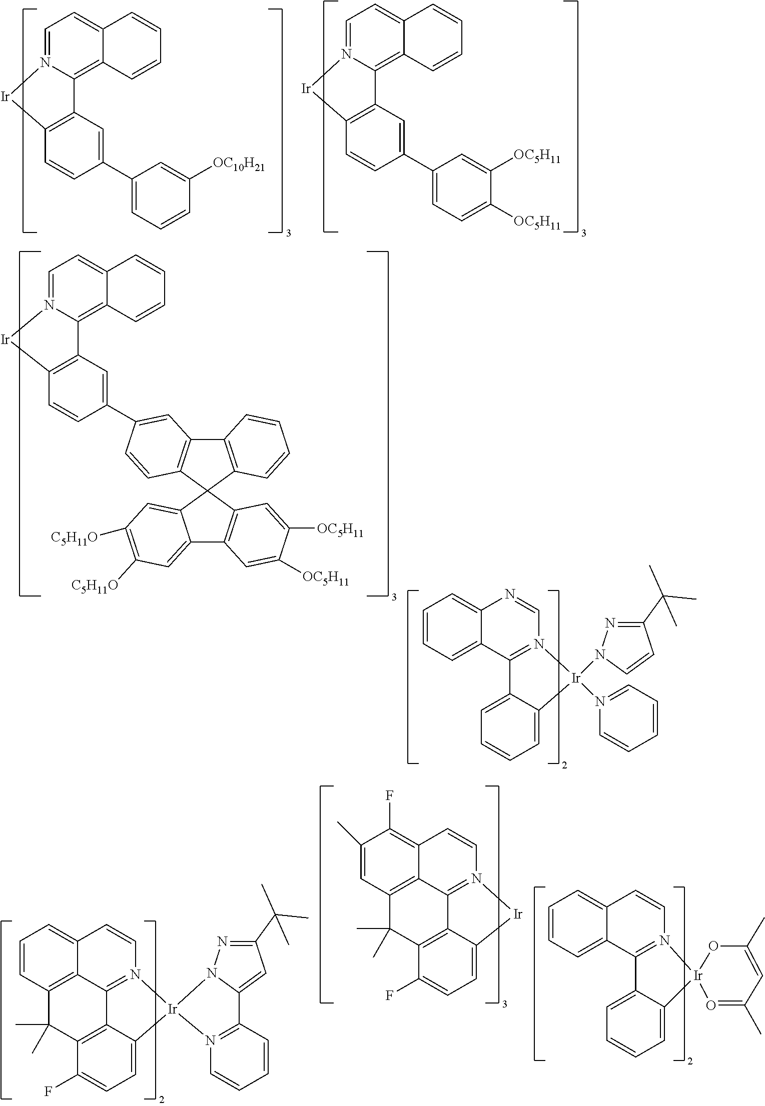

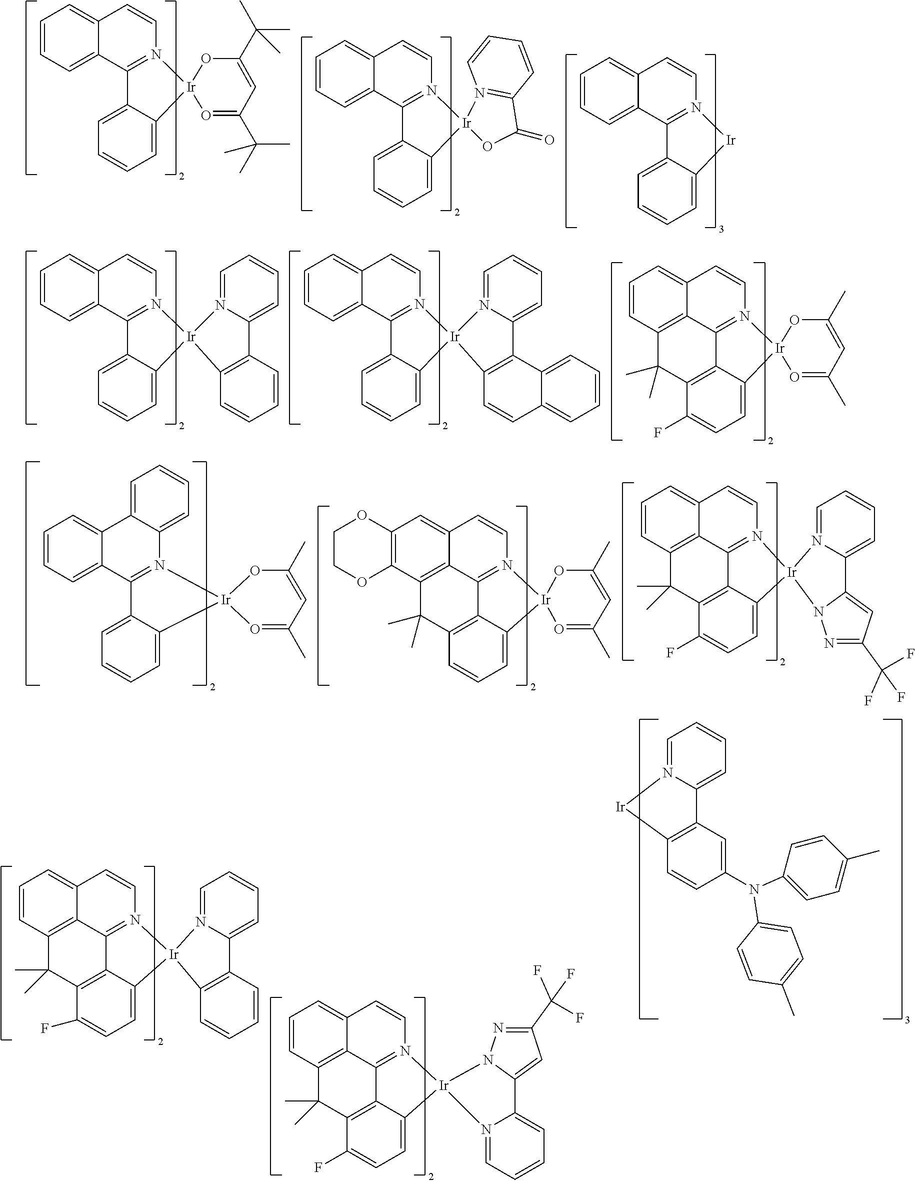

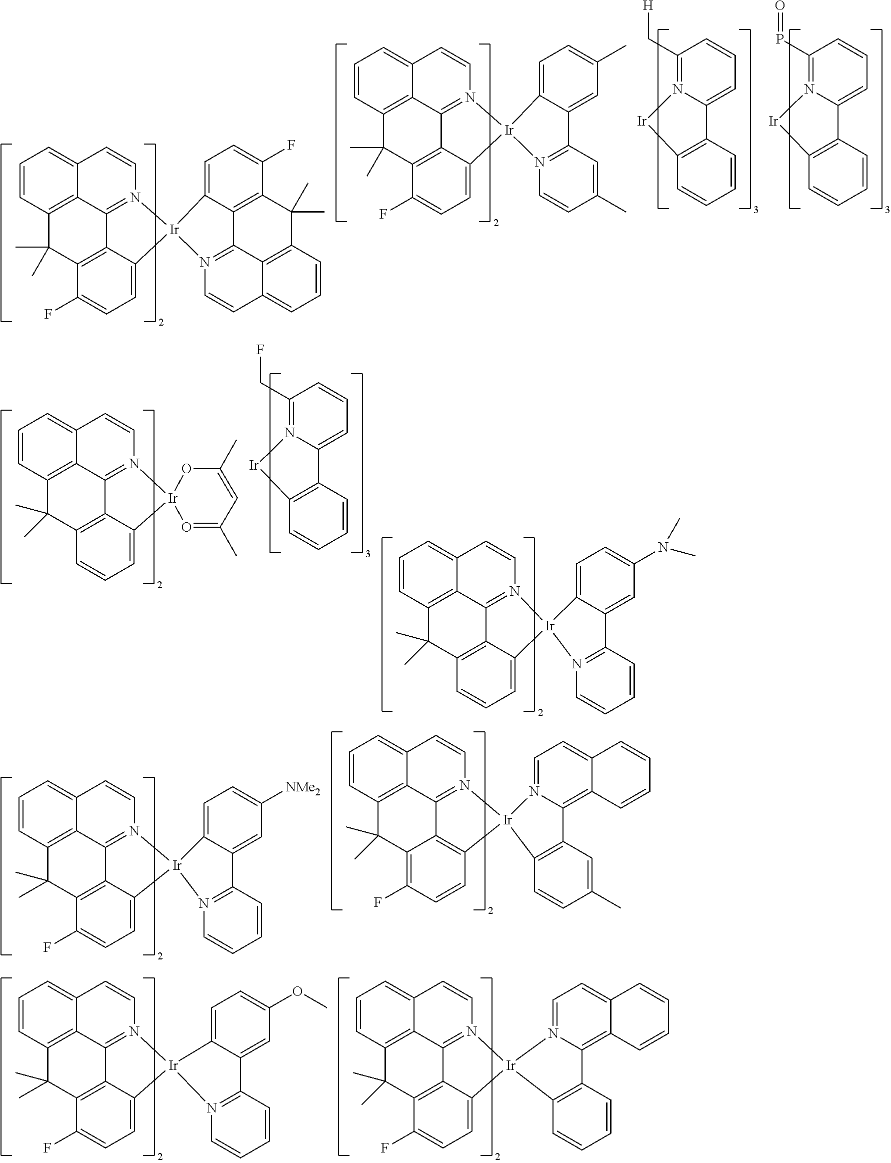

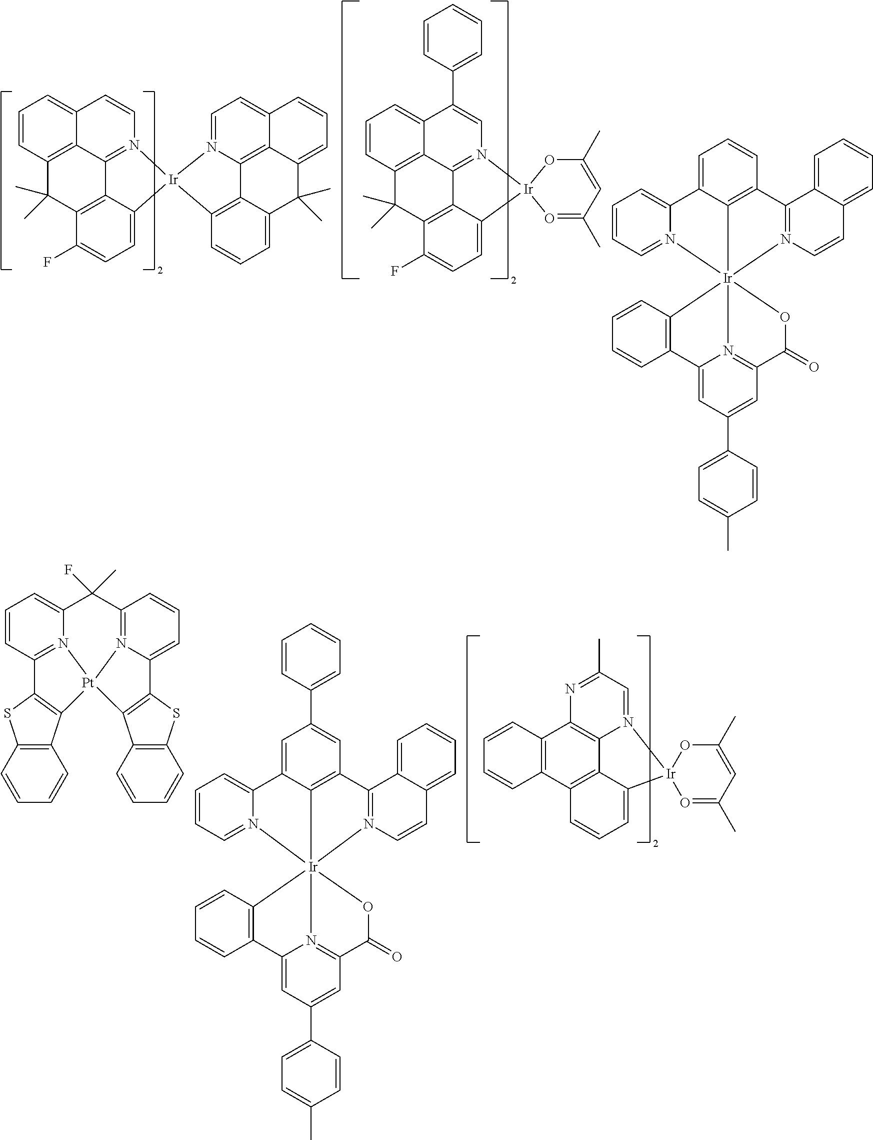

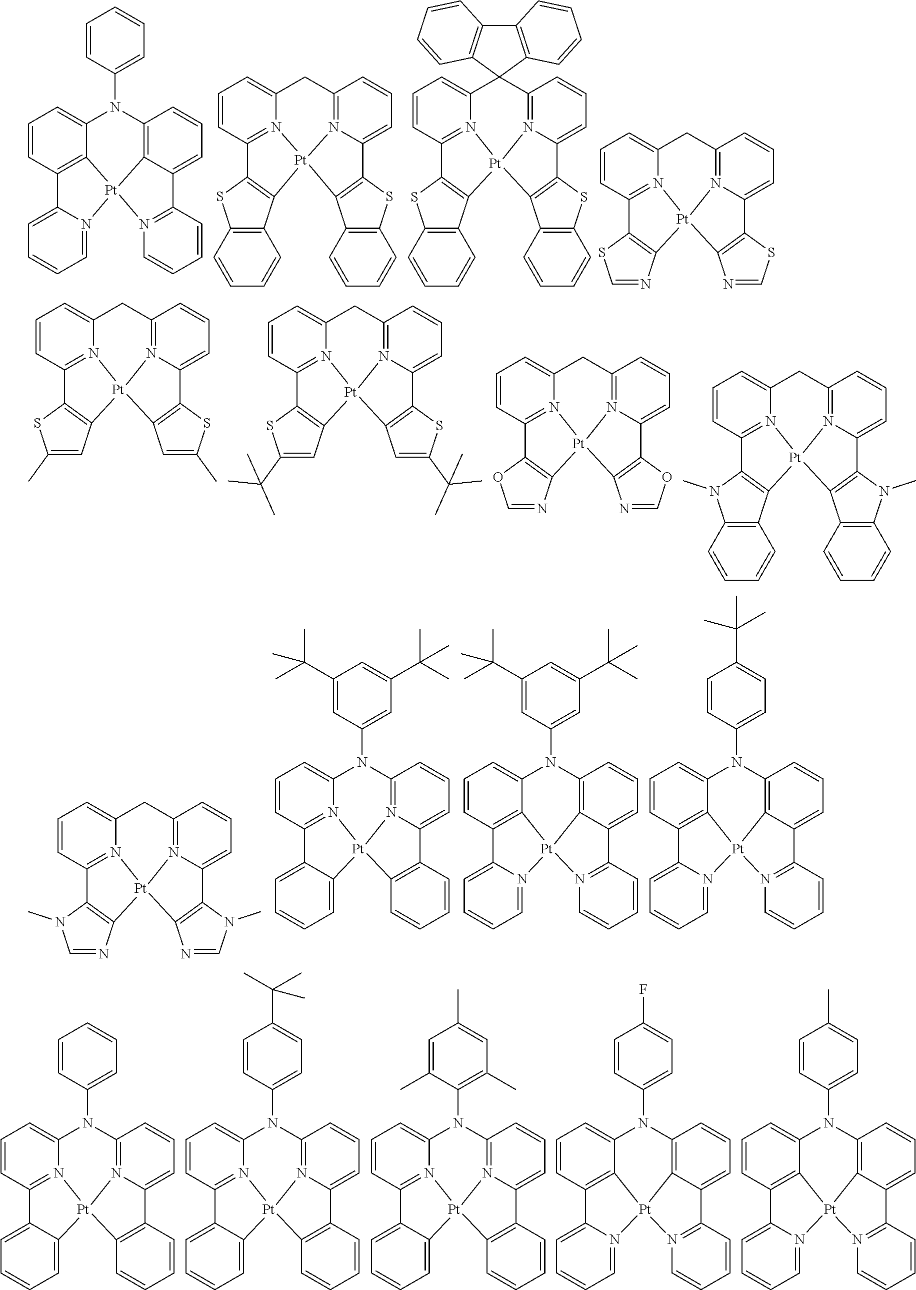

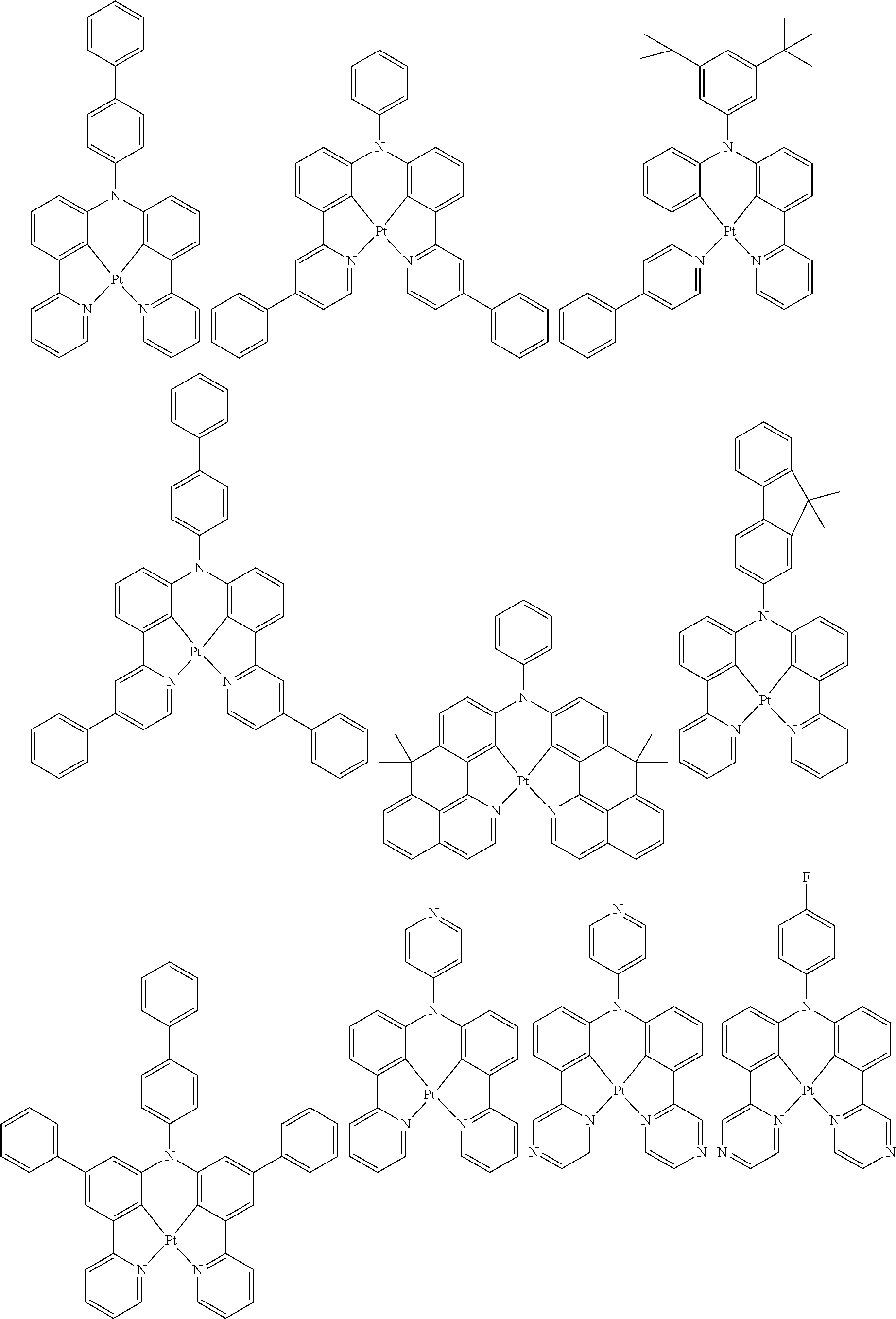

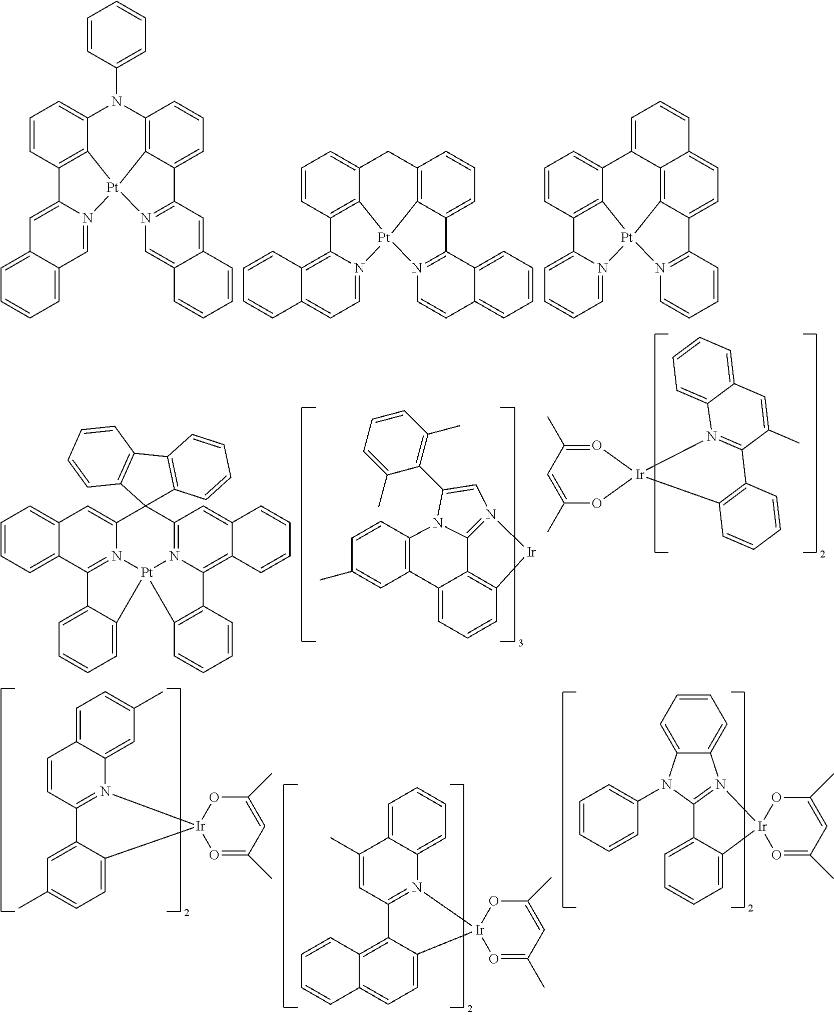

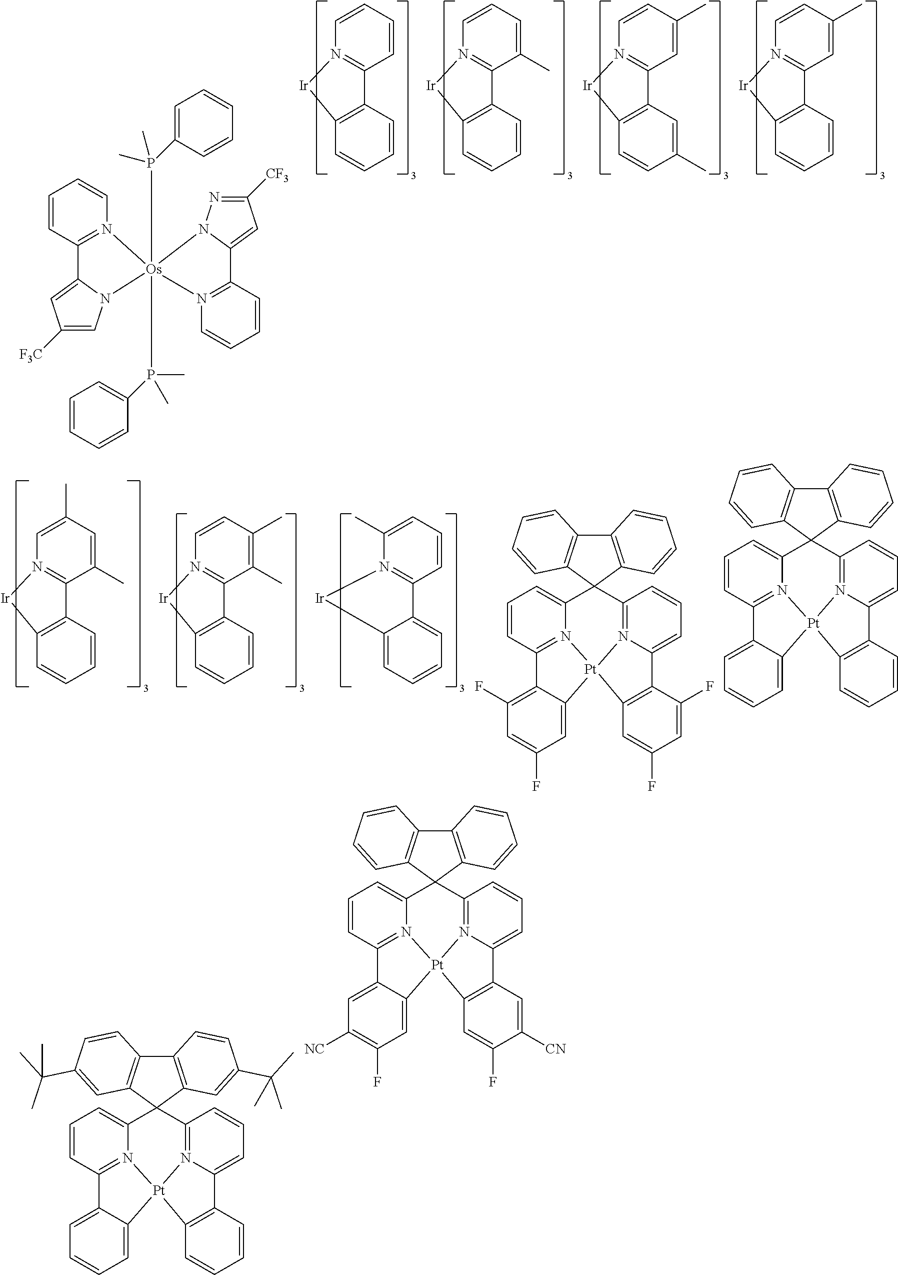

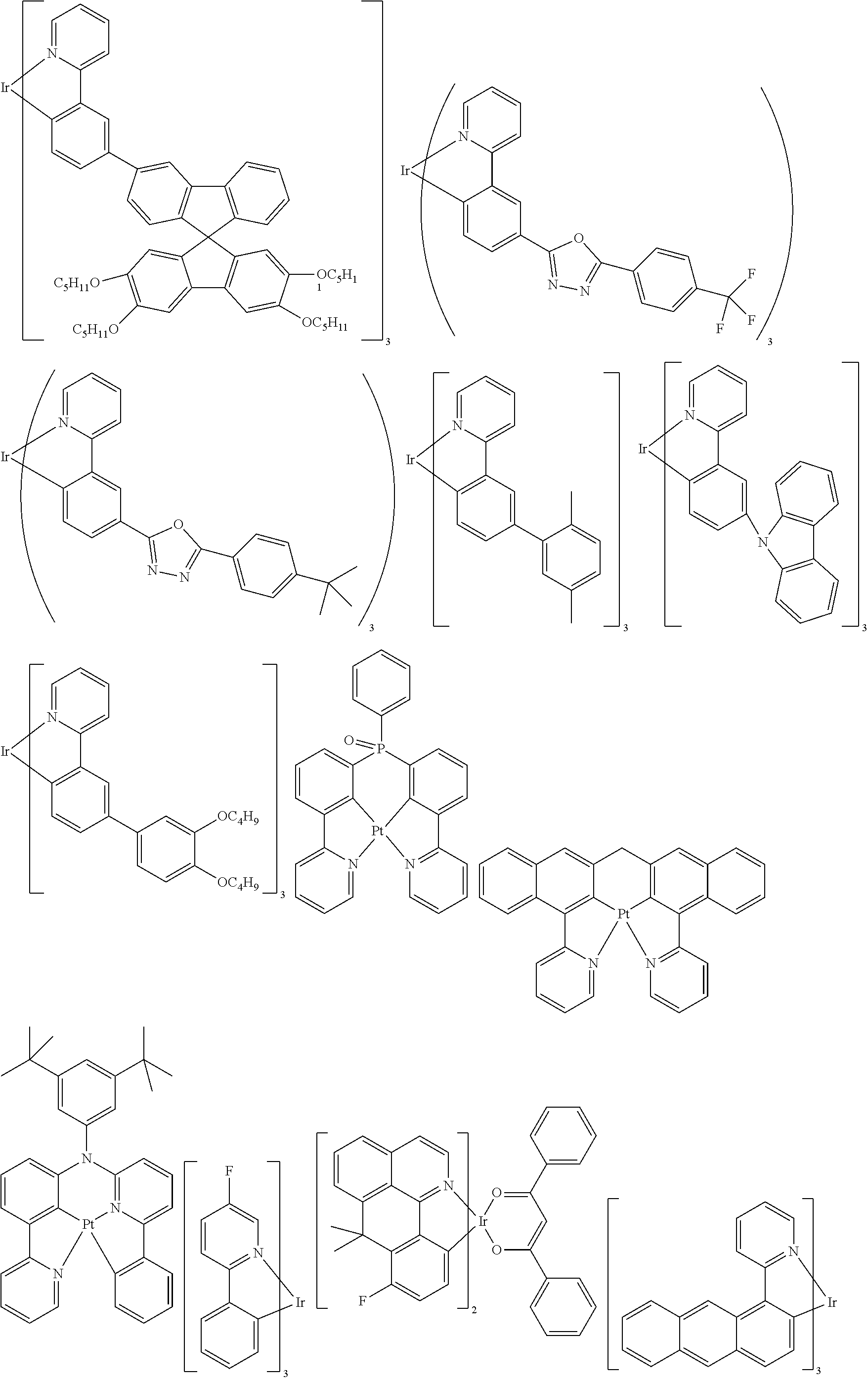

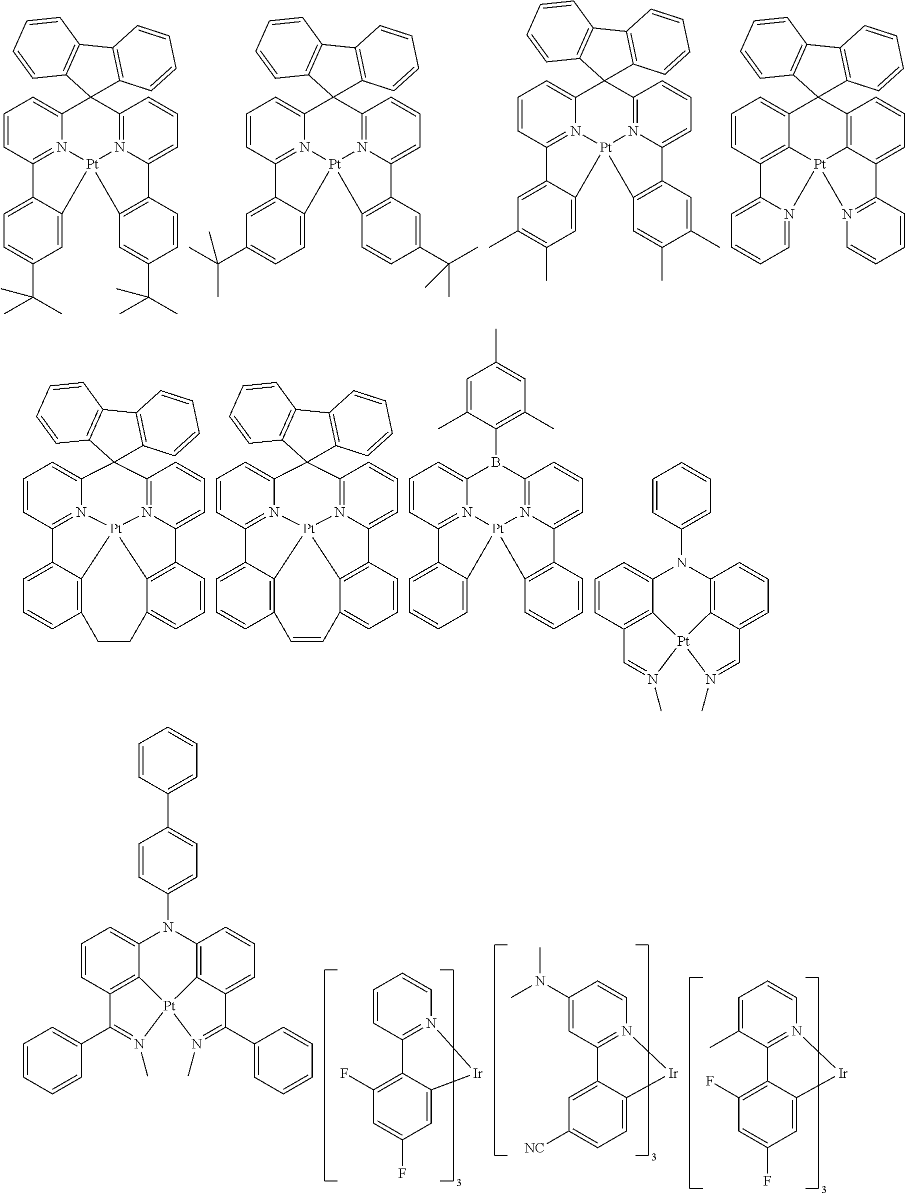

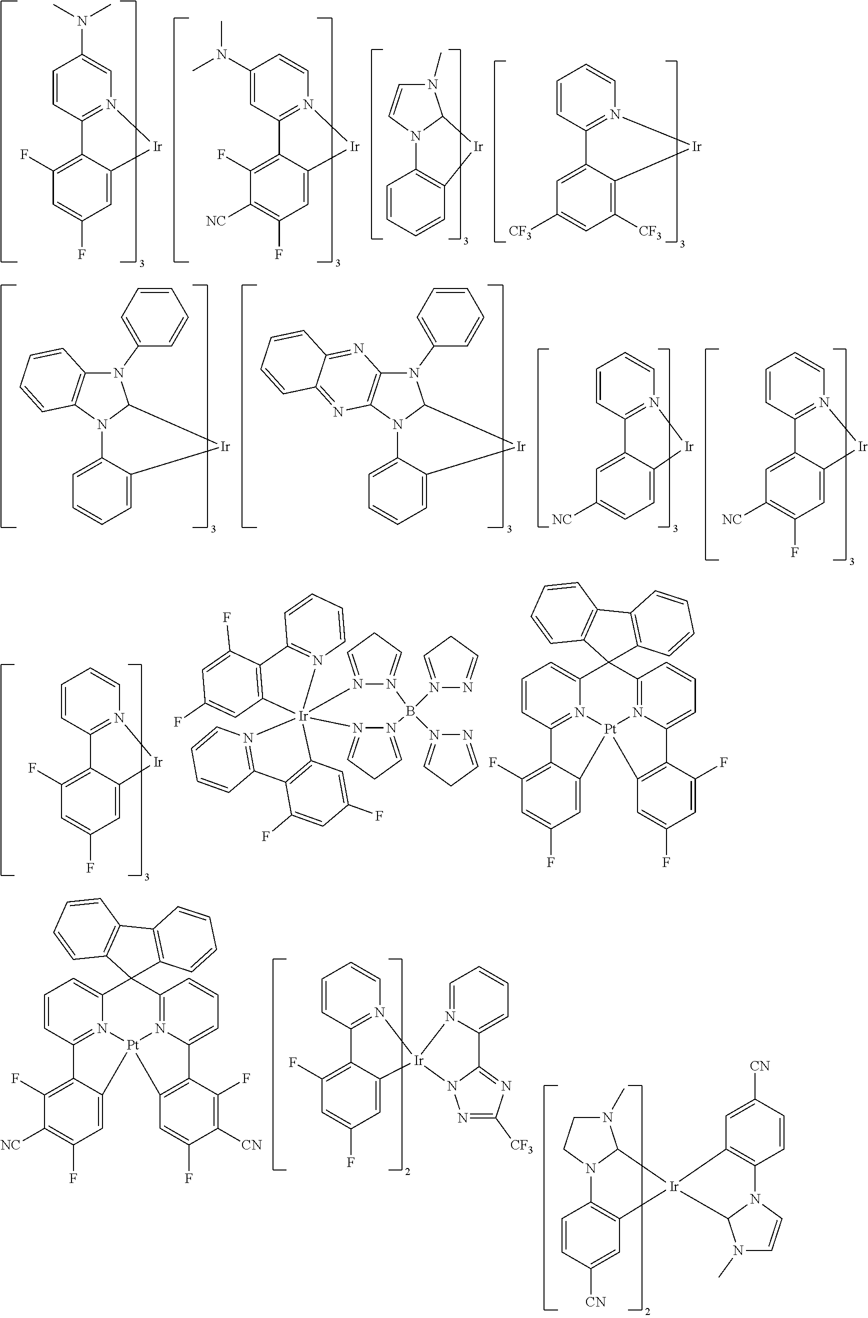

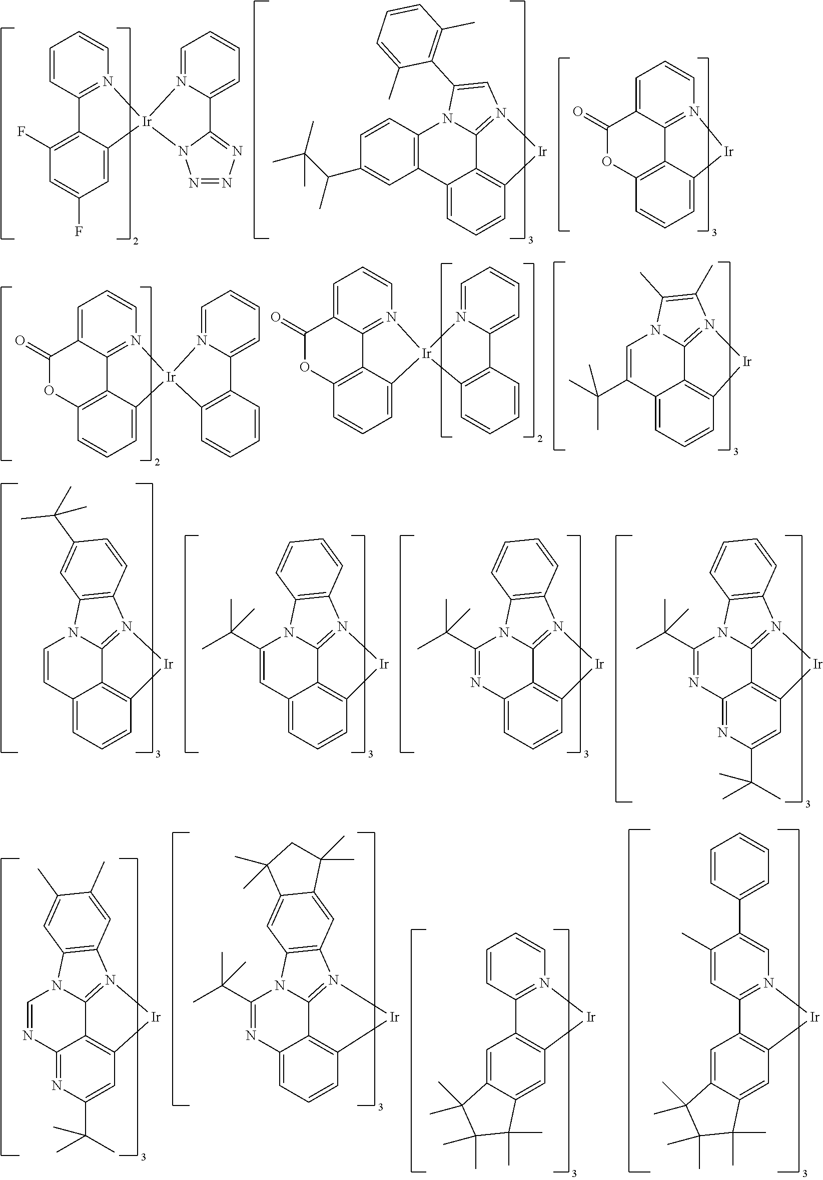

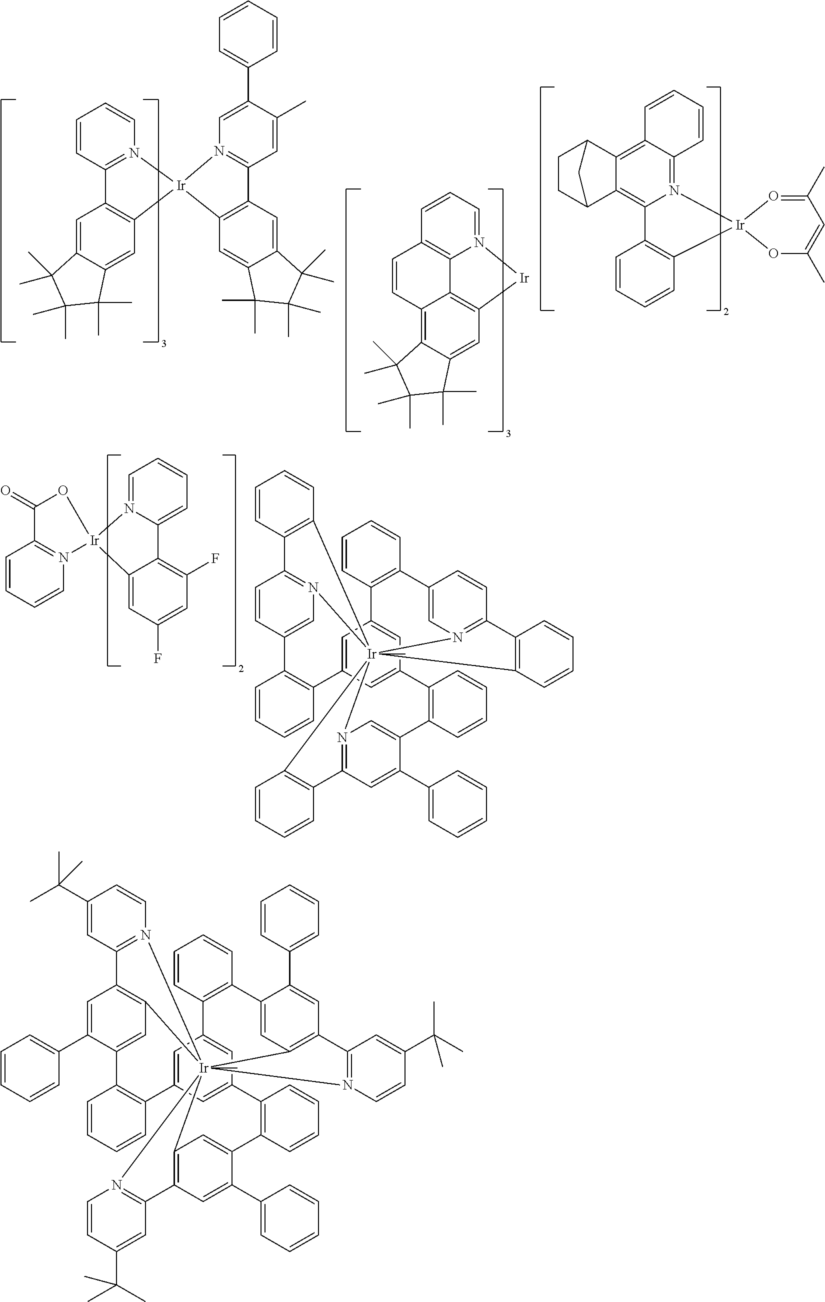

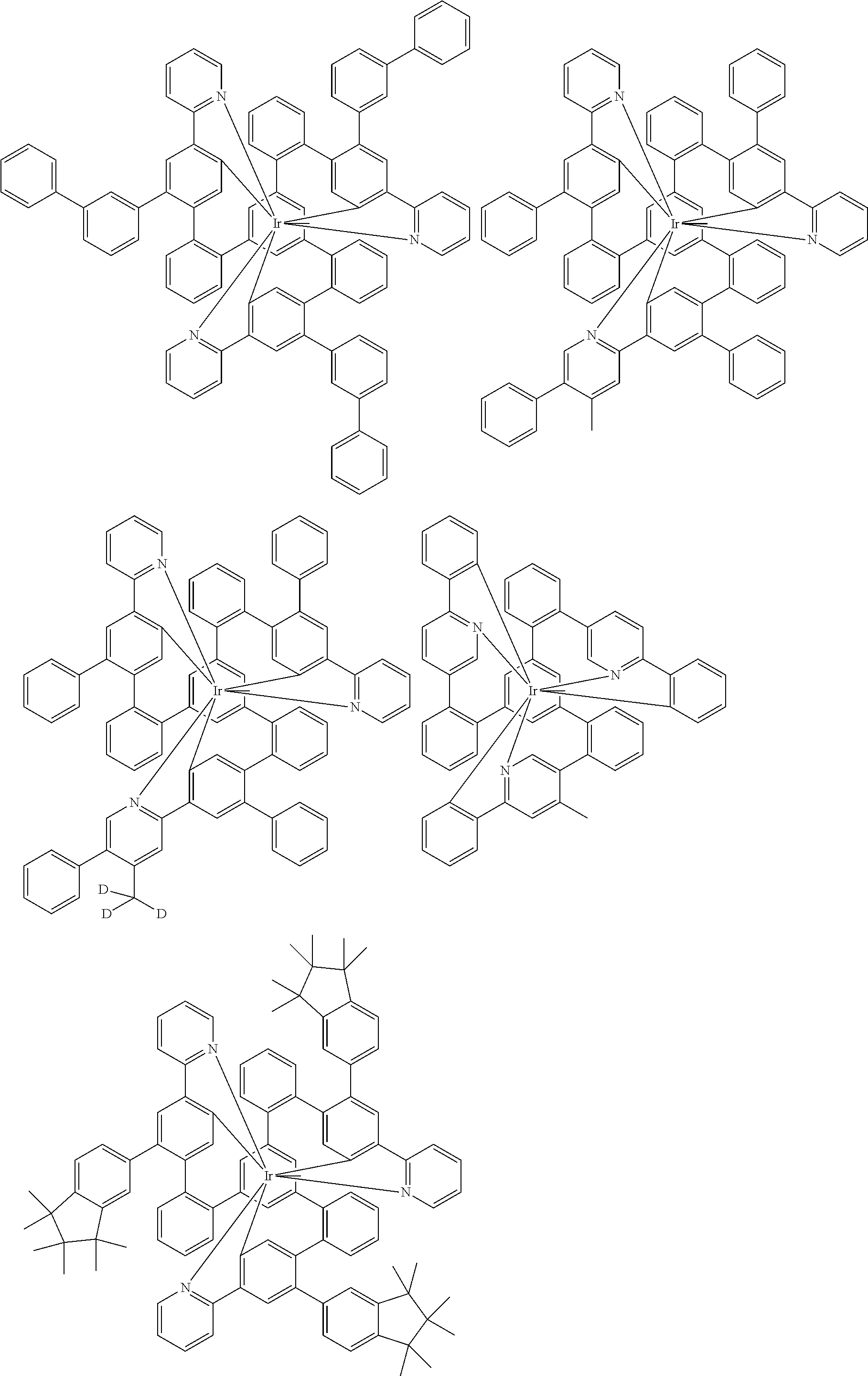

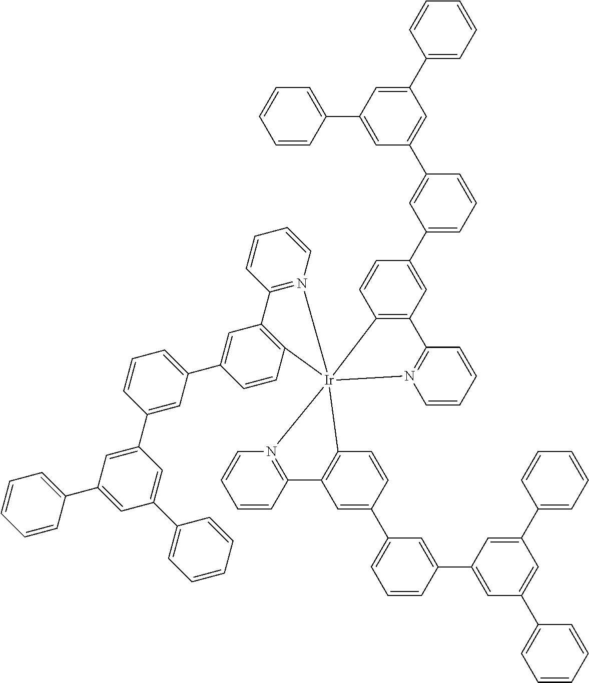

The phosphorescent emitting compounds are preferably used in an emitting layer in combination with one or more host or matrix materials.

Preferred matrix materials for phosphorescent emitting compounds are, as well as the compounds of the present application, aromatic ketones, aromatic phosphine oxides or aromatic sulphoxides or sulphones, triarylamines, carbazole derivatives, e.g. CBP (N,N-biscarbazolylbiphenyl) or carbazole derivatives, indolocarbazole derivatives, indenocarbazole derivatives, azacarbazole derivatives, bipolar matrix materials, silanes, azaboroles or boronic esters, triazine derivatives, zinc complexes, diazasilole or tetraazasilole derivatives, diazaphosphole derivatives, bridged carbazole derivatives, triphenylene derivatives, or lactams.

An emitting layer of an organic electroluminescent device may also comprise systems comprising a plurality of matrix materials (mixed matrix systems, mixed hosts) and/or a plurality of emitting compounds (phosphorescent emitting compounds, fluorescence emitting compounds). In this case too, the emitting compounds are generally those compounds having the smaller proportion in the system (=dopants) and the matrix materials are those compounds having the greater proportion in the system. In individual cases, however, the proportion of a single matrix material in the system may be less than the proportion of a single emitting compound.

The mixed matrix systems preferably comprise two or three different matrix materials, more preferably two different matrix materials. Preferably, in this case, one of the two materials is a material having hole-transporting properties and the other material is a material having electron-transporting properties.

Also suitable as matrix material for phosphorescent emitters are wide band gap host compounds; wherein the wide band gap host compound has a band gap of at least 2.0 eV, preferably 3.0 eV and has preferably a triplet energy that is greater than the triplet energy of the phosphorescent dopant. The wide band gap host compound may be used as a single matrix material or in combination with one or more of the following matrix materials: a material having hole-transporting properties, a material having electron-transporting properties or a bipolar material.

Particularly suitable matrix materials which can be used as matrix components of a mixed matrix system are selected from the preferred matrix materials specified above for phosphorescent emitting compounds or the preferred matrix materials for fluorescent emitting compounds as already described above, according to what type of emitting compound is used in the mixed matrix system.

Preferably, the proportion of the matrix or host material(s) in the emitting layer is between 50.0% and 99.9% by volume, preferably between 70.0% and 99.5% by volume, and more preferably between 92.0% and 99.5% by volume for fluorescent emitting layers and between 80.0% and 97.0% by volume for phosphorescent emitting layers. Correspondingly, the proportion of the emitting compound, namely the compound responsible for the emission of the layer, in the emitting layer is between 0.1% and 50.0% by mass, preferably between 0.5% and 20.0% by mass, and more preferably between 0.5% and 8.0% by mass for fluorescent emitting layers and between 3.0% and 20.0% by mass for phosphorescent emitting layers.

In this application, proportions are given as percent by volume when the mixtures are applied from the gas phase. If the mixtures are applied from solution, this corresponds to percent by mass.

In accordance with a preferred embodiment, each subpixel corresponds to a light emitting stack comprising at least one further organic layer. More preferably, the further layer is selected from hole-transporting layers.

In accordance with a preferred embodiment, each subpixel comprises in the following order:
A substrate;
An anode;
Optionally a hole-injection layer,
A hole-transport layer;
An emitting layer;
Optionally a hole-blocking layer;
An electron-transporting layer;
Optionally an electron-injection layer; and
A cathode.

The hole-injection layer preferably comprises a polymer. More preferably, the hole-injection layer comprises a cross-linkable polymer, which is a hole-transporting material, and a p-doping salt. Such hole injection layers and materials are described for example in WO2016/107668, WO2013/081052 and EP2325190.

The hole-transport layer also preferably comprises a polymer. More preferably, the hole-transport layer comprises a polymer comprising a repeating unit having a triarylamine group. Such hole transport layers and materials are described for example in WO2013/156130.

Other preferred hole-transport materials which can be used in a hole-transport, hole-injection or electron-blocking layer in the electroluminescent device according to the invention are indenofluorenamine derivatives (for example in accordance with WO 06/122630 or WO 06/100896), the amine derivatives disclosed in EP 1661888, hexaazatriphenylene derivatives (for example in accordance with WO 01/049806), amine derivatives containing condensed aromatic rings (for example in accordance with U.S. Pat. No. 5,061,569), the amine derivatives disclosed in WO 95/09147, monobenzoindenofluorenamines (for example in accordance with WO 08/006449), dibenzoindenofluorenamines (for example in accordance with WO 07/140847), spirobifluorenamines (for example in accordance with WO 2012/034627 or WO 2013/120577), fluorenamines (for example in accordance with the as applications EP 2875092, EP 2875699 and EP 2875004), spirodibenzopyranamines (for example in accordance with WO 2013/083216) and dihydroacridine derivatives (for example in accordance with WO 2012/150001).

Other suitable charge-transport materials, as can be used in the hole-injection or hole-transport layer or electron-blocking layer or in the electron-transport layer of the electronic device according to the invention, are, for example, the compounds disclosed in Y. Shirota et al., Chem. Rev. 2007, 107(4), 953-1010, or other materials as are employed in these layers in accordance with the prior art.

Preferably, the optional hole-injection layer, the hole-transport layer and the emitting layer are obtained from a solution process.

More preferably, all the layers between the anode and the emitting layer, including the emitting layer, are applied from solution, and all the layers between the emitting layer, non-including the emitting layer, and the cathode are applied from the gas phase.

When a layer is applied from the gas phase, it can be coated by a sublimation process. In this case, the materials are applied by vapour deposition in vacuum sublimation systems at an initial pressure of less than 10⁻⁵ mbar, preferably less than 10⁻⁶ mbar. In this case, however, it is also possible that the initial pressure is even lower, for example less than 10⁻⁷ mbar. The layer can also be coated by the OVPD (organic vapour phase deposition) method or with the aid of a carrier gas sublimation. In this case, the materials are applied at a pressure between 10⁻⁵ mbar and 1 bar. A special case of this method is the OVJP (organic vapour jet printing) method, in which the materials are applied directly by a nozzle and thus structured (for example M. S. Arnold et al., Appl. Phys. Lett. 2008, 92, 053301).

For the layers produced from solution, examples of solution processes have been already mentioned above.

Each subpixel may comprise further layers selected from hole-injection layers, hole-transport layers, hole-blocking layers, electron-transport layers, electron-injection layers, exciton-blocking layers, electron-blocking layers and/or charge-generation layers. It is likewise possible for interlayers, which have, for example, an exciton-blocking function, to be introduced between two emitting layers. However, it should be pointed out that each of these layers does not necessarily have to be present.

Generally preferred classes of material for use as corresponding functional materials in the organic electroluminescent devices according to the invention are as indicated above and below.

Materials which can be used for the electron-transport layer are all materials as are used in accordance with the prior art as electron-transport materials in the electron-transport layer. Particularly suitable are aluminium complexes, for example Alq₃, zirconium complexes, for example Zrq₄, lithium complexes, for example LiQ, benzimidazole derivatives, triazine derivatives, pyrimidine derivatives, pyridine derivatives, pyrazine derivatives, quinoxaline derivatives, quinoline derivatives, oxadiazole derivatives, aromatic ketones, lactams, boranes, diazaphosphole derivatives and phosphine oxide derivatives. Furthermore, suitable materials are derivatives of the above-mentioned compounds, as disclosed in JP 2000/053957, WO 2003/060956, WO 2004/028217, WO 2004/080975 and WO 2010/072300.

The cathode of the organic electroluminescent device preferably comprises metals having a low work function, metal alloys or multilayered structures comprising various metals, such as, for example, alkaline-earth metals, alkali metals, main-group metals or lanthanoids (for example Ca, Ba, Mg, Al, In, Mg, Yb, Sm, etc.). Also suitable are alloys comprising an alkali metal or alkaline-earth metal and silver, for example an alloy comprising magnesium and silver. In the case of multilayered structures, further metals which have a relatively high work function, such as, for example, Ag or Al, can also be used in addition to the said metals, in which case combinations of the metals, such as, for example, Ca/Ag, Mg/Ag or Ag/Ag, are generally used. It may also be preferred to introduce a thin interlayer of a material having a high dielectric constant between a metallic cathode and the organic semiconductor. Suitable for this purpose are, for example, alkali metal fluorides or alkaline-earth metal fluorides, but also the corresponding oxides or carbonates (for example LiF, Li₂O, BaF₂, MgO, NaF, CsF, Cs₂CO₃, etc.). Furthermore, lithium quinolinate (LiQ) can be used for this purpose. The layer thickness of this layer is preferably between 0.5 and 5 nm.

The anode preferably comprises materials having a high work function. The anode preferably has a work function of greater than 4.5 eV vs. vacuum. Suitable for this purpose are on the one hand metals having a high redox potential, such as, for example, Ag, Pt or Au. On the other hand, metal/metal oxide electrodes (for example Al/Ni/NiOₓ, Al/PtOₓ) may also be preferred. For some applications, at least one of the electrodes must be transparent or partially transparent in order to facilitate either irradiation of the organic material (organic solar cells) or the coupling-out of light (OLEDs, O-lasers). Preferred anode materials here are conductive mixed metal oxides. Particular preference is given to indium tin oxide (ITO) or indium zinc oxide (IZO). Preference is furthermore given to conductive, doped organic materials, in particular conductive doped polymers.

The device is appropriately (depending on the application) structured, provided with contacts and finally sealed, since the lifetime of the devices according to the invention is shortened in the presence of water and/or air.

The working examples which follow serve to further illustrate the invention and its technical effects and should not be interpreted in a restrictive manner.

### WORKING EXAMPLES

### Example 1

Monochrome devices with the following device stack are fabricated:

| | Green | |
|---|---|---|
| Cathode (AI) | 100 | nm |
| ETL | 40 | nm |
| HBL | 10 | nm |
| EML | 60 | nm |
| HTL | 20 | nm |
| HIL | 20 | nm |
| Anode (ITO) | 50 | nm |

The devices are prepared as follows:

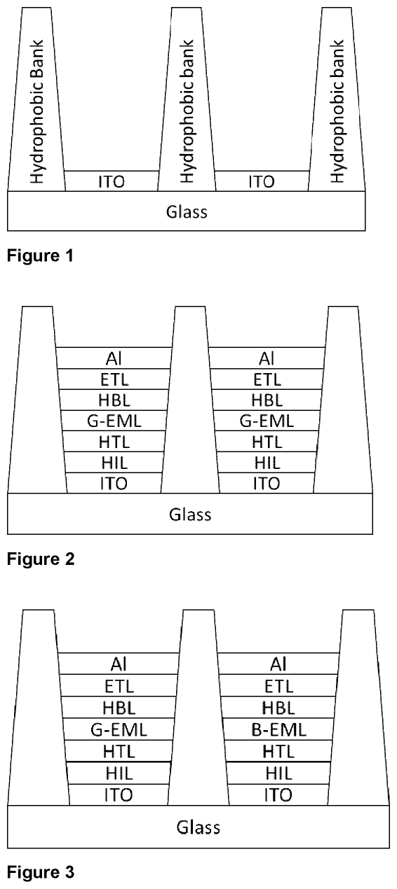

Glass substrates covered with pre-structured ITO (indium-tin-oxide) and a hydrophobic bank structure (see FIG. 1: Pre-structured inkjet printing substrates for device fabrication) are cleaned using ultrasonication in deionized water, then dried using an air-gun and subsequently annealed on a hot-plate at 225° C. for 2 hours.

For the deposition of the hole-injection layer (HIL), an HIL ink is printed, vacuum dried and the resulting HIL layer is subsequently annealed at 220° C. for 30 minutes in air.

The HIL ink is prepared by mixing a hole-transporting, cross-linkable polymer and a p-doping salt and dissolving the mixture in 3-Phenoxytoluene using a solid concentration of 10 g/L. Such HIL materials are shown in WO 2016/107668, WO 2013/081052 and EP2325190 among others. On top of the HIL, the hole-transport layer (HTL) is inkjet-printed, dried in vacuum and annealed at 225° C. for 30 minutes in nitrogen atmosphere. The HTL ink is prepared by dissolving HTM1 (see Table 1 below), which is synthesized in accordance with WO2013156130, in 3-Phenoxytoluene using a solid concentration of 7 g/L.

Subsequently, the emissive layer (EML) is inkjet-printed, vacuum dried and annealed. Altogether, six devices are fabricated with various EML annealing temperatures of 120° C., 130° C., 140° C., 150° C. and 160° C. for 10 minutes in nitrogen atmosphere, respectively.

The EML ink consists of a mixture of three materials (25% G-H1+55% G-H2+20% G-D1; see table 1) which are dissolved in 3-Phenoxytoluene using a solid concentration of 20 g/L.

All inkjet printing processes are performed under yellow light and under ambient conditions.

Subsequently, the devices are transferred into a vacuum deposition chamber where the deposition of a hole blocking layer (HBL), an electron transport layer (ETL) and a cathode (Al) is carried out using thermal evaporation.

For the HBL, ETM-1 (see Table 1 below) is used as neat film. For the electron transport layer (ETL), a 50:50 mixture of ETM-1 and ETM-2 (see Table 1 below) is used. Finally, the Al electrode is deposited. FIG. 2 shows the structure of a monochrome green device as fabricated in Example 1.

After fabrication, the devices are encapsulated in a glove box under nitrogen atmosphere and physical characterization is performed in ambient air.

TABLE 1
Molecular structures of HTL, green EML and ETL materials:

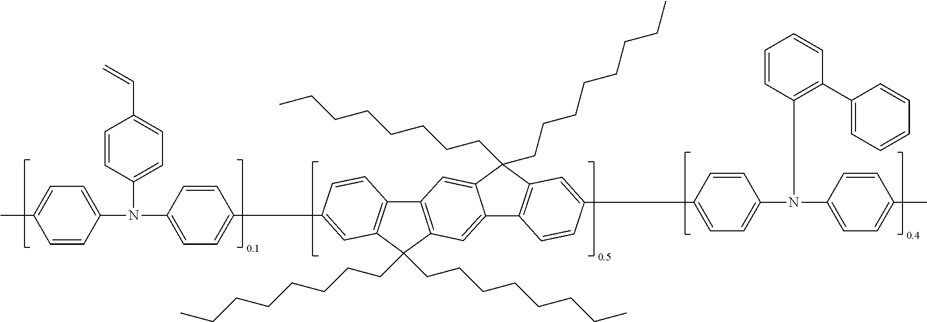

HTM1

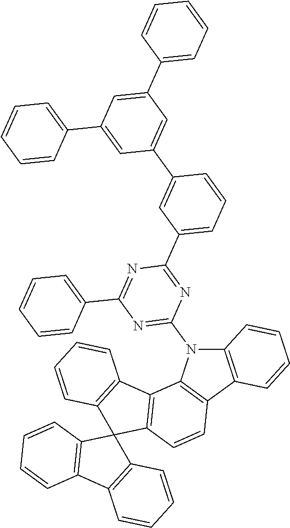 [SMILES: c1ccc(-c2cc(-c3ccccc3)cc(-c3cccc(-c4nc(-c5ccccc5)nc(-n5c6ccccc6c6ccc7c(c65)-c5ccccc5C75c6ccccc6-c6ccccc65)n4)c3)c2)cc1]

G-H1
CAS: 1616231-60-7

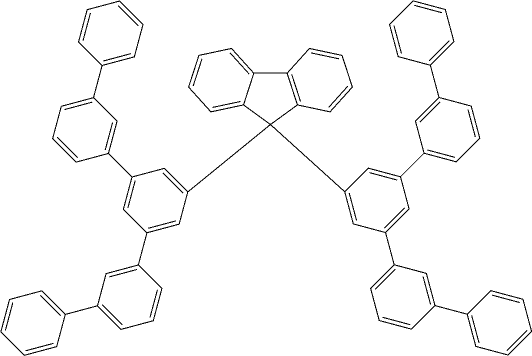 [SMILES: c1ccc(-c2cccc(-c3cc(-c4cccc(-c5ccccc5)c4)cc(C4(c5cc(-c6cccc(-c7ccccc7)c6)cc(-c6cccc(-c7ccccc7)c6)c5)c5ccccc5-c5ccccc54)c3)c2)cc1]

G-H2
CAS: 1246496-85-4

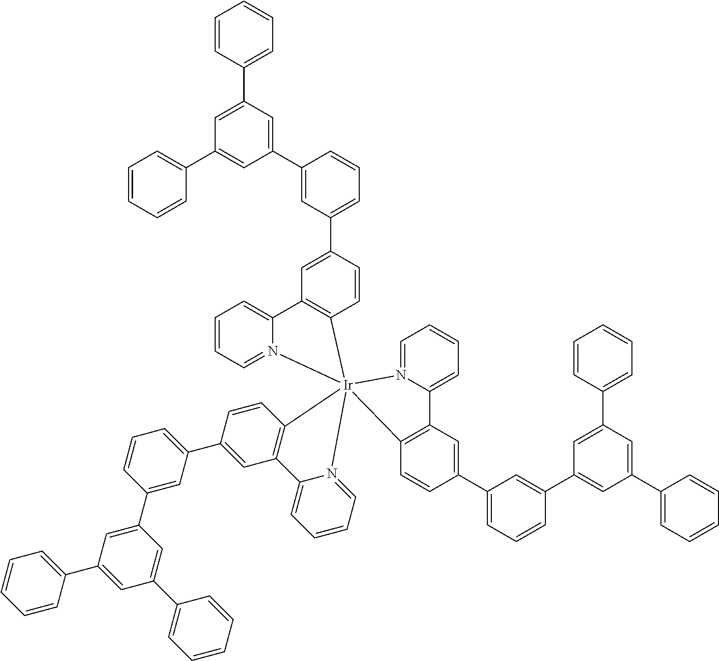

G-D1
CAS: 1269508-30-6

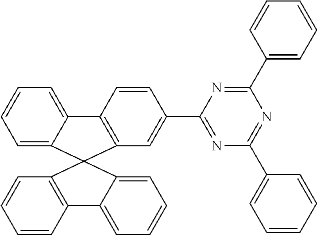 [SMILES: c1ccc(-c2nc(-c3ccccc3)nc(-c3ccc4c(c3)C3(c5ccccc5-c5ccccc53)c3ccccc3-4)n2)cc1]

ETM1

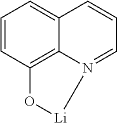

ETM2

In order to measure the external quantum efficiency (EQE @1000 cd/m2 (%)), a voltage ramp is applied to the devices by a Keithley 230 voltage source. The resulting current through the device is measured by a Keithley 199 DMM multimeter. The resulting light emission of the device is detected by an SPL-025Y brightness sensor, a combination of a photodiode with a photonic filter. The photo current of the photodiode is measured by a Keithley 617 electrometer. The device lifetime is measured under a given current corresponding to an initial luminance. The luminance is then measured over time by a calibrated photodiode.

The following device performance is achieved in dependence of the applied EML annealing temperature:

| | EML annealing | EQE (normalized) | LT95 (normalized) at |
|---|---|---|---|
| Device | temp. (° C.) | @1000 cd/m² | @8000 cd/m² |
| A | 120 | 1.01 | 0.44 |
| B | 130 | 1.00 | 0.64 |
| C | 140 | 0.99 | 0.84 |
| D | 150 | 1.00 | 1.00 |
| E | 160 | 0.97 | 0.80 |

These data clearly show that the device lifetime (LT95) is impacted by the applied EML annealing temperature. Starting from an EML annealing temperature of 120° C. (Device A), LT95 significantly increases with increasing annealing temperature until a maximum LT95 value is obtained for device D with an EML annealing temperature of 150° C. If the EML annealing temperature is further increased to 160° C., as in Device E, LT95 decreases again. In contrast, the EQE is only minimally impacted by the EML annealing temperature in case of monochrome green devices.

### Example 2

On inkjet printing substrates, Green and blue devices with the following device stacks are fabricated side-by-side (see FIG. 3):

| | |
|---|---|
| Green | Blue |

| | | | | |
|---|---|---|---|---|
| Cathode (AI) | 100 | nm | 100 | nm |
| ETL | 40 | nm | 40 | nm |
| HBL | 10 | nm | 10 | nm |
| EML | 60 | nm | 35 | nm |
| HTL | 20 | nm | 20 | nm |
| HIL | 20 | nm | 20 | nm |
| Anode (ITO) | 50 | nm | 50 | nm |

The device fabrication steps are carried out as in Example 1. For the hole-injection layer (HIL), hole-transport layer (HTL) and green emitting layer (G-EML), the same materials as in Example 1 are used. As blue emitting layer (B-EML), a mixture of two materials (99% host+1% B-D1) is used whereas the host material is varied (B-H1−B-H12). The molecular structures of these materials are shown in Table 2 below.

TABLE 2
Molecular structures of blue EML materials:

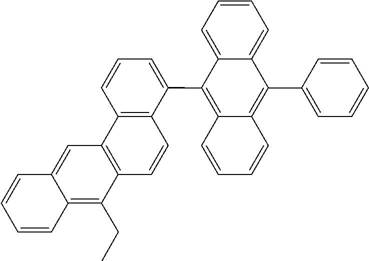 [SMILES: CCc1c2ccccc2cc2c1ccc1c(-c3c4ccccc4c(-c4ccccc4)c4ccccc34)cccc12]

B-H1

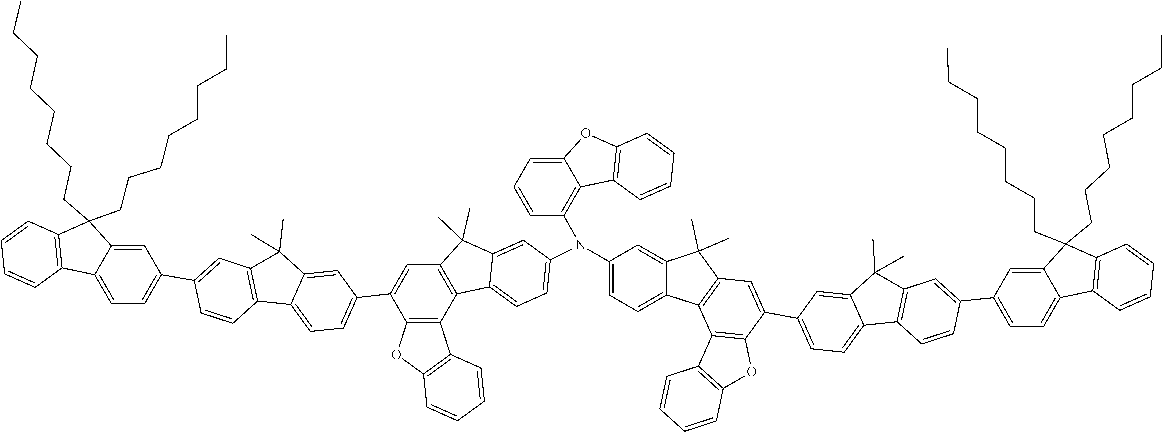 [SMILES: CCCCCCCCC1(CCCCCCCC)c2ccccc2-c2ccc(-c3ccc4c(c3)C(C)(C)c3cc(-c5cc6c(c7c5oc5ccccc57)-c5ccc(N(c7ccc8c(c7)C(C)(C)c7cc(-c9ccc%10c(c9)C(C)(C)c9cc(-c%11ccc%12c(c%11)C(CCCCCCCC)(CCCCCCCC)c%11ccccc%11-%12)ccc9-%10)c9oc%10ccccc%10c9c7-8)c7cccc8oc9ccccc9c78)cc5C6(C)C)ccc3-4)cc21]

B-D1

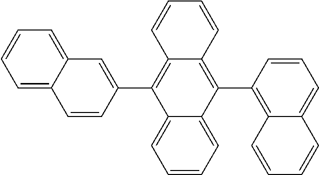 [SMILES: c1ccc2cc(-c3c4ccccc4c(-c4cccc5ccccc45)c4ccccc34)ccc2c1]

B-H2

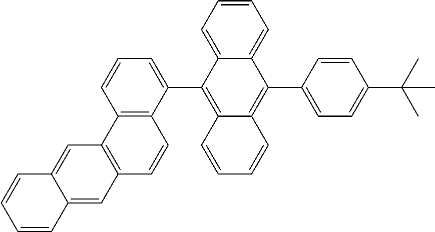 [SMILES: CC(C)(C)c1ccc(-c2c3ccccc3c(-c3cccc4c3ccc3cc5ccccc5cc34)c3ccccc23)cc1]

B-H3

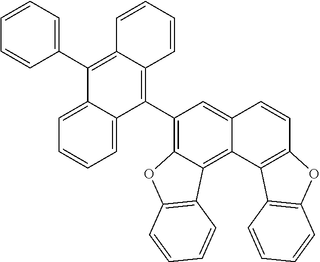 [SMILES: c1ccc(-c2c3ccccc3c(-c3cc4ccc5oc6ccccc6c5c4c4c3oc3ccccc34)c3ccccc23)cc1]

B-H4

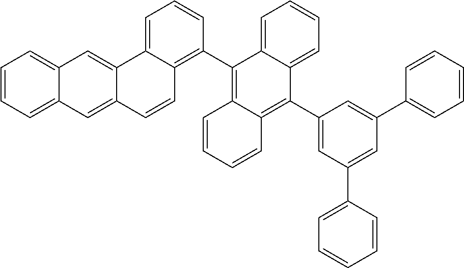 [SMILES: c1ccc(-c2cc(-c3ccccc3)cc(-c3c4ccccc4c(-c4cccc5c4ccc4cc6ccccc6cc45)c4ccccc34)c2)cc1]

B-H5

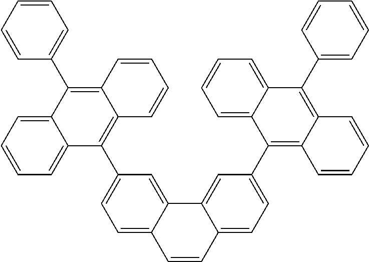 [SMILES: c1ccc(-c2c3ccccc3c(-c3ccc4ccc5ccc(-c6c7ccccc7c(-c7ccccc7)c7ccccc67)cc5c4c3)c3ccccc23)cc1]

B-H6

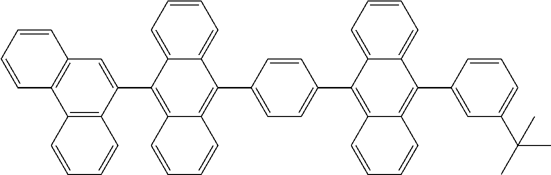 [SMILES: CC(C)(C)c1cccc(-c2c3ccccc3c(-c3ccc(-c4c5ccccc5c(-c5cc6ccccc6c6ccccc56)c5ccccc45)cc3)c3ccccc23)c1]

B-H7

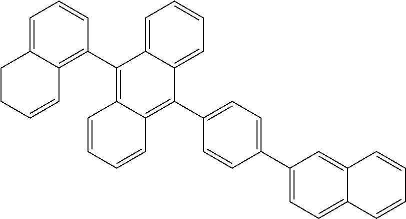 [SMILES: C1=Cc2c(cccc2-c2c3ccccc3c(-c3ccc(-c4ccc5ccccc5c4)cc3)c3ccccc23)CC1]

B-H8

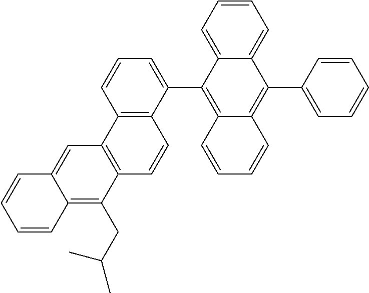 [SMILES: CC(C)Cc1c2ccccc2cc2c1ccc1c(-c3c4ccccc4c(-c4ccccc4)c4ccccc34)cccc12]

B-H9

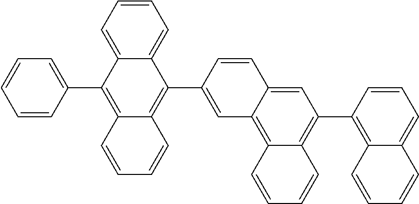 [SMILES: c1ccc(-c2c3ccccc3c(-c3ccc4cc(-c5cccc6ccccc56)c5ccccc5c4c3)c3ccccc23)cc1]

B-H10

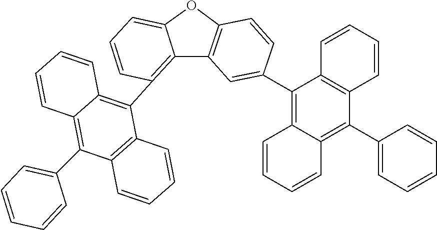 [SMILES: c1ccc(-c2c3ccccc3c(-c3ccc4oc5cccc(-c6c7ccccc7c(-c7ccccc7)c7ccccc67)c5c4c3)c3ccccc23)cc1]

B-H11

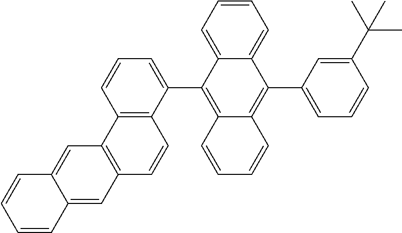 [SMILES: CC(C)(C)c1cccc(-c2c3ccccc3c(-c3cccc4c3ccc3cc5ccccc5cc34)c3ccccc23)c1]

B-H12

The compounds B-H1 to B-H12 are commercially available or can be synthesized by a skilled person in analogous manner as describe in i.e. WO2015158409, WO2020089138, WO2009100925, WO2017036573, EP 20187118.3. Compound B-D1 can be synthesized as described in WO 2019076789.

The following device performance is achieved for the Green devices in dependence of the different blue host molecules B-H1-B-H12 at an EML annealing temperature of 150° C.:

| | | Molecular | TGA vac: | |
|---|---|---|---|---|
| | Host | weight of blue | Temp at 5% | EQE, normalized |
| | material of | host material | wt. loss | to reference |
| Device | blue EML | (g/Mol) | (C. °) | @1000 cd/m² |
| Reference | — | — | — | 1.00 |
| A | B-H2 | 431 | 179 | 0.06 |
| B | B-H1 | 509 | 215 | 0.73 |
| C | B-H9 | 537 | 217 | 0.74 |
| D | B-H8 | 507 | 226 | 0.84 |
| E | B-H12 | 537 | 228 | 0.86 |
| F | B-H3 | 537 | 237 | 0.96 |
| G | B-H11 | 673 | 245 | 0.97 |
| H | B-H4 | 561 | 247 | 0.99 |
| 1 | B-H10 | 557 | 249 | 1.00 |
| J | B-H5 | 633 | 271 | 0.99 |
| K | B-H6 | 683 | 288 | 1.02 |
| L | B-H7 | 739 | 308 | 1.00 |

Here, the EQE is normalized to the respective value of a monochrome green device (see Example 1). For the blue host molecules, the molecular weight as well as their TGA temperature at 5% weight loss are stated.

The vacuum TGA measurements is performed using a TG 209 F1 Libra from Netzsch, which is temperature-calibrated under vacuum in the means of cure standards. For the measurement 1 mg of the sample is put in an aluminum crucible. The heating rate is 5K/min in the range of 105-405° C. and a reduced pressure of 0.01 mbar with 30 minutes evacuation time before measurement.

As the data shows, the EQE of the green device is impacted by the host material deposited into the neighbouring blue pixel. For some blue host molecules, the EQE of the green device is reduced. This reduction in EQE correlates with the molecular weight of the blue host material as well as its temperature at 5% weight loss in a TGA measurement in vacuum.

For the blue host material with a TGA temperature of 179° C., the green EQE is reduced to a very low value of 0.06 (Device A). In case of blue host materials with TGA temperatures of 215 and 217° C., loss in green EQE is very similar and values of 0.73 and 0.74 are reached (Devices B and C). In addition to the TGA temperatures, the observed green EQEs also correlate with the molecular weight of the blue host material for Devices A-C (431, 509 and 537 g/Mol).

For devices D and E, where blue host materials with TGA temperatures of 225 and 228° C. are printed next to the green pixels, EQEs of 0.84 and 0.86 are observed. Also for this TGA temperature range of 220° C. to 230° C., the green EQE correlates with the molecular weight of the investigated blue hosts (507 and 537 g/Mol). For TGA temperatures of ≥237° C., the EQE of the green device is effectively unimpacted (values of ˜1) by the neighbouring blue host.

This behaviour can be explained by a cross-contamination of the green device by the neighbouring blue device. During the annealing of the EML, blue host molecules with a low TGA temperature/low molecular weight evaporate and diffuse to the neighbouring green device where they quench the light emission as a result of their T1 energy being considerably lower than the one of the green EML.

In summary, these data illustrate that a good EQE can be achieved in the green device when the TGA temperature of the blue host material, which is deposited into the neighbouring pixel, is ≥237° C. Furthermore, a good EQE is also achieved in the green device for all blue host materials which have a molecular weight of >537 g/Mol.

1.-24. (canceled)

25. An electroluminescent device comprising at least one pixel comprising:
A first subpixel comprising an emitting layer EMLA comprising a compound A;
A second subpixel comprising an emitting layer EMLB comprising a compound B, wherein the compound B is the compound having the lowest T₁ state in the emitting layer of the second subpixel;
characterized in that:
T_{1-A}<T_{1-B}
TGA_{A}≥225° C.
where
T_{1-A}, T_{1-B} are the energetically lowest triplet state of the compounds A and B; and TGA_{A} is the temperature at which 5% weight loss is measured via thermal gravimetric analysis.

26. The electroluminescent device according to claim 25, characterized in that that the compound A has a temperature TGA_{A} at which 5% weight loss is measured via thermal gravimetric analysis of ≥230° C.

27. The electroluminescent device according to claim 25, characterized in that the emitting layer EMLA comprises a host compound HA and an emitting compound EA, wherein the compound A is either the host compound HA or the emitting compound EA.

28. An electroluminescent device comprising at least one pixel comprising:
A first subpixel comprising an emitting layer EML1 comprising a host compound H1 and an emitting compound E1;
A second subpixel comprising an emitting layer EML2 comprising a host compound H2 and an emitting compound E2;
characterized in that:
T_{1-H1}<T_{1-E2}
TGA_{H1}≥225° C.
where
T_{1-H1}, T_{1-E1} are the energetically lowest triplet state of the host compound H1 and of the emitting compound E2; and
TGA_{H1} is the temperature at which 5% weight loss is measured via thermal gravimetric analysis.

29. The electroluminescent device according to claim 28, characterized in that the host compound H1 has a temperature TGA_{H1} at which 5% weight loss is measured via thermal gravimetric analysis of ≥230° C.

30. The electroluminescent device according to claim 28, characterized in that the emitting compound E1 has an emission maximum wavelength λ₁, the emitting compound E2 has an emission maximum wavelength λ₂ and:
λ₁<λ₂

31. The electroluminescent device according to claim 28, characterized in that the emitting compound E1 has an emission wavelength λ₁ of from 430 to 480 nm.

32. The electroluminescent device according to claim 28, characterized in that the host compound H1 has a molecular weight Mw1≥520 g/mol.

33. The electroluminescent device according to claim 25, characterized in that the emitting layers EMLA and EMLB or EML1 and EML2 are obtained from a solution process.

34. The electroluminescent device according to claim 28, characterized in that the device comprises a third sub pixel comprising an emitting layer EML3 comprising an emitting compound E3 having an emission maximum wavelength λ₃, where:
λ₁<λ₂<λ₃; or 1)
λ₁<λ₃<λ₂. 2)

36. The electroluminescent device according to claim 25, characterized in that the subpixels are laterally separated in a side-by-side geometry by a hydrophobic bank structure.

37. The electroluminescent device according to claim 25, characterized in that each subpixel corresponds to a light emitting stack comprising at least one further organic layer.

38. The electroluminescent device according to claim 37, characterized in that the further layer is selected from hole-transporting layers.

39. The electroluminescent device according to claim 25, characterized in that that each subpixel comprises in the following order;
A substrate;
An anode;
Optionally a hole-injection layer,
A hole-transport layer;
An emitting layer;
Optionally a hole-blocking layer;
An electron-transporting layer;
Optionally an electron-injection layer; and
A cathode.

40. The electroluminescent device according to claim 39, characterized in that the optional hole-injection layer, the hole-transport layer and the emitting layer are obtained from a solution process.

41. The electroluminescent device according to claim 28, characterized in that the host compound H1 comprises at least one anthracene group.

42. The electroluminescent device according to claim 28, characterized in that the host compound H1 is a compound of formula (1), 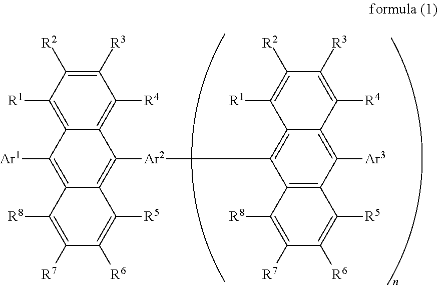
where
Ar¹,Ar², Ar³ are, on each occurrence, identically or differently, an aromatic or heteroaromatic ring system having 5 to 60 aromatic ring atoms, which may in each case also be substituted by one or more radicals R⁹;
R¹ to R⁹ stand on each occurrence, identically or differently, for H, D, F, Cl, Br, I, CHO, CN, C(═O)Ar, P(═O)(Ar)₂, S(═O)Ar, S(═O)₂Ar, N(R)₂, N(Ar)₂, NO₂, Si(R)₃, B(OR)₂, OSO₂R, a straight-chain alkyl, alkoxy or thioalkyl group having 1 to 40 C atoms or branched or a cyclic alkyl, alkoxy or thioalkyl group having 3 to 40 C atoms, each of which may be substituted by one or more radicals R, where in each case one or more non-adjacent CH₂ groups may be replaced by RC═CR, Si(R)₂, Ge(R)₂, Sn(R)₂, C═O, C═S, C═Se, P(═O)(R), SO, SO₂, O, S or CONR and where one or more H atoms may be replaced by D, F, Cl, Br, I, CN or NO₂, an aromatic or heteroaromatic ring system having 5 to 60 aromatic ring atoms, which may in each case be substituted by one or more radicals R, or an aryloxy group having 5 to 60 aromatic ring atoms, which may be substituted by one or more radicals R;
R stands on each occurrence, identically or differently, for H, D, F, Cl, Br, I, CHO, CN, C(═O)Ar, P(═O)(Ar)₂, S(═O)Ar, S(═O)₂Ar, N(W)₂, N(Ar)₂, NO₂, Si(R)₃, B(OR′)₂, OSO₂R, a straight-chain alkyl, alkoxy or thioalkyl group having 1 to 40 C atoms or branched or a cyclic alkyl, alkoxy or thioalkyl group having 3 to 40 C atoms, each of which may be substituted by one or more radicals R′, where in each case one or more non-adjacent CH₂ groups may be replaced by R′C═CR′, Si(R′)₂, Ge(R′)₂, Sn(R′)₂, C═O, C═S, C═Se, P(═O)(R′), SO, SO₂, O, S or CONR and where one or more H atoms may be replaced by D, F, Cl, Br, I, CN or NO₂, an aromatic or heteroaromatic ring system having 5 to 60 aromatic ring atoms, which may in each case be substituted by one or more radicals R′, or an aryloxy group having 5 to 60 aromatic ring atoms, which may be substituted by one or more radicals R′; where two adjacent substituents R may form an aliphatic or aromatic ring system together, which may be substituted by one or more radicals R′;
Ar is, on each occurrence, identically or differently, an aromatic or heteroaromatic ring system having 5 to 60 aromatic ring atoms, which may in each case also be substituted by one or more radicals R′;
stands on each occurrence, identically or differently, for H, D, F, Cl, Br, I, CN, a straight-chain alkyl, alkoxy or thioalkyl group having 1 to 20 C atoms or branched or cyclic alkyl, alkoxy or thioalkyl group having 3 to 20 C atoms, where in each case one or more non-adjacent CH₂ groups may be replaced by SO, SO₂, O, S and where one or more H atoms may be replaced by D, F, Cl, Br or I, or an aromatic or heteroaromatic ring system having 5 to 24 aromatic ring atoms; and
n is 0 or 1.

43. The electroluminescent device according to claim 28, characterized in that the host compound H1 is a compound of formula (1) having at least one D.

44. The electroluminescent device according to claim 28, characterized in that the emitting layer EML1 comprises an emitting compound E1, a host compound H1 and a second host compound H1B.

45. The electroluminescent device according to claim 44, characterized in that the first host compound H1 and the second host compound H1B are selected from the compounds of formula (1) 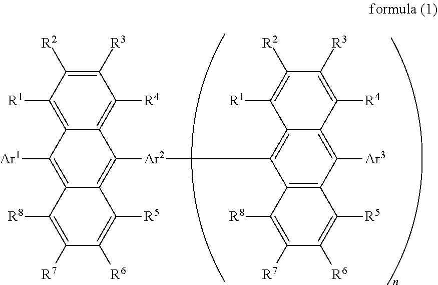
where
Ar¹, Ar², Ar³ are, on each occurrence, identically or differently, an aromatic or heteroaromatic ring system having 5 to 60 aromatic ring atoms, which may in each case also be substituted by one or more radicals R⁹;
R¹ to R⁹ stand on each occurrence, identically or differently, for H, D, F, Cl, Br, I, CHO, CN, C(═O)Ar, P(═O)(Ar)₂, S(═O)Ar, S(═O)₂Ar, N(R)₂, N(Ar)₂, NO₂, Si(R)₃, B(OR)₂, OSO₂R, a straight-chain alkyl, alkoxy or thioalkyl group having 1 to 40 C atoms or branched or a cyclic alkyl, alkoxy or thioalkyl group having 3 to 40 C atoms, each of which may be substituted by one or more radicals R, where in each case one or more non-adjacent CH₂ groups may be replaced by RC═CR, C≡C, Si(R)₂, Ge(R)₂, Sn(R)₂, C═O, C═S, C═Se, P(═O)(R), SO, SO₂, O, S or CONR and where one or more H atoms may be replaced by D, F, Cl, Br, I, CN or NO₂, an aromatic or heteroaromatic ring system having 5 to 60 aromatic ring atoms, which may in each case be substituted by one or more radicals R, or an aryloxy group having 5 to 60 aromatic ring atoms, which may be substituted by one or more radicals R;
R stands on each occurrence, identically or differently, for H, D, F, Cl, Br, I, CHO, CN, C(═O)Ar, P(═O)(Ar)₂, S(═O)Ar, S(═O)₂Ar, N(R′)₂, N(Ar)₂, NO₂, Si(R′)₃, B(OR′)₂, OSO₂R, a straight-chain alkyl, alkoxy or thioalkyl group having 1 to 40 C atoms or branched or a cyclic alkyl, alkoxy or thioalkyl group having 3 to 40 C atoms, each of which may be substituted by one or more radicals R′, where in each case one or more non-adjacent CH₂ groups may be replaced by R′C═CR′, Si(R′)₂, Ge(R′)₂, Sn(R′)₂, C═O, C═S, C═Se, P(═O)(R′), SO, SO₂, O, S or CONR and where one or more H atoms may be replaced by D, F, Cl, Br, I, CN or NO₂, an aromatic or heteroaromatic ring system having 5 to 60 aromatic ring atoms, which may in each case be substituted by one or more radicals R′, or an aryloxy group having 5 to 60 aromatic ring atoms, which may be substituted by one or more radicals R′; where two adjacent substituents R may form an aliphatic or aromatic ring system together, which may be substituted by one or more radicals R′;
Ar is, on each occurrence, identically or differently, an aromatic or heteroaromatic ring system having 5 to 60 aromatic ring atoms, which may in each case also be substituted by one or more radicals R′;
R′ stands on each occurrence, identically or differently, for H, D, F, Cl, Br, I, CN, a straight-chain alkyl, alkoxy or thioalkyl group having 1 to 20 C atoms or branched or cyclic alkyl, alkoxy or thioalkyl group having 3 to 20 C atoms, where in each case one or more non-adjacent CH₂ groups may be replaced by SO, SO₂, O, S and where one or more H atoms may be replaced by D, F, Cl, Br or I, or an aromatic or heteroaromatic ring system having 5 to 24 aromatic ring atoms; and
n is 0 or 1.

46. The electroluminescent device according to claim 28, characterized in that the emitting compound E1 is a fluorescent emitting compound.

47. The electroluminescent device according to claim 28, characterized in that the emitting compound E1 is a fluorescent emitting compound selected from the group consisting of:
an arylamine containing three substituted or unsubstituted aromatic or heteroaromatic ring systems bonded directly to the nitrogen;
a bridged triarylamine;
a condensed aromatic or heteroaromatic ring system having at least 14 aromatic ring atoms;
an indenofluorene, indenofluorenamine or indenofluorenediamine;
a benzoindonofluorene, benzoindenofluorenamine or benzoindenofluorenediamine;
a dibenzoindenofluorene, dibenzoindenofluorenamine or dibenzoindenofluorenediamine;
an indenofluorene containing a condensed aryl group having at least 10 aromatic ring atoms;
a bisindenoindenofluorene;
an indenodibenzofuran; indenofluorenamine or indenofluorenediamine;
a fluorene dimer;
a phenoxazine; and
a boron derivative.

48. A process for the production of the electroluminescent device according to claim 28, characterized in that the process comprises the following steps:
a) applying a solution comprising an emitting compound E1 and a host compound H1 on a substrate, or on another layer, in order to form the emitting layer EML1 of the first subpixel;
b) applying a solution comprising an emitting compound E2 and a host compound H2 on a substrate, or on another layer, in order to form the emitting layer EML2 of the second subpixel;
c) drying of the layer deposited in step a) in order to remove the solvent;
d) drying of the layer deposited in step b) in order to remove the solvent;
whereas steps a) and b) can be performed one after each other or simultaneously; and
steps c) and d) can be performed one after each other or simultaneously.
